(19) United States
(12) Patent Application Publication
(10) Pub. No.: US 2023/0116067 A1
(43) Pub. Date: Apr. 13, 2023

(54) DISPLAY APPARATUS, DISPLAY MODULE, AND ELECTRONIC DEVICE

(71) Applicant: Semiconductor Energy Laboratory Co., Ltd., Atsugi-shi (JP)

(72) Inventors: Nozomu SUGISAWA, Isehara (JP); Tomoya AOYAMA, Atsugi (JP)

(21) Appl. No.: 17/954,435

(22) Filed: Sep. 28, 2022

(30) Foreign Application Priority Data
Oct. 7, 2021 (JP) 2021-165508

(51) Int. Cl. H01L 27/32; H01L 51/56

(52) U.S. Cl. CPC H01L 27/322; H01L 51/56

(57) ABSTRACT

A high-resolution display apparatus is provided. The display apparatus includes first to third light-emitting devices, a color conversion layer, and first and second insulating layers. The first light-emitting device includes a first pixel electrode, a first light-emitting layer, and a common electrode. The second light-emitting device includes a second pixel electrode, a second light-emitting layer, and the common electrode. The third light-emitting device includes a third pixel electrode, a third light-emitting layer, and the common electrode. The first and second light-emitting layers contain the same light-emitting material. The third light-emitting material emits shorter-wavelength light than the first and second light-emitting devices. The color conversion layer overlaps with the first light-emitting device. The color conversion layer converts a color of light emitted from the first light-emitting device into a different color. The first and second insulating layers each overlap with a side surface and part of a top surface of the first light-emitting layer and a side surface and part of a top surface of the second light-emitting layer. The common electrode covers a top surface of the second insulating layer.

### BACKGROUND OF THE INVENTION

### 1. Field of the Invention

One embodiment of the present invention relates to a display apparatus, a display module, and an electronic device. One embodiment of the present invention relates to a manufacturing method of a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### 2. Description of the Related Art

Recent display apparatuses have been expected to be applied to a variety of uses. Usage examples of large-sized display apparatuses include a television device for home use (also referred to as TV or television receiver), digital signage, and a public information display (PID). In addition, a smartphone and a tablet terminal each including a touch panel, and the like, are being developed as portable information terminals.

Furthermore, higher-resolution display apparatuses have been required. For example, devices for virtual reality (VR), augmented reality (AR), substitutional reality (SR), or mixed reality (MR) are given as devices requiring high-resolution display apparatuses and have been actively developed in recent years.

Light-emitting apparatuses including light-emitting devices (also referred to as light-emitting elements) have been developed as display apparatuses, for example. Light-emitting devices utilizing electroluminescence (hereinafter referred to as EL; such devices are also referred to as EL devices or EL elements) have features such as ease of reduction in thickness and weight, high-speed response to input signals, and driving with a constant DC voltage power source, and have been used in display apparatuses.

Patent Document 1 discloses a display apparatus using an organic EL device (also referred to as organic EL element) for VR.

### REFERENCE

### Patent Document

[Patent Document 1] International Publication No. WO2018/087625

### SUMMARY OF THE INVENTION

An object of one embodiment of the present invention is to provide a high-resolution display apparatus. An object of one embodiment of the present invention is to provide a high-definition display apparatus. An object of one embodiment of the present invention is to provide a highly reliable display apparatus. An object of one embodiment of the present invention is to provide a display apparatus capable of displaying an image at high luminance.

An object of one embodiment of the present invention is to provide a method for manufacturing a high-resolution display apparatus. An object of one embodiment of the present invention is to provide a method for manufacturing a high-definition display apparatus. An object of one embodiment of the present invention is to provide a method for manufacturing a highly reliable display apparatus. An object of one embodiment of the present invention is to provide a method for manufacturing a display apparatus with high yield.

Note that the description of these objects does not preclude the existence of other objects. One embodiment of the present invention does not need to achieve all of these objects. Other objects can be derived from the description of the specification, the drawings, and the claims.

One embodiment of the present invention is a display apparatus including a first light-emitting device, a second light-emitting device, a third light-emitting device, a color conversion layer, a first insulating layer, and a second insulating layer. The first light-emitting device includes a first pixel electrode, a first light-emitting layer over the first pixel electrode, and a common electrode over the first light-emitting layer. The second light-emitting device includes a second pixel electrode, a second light-emitting layer over the second pixel electrode, and the common electrode over the second light-emitting layer. The third light-emitting device includes a third pixel electrode, a third light-emitting layer over the third pixel electrode, and the common electrode over the third light-emitting layer. The first light-emitting layer and the second light-emitting layer include the same light-emitting material. The third light-emitting device emits shorter-wavelength light than the first light-emitting device and the second light-emitting device. The color conversion layer overlaps with the first light-emitting device. The color conversion layer converts a color of light emitted from the first light-emitting device into a different color. The first insulating layer covers a side surface and part of a top surface of the first light-emitting layer and a side surface and part of a top surface of the second light-emitting layer. The second insulating layer overlaps with the part of the top surface of the first light-emitting layer and the part of the top surface of the second light-emitting layer with the first insulating layer therebetween. The second insulating layer includes a portion positioned between the side surface of the first light-emitting layer and the side surface of the second light-emitting layer. The common electrode covers a top surface of the second insulating layer.

One embodiment of the present invention is a display apparatus including a first light-emitting device, a second light-emitting device, a third light-emitting device, a color conversion layer, a first insulating layer, and a second insulating layer. The first light-emitting device includes a first pixel electrode, a first light-emitting layer over the first pixel electrode, a first functional layer over the first light-emitting layer, and a common electrode over the first functional layer. The second light-emitting device includes a second pixel electrode, a second light-emitting layer over the second pixel electrode, a second functional layer over the second light-emitting layer, and the common electrode over the second functional layer. The third light-emitting device includes a third pixel electrode, a third light-emitting layer over the third pixel electrode, a third functional layer over the third light-emitting layer, and the common electrode over the third functional layer. The first light-emitting layer and the second light-emitting layer contain the same light-emitting material. The third light-emitting device emits the shortest-wavelength light among the first light-emitting device, the second light-emitting device, and the third light-emitting device. The color conversion layer overlaps with the first light-emitting device. The color conversion layer converts a color of light emitted from the first light-emitting device into a different color. The first insulating layer covers a side surface and part of a top surface of the first light-emitting layer, a side surface and part of a top surface of the second light-emitting layer, a side surface and part of a top surface of the first functional layer, and a side surface and part of a top surface of the second functional layer. The second insulating layer overlaps with the part of the top surface of the first light-emitting layer, the part of the top surface of the second light-emitting layer, the part of the top surface of the first functional layer, and the part of the top surface of the second functional layer with the first insulating layer therebetween. The second insulating layer includes a portion positioned between the side surface of the first light-emitting layer and the side surface of the second light-emitting layer. The common electrode covers a top surface of the second insulating layer.

It is preferable that the first functional layer, the second functional layer, and the third functional layer each include at least one of a hole-injection layer, an electron-injection layer, a hole-transport layer, an electron-transport layer, a hole-blocking layer, and an electron-blocking layer.

It is preferable that the first light-emitting device and the second light-emitting device emit green light, the third light-emitting device emit blue light, and the color conversion layer convert green light into red light.

The display apparatus preferably includes a first coloring layer at a position overlapping with the first light-emitting device with the color conversion layer therebetween. The first coloring layer preferably transmits red light.

The display apparatus preferably includes a second coloring layer transmitting green light at a position overlapping with the second light-emitting device and a third coloring layer transmitting blue light at a position overlapping with the third light-emitting device.

In a cross-sectional view, an end portion of the second insulating layer preferably has a tapered shape with a taper angle less than 90°.

The second insulating layer preferably covers at least part of a side surface of the first insulating layer.

An end portion of the second insulating layer is preferably positioned on an outer side of an end portion of the first insulating layer.

The top surface of the second insulating layer preferably has a convex shape.

In a cross sectional view, an end portion of the first insulating layer preferably has a tapered shape with a taper angle less than 90°.

It is preferable that the first insulating layer and the second insulating layer each include a portion overlapping with a top surface of the first pixel electrode and a portion overlapping with a top surface of the second pixel electrode.

It is preferable that the first light-emitting layer cover a side surface of the first pixel electrode, the second light-emitting layer cover a side surface of the second pixel electrode, and the third light-emitting layer cover a side surface of the third pixel electrode.

In a cross-sectional view, it is preferable that an end portion of the first pixel electrode, an end portion of the second pixel electrode, and an end portion of the third pixel electrode each have a tapered shape with a taper angle less than 90°.

It is preferable that the first insulating layer be an inorganic insulating layer and the second insulating layer be an organic insulating layer.

The first insulating layer preferably contains aluminum oxide.

It is preferable that the first light-emitting device include a common layer between the first light-emitting layer and the common electrode, the second light-emitting device include the common layer between the second light-emitting layer and the common electrode, the third light-emitting device include the common layer between the third light-emitting layer and the common electrode, and the common layer be positioned between the second insulating layer and the common electrode.

Another embodiment of the present invention is a display module including the display apparatus with any of the above structures. The display module is provided with a connector such as a flexible printed circuit (FPC) or a tape carrier package (TCP), or an integrated circuit (IC) by a chip on glass (COG) method, a chip on film (COF) method, or the like.

Another embodiment of the present invention is an electronic device including the display module and at least one of a housing, a battery, a camera, a speaker, and a microphone.

One embodiment of the present invention can provide a high-resolution display apparatus. One embodiment of the present invention can provide a high-definition display apparatus. One embodiment of the present invention can provide a highly reliable display apparatus. One embodiment of the present invention can provide a display apparatus capable of displaying an image at high luminance.

One embodiment of the present invention can provide a method for manufacturing a high-resolution display apparatus. One embodiment of the present invention can provide a method for manufacturing a high-definition display apparatus. One embodiment of the present invention can provide a method for manufacturing a highly reliable display apparatus. One embodiment of the present invention can provide a method for manufacturing a display apparatus with high yield.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a top view illustrating an example of a display apparatus, FIG. 1B is a cross-sectional view illustrating an example of a display apparatus, and FIG. 1C is a top view illustrating an example of a layer 113G;

FIGS. 2A and 2B are cross-sectional views illustrating an example of a display apparatus;

FIGS. 3A and 3B are cross-sectional views illustrating an example of a display apparatus;

FIGS. 4A and 4B are cross-sectional views illustrating examples of a display apparatus;

FIGS. 5A and 5B are cross-sectional views illustrating examples of a display apparatus;

FIGS. 6A and 6B are cross-sectional views illustrating examples of a display apparatus;

FIGS. 7A and 7F are cross-sectional views illustrating an example of a display apparatus, and FIGS. 7B to 7E are cross-sectional views illustrating examples of pixel electrodes;

FIGS. 8A to 8C are cross-sectional views illustrating an example of a display apparatus;

FIGS. 9A to 9D are cross-sectional views illustrating examples of a display apparatus;

FIG. 10A is a top view illustrating an example of a display apparatus, and FIG. 10B is a cross-sectional view illustrating an example of the display apparatus;

FIGS. 11A to 11C are cross-sectional views illustrating an example of a method for manufacturing a display apparatus;

FIGS. 12A to 12C are cross-sectional views illustrating an example of a method for manufacturing a display apparatus;

FIGS. 13A to 13C are cross-sectional views illustrating an example of a method for manufacturing a display apparatus;

FIGS. 14A to 14C are cross-sectional views illustrating an example of a method for manufacturing a display apparatus;

FIGS. 15A and 15B are cross-sectional views illustrating an example of a method for manufacturing a display apparatus;

FIGS. 16A to 16E are cross-sectional views illustrating an example of a method for manufacturing a display apparatus;

FIGS. 17A and 17B are cross-sectional views illustrating an example of a method for manufacturing a display apparatus;

FIGS. 18A to 18G illustrate examples of pixels;

FIGS. 19A to 19K illustrate examples of a pixel;

FIG. 20A and FIG. 20B are perspective views illustrating an example of a display apparatus;

FIGS. 21A and 21B are cross-sectional views illustrating examples of a display apparatus;

FIG. 22 is a cross-sectional view illustrating an example of a display apparatus;

FIG. 23 is a cross-sectional view illustrating an example of a display apparatus;

FIG. 24 is a cross-sectional view illustrating an example of a display apparatus;

FIG. 25 is a cross-sectional view illustrating an example of a display apparatus;

FIG. 26 is a cross-sectional view illustrating an example of a display apparatus;

FIG. 27 is a perspective view illustrating an example of a display apparatus;

FIG. 28A is a cross-sectional view illustrating an example of a display apparatus, and FIGS. 28B and 28C are cross-sectional views illustrating examples of a transistor;

FIGS. 29A to 29D are cross-sectional views illustrating an example of a display apparatus;

FIG. 30 is a cross-sectional view illustrating an example of a display apparatus;

FIGS. 31A to 31F illustrate structure examples of a light-emitting device;

FIGS. 32A and 32B illustrate structure examples of a light-receiving device, and FIGS. 32C to 32E illustrate structure examples of a display apparatus;

FIGS. 33A to 33D illustrate examples of electronic devices;

FIGS. 34A to 34F illustrate examples of electronic devices; and

FIGS. 35A to 35G illustrate examples of electronic devices.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers of light-emitting devices having different emission wavelengths are separately formed may be referred to as a side-by-side (SBS) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be distinguished from each other depending on the cross-sectional shape or properties in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

Note that in this specification and the like, a tapered shape refers to a shape such that at least part of a side surface of a component is inclined with respect to a substrate surface or a formation surface of the component. For example, a tapered shape preferably includes a region where the angle between the inclined side surface and the substrate surface or the formation surface of the component (such an angle is also referred to as a taper angle) is less than 90°. Note that the side surface of the component and the substrate surface is not necessarily completely flat, and may have a substantially planar shape with a small curvature or slight unevenness.

### Embodiment 1

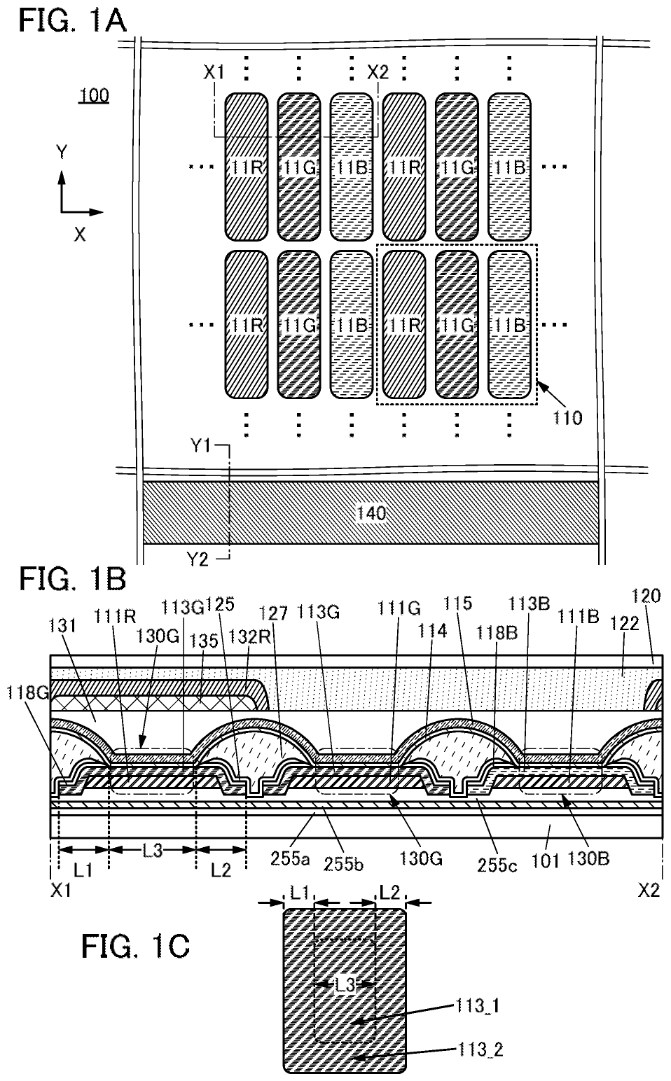

In this embodiment, a display apparatus of one embodiment of the present invention is described with reference to FIGS. 1A and 1B, FIGS. 2A and 2B, FIGS. 3A and 3B, FIGS. 4A and 4B, FIGS. 5A and 5B, FIGS. 6A and 6B, FIGS. 7A to 7F, FIGS. 8A to 8C, FIGS. 9A to 9D, and FIGS. 10A and 10B.

The display apparatus of one embodiment of the present invention includes a first light-emitting device and a second light-emitting device containing the same light-emitting material, a color conversion layer overlapping with the first light-emitting device, and a third light-emitting device emitting shorter-wavelength light than the first and second light-emitting devices.

In the case of manufacturing a display apparatus including a plurality of light-emitting devices emitting light of different colors, light-emitting layers different in emission color each need to be formed in an island shape.

For example, an island-shaped light-emitting layer can be formed by a vacuum evaporation method using a metal mask. However, this method causes a deviation from the designed shape and position of an island-shaped light-emitting layer due to various influences such as the low accuracy of the metal mask position, the positional deviation between the metal mask and a substrate, a warp of the metal mask, and the vapor-scattering-induced expansion of outline of the formed film; accordingly, it is difficult to achieve high resolution and high aperture ratio of the display apparatus. In addition, the outline of the layer may blur during vapor deposition, whereby the thickness of an end portion may be small. That is, the thickness of the island-shaped light-emitting layer formed using a metal mask may vary from area to area. In the case of manufacturing a display apparatus with a large size, high definition, or high resolution, the manufacturing yield might be reduced because of low dimensional accuracy of the metal mask and deformation due to heat or the like.

In view of this, in manufacture of the display apparatus of one embodiment of the present invention, fine patterning of a light-emitting layer is performed by a photolithography method without a shadow mask such as a metal mask. Specifically, a light-emitting layer is formed across a plurality of pixel electrodes that have been formed independently for respective subpixels. After that, the light-emitting layer is processed by a photolithography method, so that one island-shaped light-emitting layer is formed per pixel electrode. Thus, the light-emitting layer can be divided into island-shaped light-emitting layers for respective subpixels.

For example, in the case where the display apparatus includes three kinds of light-emitting devices, which are a light-emitting device emitting blue light (also simply referred to as a blue-light-emitting device), a light-emitting device emitting green light, and a light-emitting device emitting red light, three kinds of island-shaped light-emitting layers can be formed by forming a light-emitting layer and performing processing three times by photolithography.

Here, for the characteristics of the light-emitting device, the state of an interface between the pixel electrode and the EL layer is important. In the formation process of the island-shaped light-emitting layers, the pixel electrode of the light-emitting device of the color formed second or later is sometimes damaged by the preceding step. In this case, the driving voltage of the light-emitting device of the color formed second or later might be high. Furthermore, the light-emitting device of the color formed third receives more damage on its pixel electrode than the light-emitting device of the color formed second, and thus the characteristics of the former light-emitting device are also affected more.

A smaller number of times of formation of the light-emitting layer and processing of the light-emitting layer by a photolithography method is preferable because a reduction in manufacturing cost and an improvement in manufacturing yield become possible.

In view of this, in the display apparatus of one embodiment of the present invention, light-emitting devices including the same light-emitting layers (which can also be regarded as the same light-emitting materials) are used for two subpixels, and a color conversion layer is used for one of the subpixels, so that a subpixel emitting red light and a subpixel emitting green light are achieved. A light-emitting device emitting light with a longer wavelength than blue light is used for each of the subpixel emitting red light and the subpixel emitting green light, and for example, a light-emitting device emitting green light is preferably used. The light-emitting device includes a light-emitting layer (or a light-emitting material) emitting green light, for example.

Here, a light-emitting device emitting light with a longer wavelength than blue light (e.g., green light) is likely to achieve higher efficiency, lower-voltage driving, and a longer lifetime more easily than a light-emitting device emitting blue light. For example, a fluorescent device is often used as the blue-light-emitting device in view of reliability. Meanwhile, a phosphorescent device can be used as the green-light-emitting device, and thus high emission efficiency can be achieved. Therefore, for a subpixel emitting red light in combination with a color conversion layer, a light-emitting device emitting light with a longer wavelength than blue light (e.g., green light) is preferably used, in which case the outcoupling efficiency and reliability of the subpixel emitting red light can be improved.

A light-emitting device emitting blue light is used for the subpixel emitting blue light. Thus, subpixels of three colors can be formed separately just by forming light-emitting devices of two colors. Accordingly, damage to the pixel electrodes of the subpixels of respective colors can be suppressed, whereby degradation of characteristics of the light-emitting devices can be inhibited.

In the method for manufacturing a display apparatus of one embodiment of the present invention, the number of times of processing of the light-emitting layer by a photolithography method is two; thus, the display apparatus can be manufactured with high yield.

A light-emitting device emitting light with a shorter wavelength (i.e., higher energy) needs a higher driving voltage; thus, a blue-light-emitting device is likely to need a higher driving voltage than a light-emitting device emitting light with a longer wavelength than blue light. In addition, the blue-light-emitting device is likely to have lower reliability than light-emitting devices of other colors.

In view of this, in manufacture of the display apparatus of one embodiment of the present invention, it is preferable that a light-emitting layer of a light-emitting device emitting light with the shortest wavelength, for example, the blue-light-emitting device, be formed first.

This enables the blue-light-emitting device to keep the favorable state of the interface between the pixel electrode and the EL layer and to be inhibited from having an increased driving voltage. In addition, the blue-light-emitting device can have a longer lifetime and higher reliability. Note that the light-emitting device emitting light with a longer wavelength than blue light has a smaller increase in driving voltage or the like than the blue-light-emitting device, resulting in a lower driving voltage and higher reliability of the display apparatus.

In a possible way of processing the light-emitting layer into an island shape, the light-emitting layer is processed directly by a photolithography method. In the case of the above way, damage to the light-emitting layer (e.g., processing damage) might significantly degrade the reliability. In view of this, in manufacture of the display apparatus of one embodiment of the present invention, a mask layer (also referred to as a sacrificial layer, a protective layer, or the like) is preferably formed over a functional layer (e.g., a carrier-blocking layer, a carrier-transport layer, or a carrier-injection layer, specifically, a hole-blocking layer, an electron-transport layer, an electron-injection layer, or the like), followed by the processing of the light-emitting layer and the functional layer into an island shape. Such a method provides a highly reliable display apparatus. A functional layer between the light-emitting layer and the mask layer can inhibit the light-emitting layer from being exposed on the outermost surface during the manufacturing process of the display apparatus and can reduce damage to the light-emitting layer.

The EL layer preferably includes a first region that is a light-emitting region (also referred to as an emission area) and a second region on the outer side of the first region. The second region can also be referred to as a dummy region or a dummy area. The first region is positioned between the pixel electrode and the common electrode. The first region is covered with the mask layer during the manufacturing process of the display apparatus, which greatly reduces damage to the first region. Accordingly, a light-emitting device with high emission efficiency and a long lifetime can be achieved. Meanwhile, the second region includes an end portion of the EL layer and the vicinity thereof, which might be damaged at least partly by being exposed to plasma, for example, in the manufacturing process of the display apparatus. By not using the second region as the light-emitting region, variation in characteristics of the light-emitting devices can be reduced.

In the case where the light-emitting layer is processed into an island shape, a layer positioned below the light-emitting layer (e.g., a carrier-injection layer, a carrier-transport layer, or a carrier-blocking layer, specifically a hole-injection layer, a hole-transport layer, an electron-blocking layer, or the like) is preferably processed into an island shape with the same pattern as the light-emitting layer. Processing a layer positioned below the light-emitting layer into an island shape with the same pattern as the light-emitting layer can reduce a leakage current (sometimes referred to as a horizontal-direction leakage current, a horizontal leakage current, or a lateral leakage current) that might be generated between adjacent subpixels. For example, in the case where the hole-injection layer is shared by adjacent subpixels, a horizontal leakage current might be generated due to the hole-injection layer. Meanwhile, in the display apparatus of one embodiment of the present invention, the light-emitting layer and the hole-injection layer can be processed into the same island shape; thus, a horizontal leakage current between adjacent subpixels is not substantially generated or can be extremely small.

In the case of performing processing by a photolithography method, for example, the EL layers might be suffer from various kinds of damage due to heating at the time of resist mask formation and exposure to an etchant or an etching gas at the time of resist mask processing or removal. In the case where a mask layer is provided over the EL layer, the EL layer might be affected by heating, an etchant, an etching gas, or the like in forming, processing, and removing the mask layer.

In addition, when steps after formation of the EL layer are performed at temperature higher than the upper temperature limit of the EL layer, deterioration of the EL layer proceeds, which might result in a decrease in the emission efficiency and reliability of the light-emitting device.

Thus, in one embodiment of the present invention, the upper temperature limit of a compound contained in the light-emitting device is preferably higher than or equal to 100° C. and lower than or equal to 180° C., further preferably higher than or equal to 120° C. and lower than or equal to 180° C., still further preferably higher than or equal to 140° C. and lower than or equal to 180° C.

Examples of indicators of the upper temperature limit include the glass transition point (Tg), the softening point, the melting point, the thermal decomposition temperature, and the 5% weight loss temperature. For example, as an indicator of the upper temperature limit of a layer included in the EL layer, a glass transition point of a material contained in the layer can be used. In the case where the layer is a mixed layer formed of a plurality of materials, a glass transition point of a material contained in the highest proportion can be used, for example. Alternatively, the lowest temperature among the glass transition points of the materials may be used.

In particular, the upper temperature limit of the functional layers provided over the light-emitting layer is preferably high. It is further preferable that the upper temperature limit of the functional layer provided over and in contact with the light-emitting layer be high. When the functional layer has high heat resistance, the light-emitting layer can be effectively protected and less damaged.

In addition, it is particularly preferable that the upper temperature limit of the light-emitting layer be high. In this case, the light-emitting layer can be inhibited from being damaged by heating and being decreased in emission efficiency and lifetime.

Increasing the upper temperature limit of the light-emitting device can increase the reliability of the light-emitting device. Furthermore, the allowable temperature range in the manufacturing process of the display apparatus can be widened, thereby improving the manufacturing yield and the reliability.

Note that it is not necessary to form all layers of EL layers separately between light-emitting devices emitting light of different colors, and some layers of the EL layers can be formed in the same step. In the method for manufacturing the display apparatus of one embodiment of the present invention, some layers included in the EL layer are formed into an island shape separately for each color, and then at least part of the mask layer is removed. After that, other layers (sometimes referred to as common layers) included in the EL layers and a common electrode (also referred to as an upper electrode) are formed so as to be shared by the light-emitting devices of respective colors (formed as one film). For example, the carrier-injection layer and the common electrode can be formed so as to be shared by the light-emitting devices of respective colors.

The carrier-injection layer is often a layer having relatively high conductivity in the EL layer. Therefore, when the carrier-injection layer is in contact with a side surface of any layer included in the EL layer formed in an island shape or a side surface of the pixel electrode, the light-emitting device might be short-circuited. Note that also in the case where the carrier-injection layer is formed in an island shape and the common electrode is formed to be shared by the light-emitting devices of respective colors, the light-emitting device might be short-circuited when the common electrode is in contact with the side surface of the EL layer or the side surface of the pixel electrode.

In view of this, the display apparatus of one embodiment of the present invention includes an insulating layer covering at least the side surface of the island-shaped light-emitting layer. The insulating layer preferably covers part of the top surface of the island-shaped light-emitting layer.

Thus, at least some layers in the EL layer formed in an island shape and the pixel electrode can be prevented from being in contact with the carrier-injection layer or the common electrode. Hence, a short circuit in the light-emitting device is inhibited, and the reliability of the light-emitting device can be improved.

In a cross-sectional view, an end portion of the insulating layer preferably has a tapered shape with a taper angle less than 90°. In this case, step disconnection of the common layer and the common electrode provided over the insulating layer can be prevented. Thus, connection defects caused by step disconnection can be inhibited. In addition, an increase in electric resistance, which is caused by local thinning of the common electrode due to a step, can be inhibited.

Note that in this specification and the like, step disconnection refers to a phenomenon in which a layer, a film, or an electrode is split because of the shape of the formation surface (e.g., a step).

Thus, in the method for manufacturing a display apparatus of one embodiment of the present invention, an island-shaped light-emitting layer is formed by processing a light-emitting layer formed on the entire surface, not by using a fine metal mask. Accordingly, a high-resolution display apparatus or a display apparatus with a high aperture ratio, which has been difficult to be formed so far, can be achieved. Moreover, light-emitting layers can be formed separately for each color, enabling the display apparatus to perform extremely clear display with high contrast and high display quality. Moreover, providing the mask layer over the light-emitting layer can reduce damage to the light-emitting layer in the manufacturing process of the display apparatus, resulting in an increase in reliability of the light-emitting device.

It is difficult to reduce the distance between adjacent light-emitting devices to less than 10 μm with a formation method using a metal mask, for example. However, the method using photolithography according to one embodiment of the present invention can shorten the distance between adjacent light-emitting devices, adjacent EL layers, or adjacent pixel electrodes to less than 10 μm, 5 μm or less, 3 μm or less, 2 μm or less, 1.5 μm or less, or even 1 μm or less, for example, in a process over a glass substrate. Using a light exposure apparatus for LSI can further shorten the distance between adjacent light-emitting devices, adjacent EL layers, or adjacent pixel electrodes to 500 nm or less, 200 nm or less, 100 nm or less, or even 50 nm or less, for example, in a process over a Si wafer. Accordingly, the area of a non-light-emitting region that may exist between two light-emitting devices can be significantly reduced, and the aperture ratio can be close to 100%. For example, the display apparatus of one embodiment of the present invention can have an aperture ratio higher than or equal to 40%, higher than or equal to 50%, higher than or equal to 60%, higher than or equal to 70%, higher than or equal to 80%, or higher than or equal to 90%, and lower than 100%.

Increasing the aperture ratio of the display apparatus can improve the reliability of the display apparatus. Specifically, with reference to the lifetime of a display apparatus including an organic EL device and having an aperture ratio of 10%, a display apparatus having an aperture ratio of 20% (that is, having an aperture ratio two times higher than the reference) has a lifetime 3.25 times longer than the reference, and a display apparatus having an aperture ratio of 40% (that is, having an aperture ratio four times higher than the reference) has a lifetime 10.6 times longer than the reference. Thus, the density of a current flowing to the organic EL device to obtain a certain display can be reduced with an increasing aperture ratio, and accordingly the lifetime of the display apparatus can be increased. The display apparatus of one embodiment of the present invention can have a higher aperture ratio and thus can have higher display quality. Furthermore, the display apparatus of one embodiment of the present invention has excellent effect that the reliability (especially the lifetime) can be significantly improved with an increasing aperture ratio.

Furthermore, a pattern of the light-emitting layer itself (also referred to as processing size) can be made much smaller than that in the case of using a fine metal mask. For example, in the case of using a metal mask for forming light-emitting layers separately, a variation in the thickness occurs between the center and the edge of the light-emitting layer. This causes a reduction in an effective area that can be used as a light-emitting region with respect to the area of the light-emitting layer. In contrast, in the above manufacturing method, the film with a uniform thickness is processed, so that island-shaped light-emitting layers can be formed to have a uniform thickness. Accordingly, even with a fine pattern, almost all the area of the light-emitting layer can be used as a light-emitting region. Thus, a display apparatus having both a high resolution and a high aperture ratio can be manufactured. Furthermore, the display apparatus can be reduced in size and weight.

Specifically, for example, the display apparatus of one embodiment of the present invention can have a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

In this embodiment, cross-sectional structures of the display apparatus of one embodiment of the present invention are mainly described, and a method for manufacturing the display apparatus of one embodiment of the present invention will be described in detail in Embodiment 2.

FIG. 1A is a top view of a display apparatus 100. The display apparatus 100 includes a display portion in which a plurality of pixels 110 are arranged, and a connection portion 140 outside the display portion. A plurality of subpixels are arranged in a matrix in the display portion. FIG. 1A illustrates subpixels arranged in two rows and six columns, which form pixels 110 in two rows and two columns. The connection portion 140 can also be referred to as a cathode contact portion.

The top surface shape of the subpixel illustrated in FIG. 1A corresponds to the top surface shape of a light-emitting region. In this specification and the like, a top surface shape refers to a shape in a plan view, i.e., a shape seen from above.

Examples of a top surface shape of the subpixel include polygons such as a triangle, a tetragon (including a rectangle, a rhombus, and a square), and a pentagon; polygons with rounded corners; an ellipse; and a circle.

The range of the circuit layout for forming the subpixels is not limited to the range of the subpixels illustrated in FIG. 1A, and the components of the circuit may be placed outside the range of the subpixels. For example, transistors included in a subpixel 11R may be positioned within the range of a subpixel 11G illustrated in FIG. 1A, or some or all of the transistors may be positioned outside the range of the subpixel 11R.

Although the subpixels 11R, 11G, and 11B have the same or substantially the same aperture ratio (also referred to as size or size of a light-emitting region) in FIG. 1A, one embodiment of the present invention is not limited thereto. Note that the aperture ratio of each of the subpixels 11R, 11G, and 11B can be determined as appropriate. The subpixels 11R, 11G, and 11B may have different aperture ratios, or two or more of the subpixels 11R, 11G, and 11B may have the same or substantially the same aperture ratio.

The pixel 110 illustrated in FIG. 1A employs stripe arrangement. The pixel 110 illustrated in FIG. 1A includes three subpixels of the subpixel 11R, the subpixel 11G, and the subpixel 11B. The subpixels 11R, 11G, and 11B emit light of different colors. The subpixels 11R, 11G, and 11B can be of three colors of red (R), green (G), and blue (B) or three colors of yellow (Y), cyan (C), and magenta (M), for example. The number of types of subpixels is not limited to three, and four or more types of subpixels may be used. The four types of subpixels can emit light of four colors of R, G, B, and white (W), four colors of R, G, B, and Y, or four types of R, G, B, and infrared (IR) light, for example.

In this specification and the like, the row direction is referred to as X direction and the column direction is referred to as Y direction, in some cases. The X direction and the Y direction intersect with each other and are, for example, orthogonal to each other (see FIG. 1A). FIG. 1A illustrates an example where subpixels of different colors are arranged in the X direction and subpixels of the same color are arranged in the Y direction.

Although the top view in FIG. 1A illustrates an example where the connection portion 140 is positioned in the lower side of the display portion, the position of the connection portion 140 is not limited thereto. The connection portion 140 is provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of the connection portions 140 can be one or more.

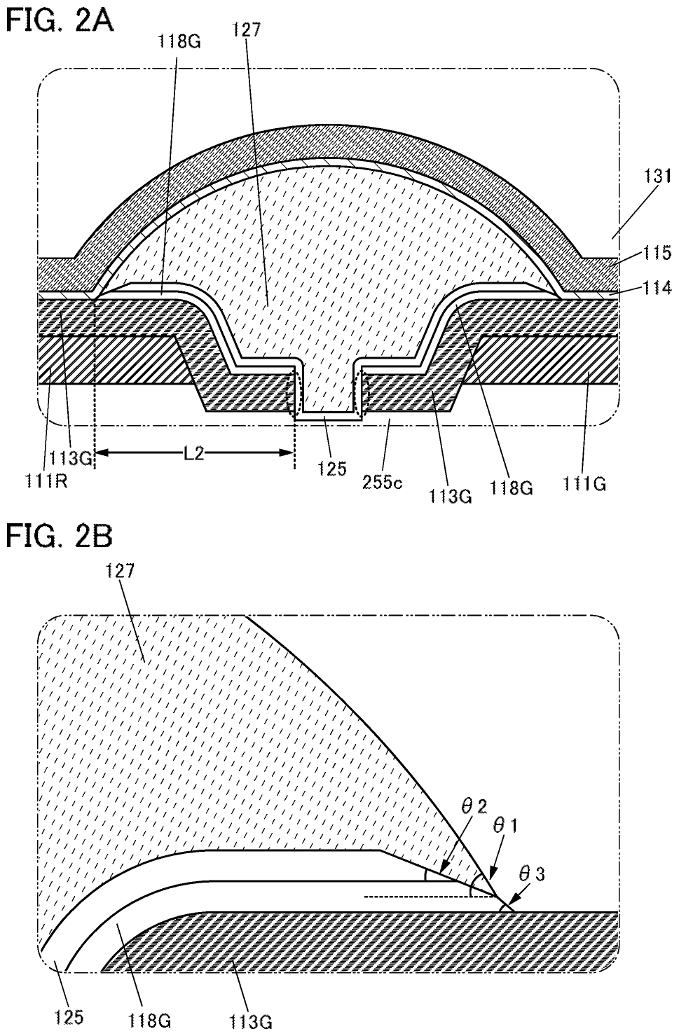

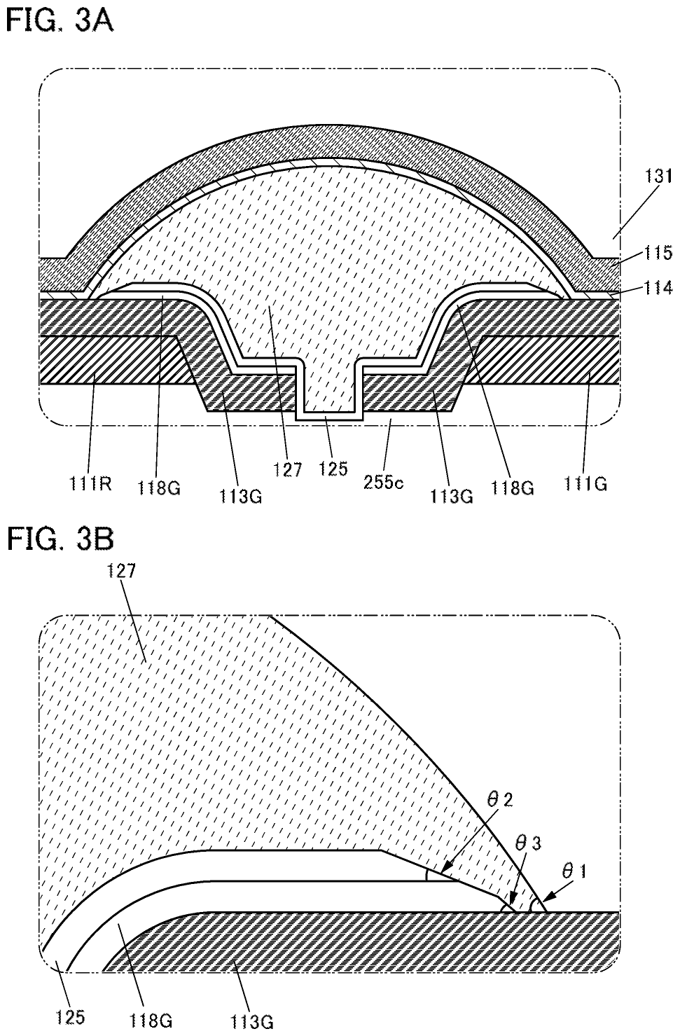

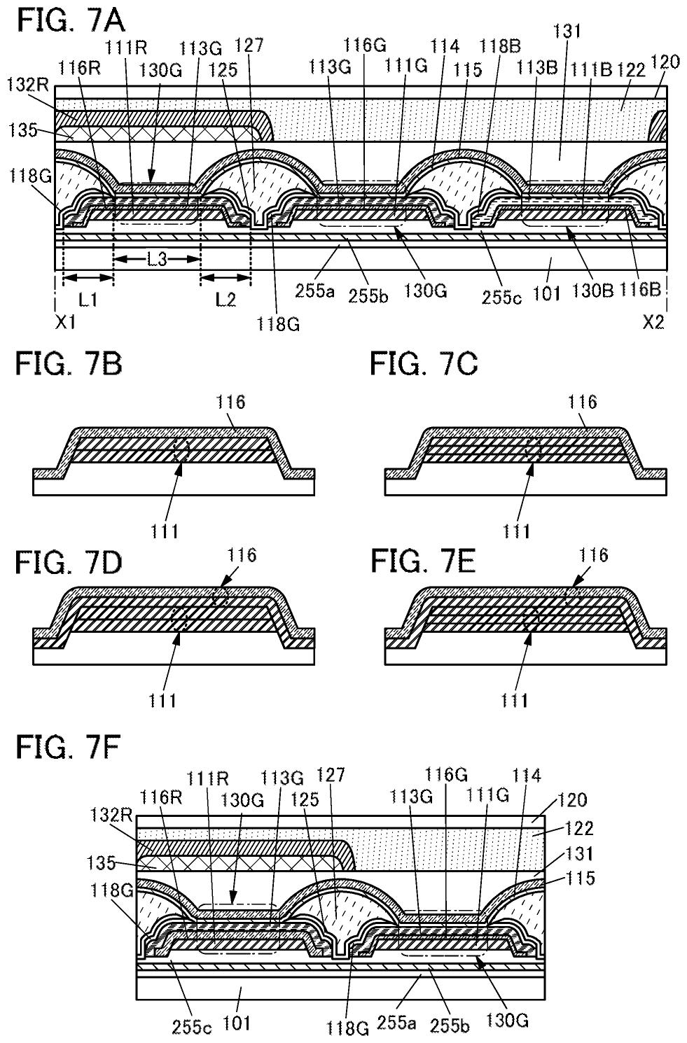

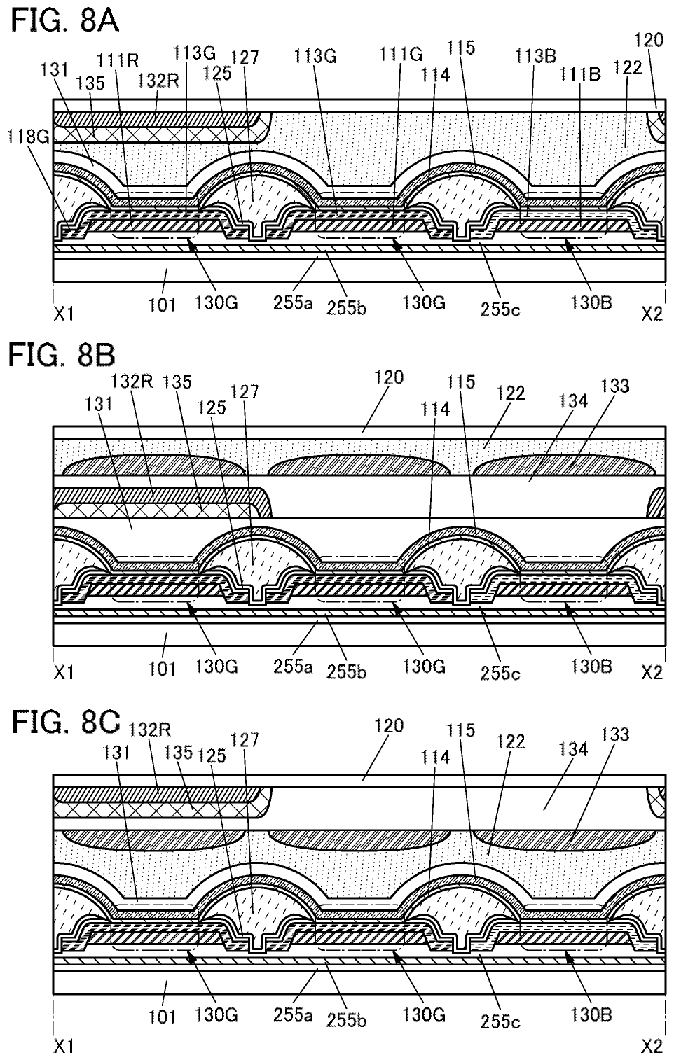

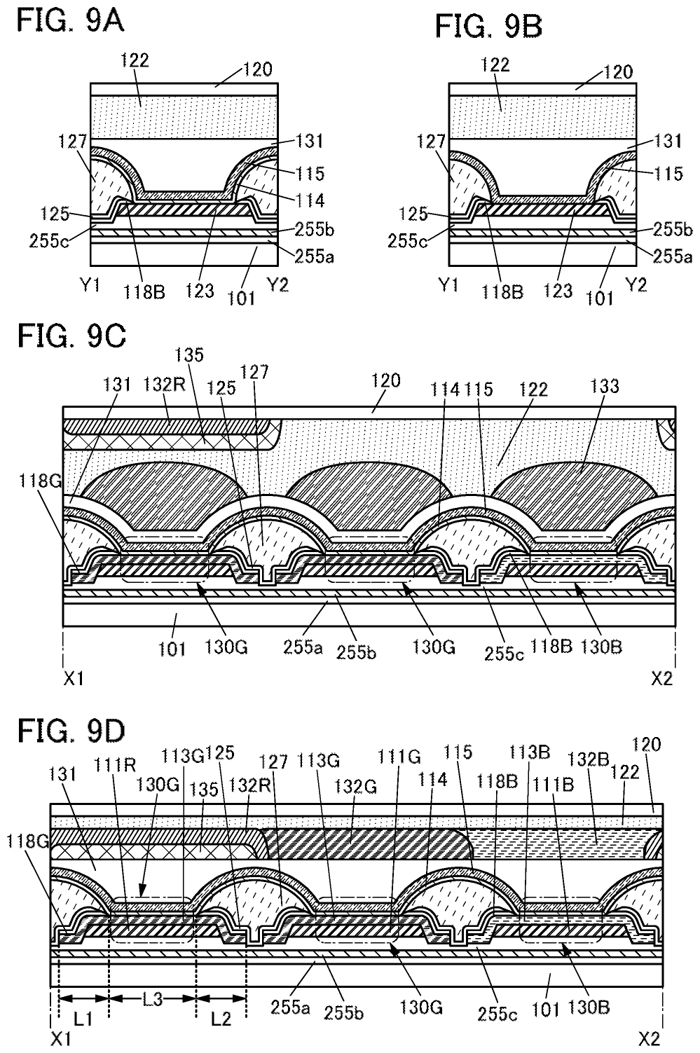

FIG. 1B is a cross-sectional view along the dashed-dotted line X1-X2 in FIG. 1A. FIG. 1C is a top view of the layer 113G. FIGS. 2A and 2B are enlarged views of part of the cross-sectional view in FIG. 1B. FIGS. 3A and 3B, FIGS. 4A and 4B, FIGS. 5A and 5B, and FIGS. 6A and 6B illustrate variation examples of FIGS. 2A and 2B. FIG. 7A, FIGS. 8A to 8C, and FIGS. 9C and 9D illustrate variation examples of FIG. 1B. FIGS. 7B to 7E are cross-sectional views illustrating variation examples of the pixel electrode. FIG. 7F illustrates a variation example of FIG. 7A. FIGS. 9A and 9B are cross-sectional views along the dashed-dotted line Y1-Y2 in FIG. 1A.

The subpixel 11R includes a light-emitting device 130G emitting green light and a color conversion layer 135 converting green light into red light. Thus, light emitted from the light-emitting device 130G is extracted as red light to the outside of the display apparatus through the color conversion layer 135.

The subpixel 11R preferably further includes a coloring layer 132R transmitting red light. In some cases, part of green light emitted from the light-emitting device 130G passes through the color conversion layer 135 without being converted. The light passing through the color conversion layer 135 is extracted through the coloring layer 132R, so that light except red light can be absorbed by the coloring layer 132R and the color purity of light emitted from the subpixel 11R can be increased.

The subpixel 11G includes the light-emitting device 130G emitting green light. Thus, light emitted from the light-emitting device 130G is extracted as green light to the outside of the display apparatus. Note that the subpixel 11G may further include a coloring layer transmitting green light. In this case, the color purity of light emitted from the subpixel 11G can be increased.

The subpixel 11B includes a light-emitting device 130B emitting blue light. Light emitted from the light-emitting device 130B is extracted as blue light to the outside of the display apparatus. Note that the subpixel 11B may further include a coloring layer transmitting blue light. In this case, the color purity of light emitted from the subpixel 11B can be increased.

An example of the blue light is light with a peak wavelength greater than or equal to 400 nm and less than 480 nm. An example of the green light is light with a peak wavelength greater than or equal to 480 nm and less than 580 nm. An example of the red light is light with a peak wavelength greater than or equal to 580 nm and less than or equal to 700 nm.

In the display apparatus of one embodiment of the present invention, when the emission peak wavelengths of the light-emitting devices 130G and 130B and the peak wavelength of light extracted from the subpixel 11R are compared, the emission peak wavelength of the light-emitting device 130B is the shortest, the emission peak wavelength of the light-emitting device 130G is the second shortest, and the peak wavelength of light extracted from the subpixel 11R is the longest.

As the color conversion layer, one or both of a phosphor and a quantum dot (QD) is preferably used. In particular, a quantum dot has an emission spectrum with a narrow peak, so that emission with high color purity can be obtained. Thus, the display quality of the display apparatus can be improved.

The color conversion layer can be formed by a droplet discharge method (e.g., an inkjet method), a coating method, an imprinting method, a variety of printing methods (screen printing or offset printing), or the like. A color conversion film such as a quantum dot film may also be used.

For processing a film to be the color conversion layer, a photolithography method is preferably employed. Examples of the photolithography method include a method in which a resist mask is formed over a thin film to be processed, the thin film is processed by etching or the like, and the resist mask is removed, and a method in which a photosensitive thin film is formed, and the photosensitive thin film is exposed to light and developed to be processed into a desired shape. For example, a thin film is formed using a material in which a quantum dot is mixed with a photoresist, and the thin film is processed by a photolithography method, whereby an island-shaped color conversion layer can be formed.

There is no limitation on a material of quantum dots, and examples include a Group 14 element, a Group 15 element, a Group 16 element, a compound of a plurality of Group 14 elements, a compound of an element belonging to any of Groups 4 to 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and a combinations thereof. What is called an alloyed quantum dot, whose composition is represented by a given ratio, may be used.

Examples of the quantum dot include a core quantum dot, a core-shell quantum dot, and a core-multishell quantum dot. Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It is also possible to reduce reactivity and improve electrical stability.

Since band gaps of quantum dots are increased as their size is decreased, the size is adjusted as appropriate so that light with a desired wavelength can be obtained. Light emission from the quantum dots is shifted to a blue color side, i.e., a high energy side, as the crystal size is decreased; thus, the emission wavelengths of the quantum dots can be adjusted over a wavelength range in the spectrum of an ultraviolet region, a visible light region, and an infrared region by changing the size of the quantum dots. The range of size (diameter) of quantum dots is, for example, greater than or equal to 0.5 nm and less than or equal to 20 nm, preferably greater than or equal to 1 nm and less than or equal to 10 nm. The emission spectra are narrowed as the size distribution of quantum dots gets smaller, and thus light can be obtained with high color purity. The shape of quantum dots is not limited to a particular shape and may be a spherical shape, a rod shape, a circular shape, or the like. A quantum rod, which is a rod-shaped quantum dot, has a function of emitting directional light.

The coloring layer is a colored layer that selectively transmits light in a specific wavelength range and absorbs light in the other wavelength ranges. As the coloring layer 132R, a color filter transmitting light in the red wavelength range can be used, for example. As the coloring layer in the subpixel 11G, a color filter transmitting light in the green wavelength range can be used. As the coloring layer in the subpixel 11B, a color filter transmitting light in the blue wavelength range can be used. Examples of materials that can be used for the coloring layer include a metal material, a resin material, and a resin material containing a pigment or dye.

As illustrated in FIG. 1B, the display apparatus 100 includes insulating layers over a layer 101 including transistors, the light-emitting devices 130G and 130B over the insulating layers, and a protective layer 131 provided to cover these light-emitting devices. The color conversion layer 135 and the coloring layer 132R are stacked over the protective layer 131, and a substrate 120 is bonded over the protective layer 131 and the coloring layer 132R with a resin layer 122. The color conversion layer 135 and the coloring layer 132R are provided at a position overlapping with the light-emitting device 130G included in the subpixel 11R. In a region between adjacent light-emitting devices, an insulating layer 125 and an insulating layer 127 over the insulating layer 125 are provided.

Although FIG. 1B illustrates cross sections of a plurality of insulating layers 125 and a plurality of insulating layers 127, the insulating layers 125 are connected to each other and the insulating layers 127 are connected to each other when the display apparatus 100 is seen from above. In other words, the display apparatus 100 can have a structure including one insulating layer 125 and one insulating layer 127, for example. Note that the display apparatus 100 may include a plurality of insulating layers 125 that are separated from each other and a plurality of insulating layers 127 that are separated from each other.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 101 including transistors can employ a stacked-layer structure in which a plurality of transistors are provided over a substrate and an insulating layer is provided to cover these transistors, for example. The insulating layer over the transistors may have a single-layer structure or a stacked-layer structure. In FIG. 1B, an insulating layer 255a, an insulating layer 255b over the insulating layer 255a, and an insulating layer 255c over the insulating layer 255b are illustrated as the insulating layer over the transistors. These insulating layers may have a depressed portion between adjacent light-emitting devices. In the example illustrated in FIG. 1B and the like, the insulating layer 255c has a depressed portion. Note that the insulating layer 255c does not necessarily include a depressed portion between adjacent light-emitting devices. Note that the insulating layers (the insulating layers 255a to 255c) over the transistors may be regarded as part of the layer 101 including transistors.

As each of the insulating layers 255a, 255b, and 255c, any of a variety of inorganic insulating films such as an oxide insulating film, a nitride insulating film, an oxynitride insulating film, and a nitride oxide insulating film can be suitably used. As the insulating layers 255a and 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as the insulating layers 255a and 255c and a silicon nitride film be used as the insulating layer 255b. The insulating layer 255b preferably has a function of an etching protective film.

Note that in this specification and the like, oxynitride refers to a material that contains more oxygen than nitrogen, and nitride oxide refers to a material that contains more nitrogen than oxygen. For example, silicon oxynitride refers to a material that contains more oxygen than nitrogen, and silicon nitride oxide refers to a material that contains more nitrogen than oxygen.

Structure examples of the layer 101 including transistors will be described in Embodiment 4.

The light-emitting device 130G emits green (G) light, and the light-emitting device 130B emits blue (B) light.

As the light-emitting device, an organic light-emitting diode (OLED) or a quantum-dot light-emitting diode (QLED) is preferably used, for example. Examples of a light-emitting substance contained in the light-emitting device include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material). A light-emitting diode (LED) such as a micro-LED can also be used as the light-emitting device.

The light-emitting device can emit infrared, red, green, blue, cyan, magenta, yellow, or white light, for example. When the light-emitting device has a microcavity structure, the color purity can be further increased.

Description in Embodiment 5 can be referred to for the structure and the materials of the light-emitting device.

One of the pair of electrodes of the light-emitting device functions as an anode, and the other electrode functions as a cathode. The case where the pixel electrode functions as an anode and the common electrode functions as a cathode is described below as an example in some cases.

The light-emitting device 130G included in the subpixel 11R includes a pixel electrode 111R over the insulating layer 255c, the island-shaped layer 113G over the pixel electrode 111R, a common layer 114 over the island-shaped layer 113G, and a common electrode 115 over the common layer 114. In the light-emitting device 130G, the layer 113G and the common layer 114 can be collectively referred to as an EL layer.

The light-emitting device 130G included in the subpixel 11G includes a pixel electrode 111G over the insulating layer 255c, the island-shaped layer 113G over the pixel electrode 111G, the common layer 114 over the island-shaped layer 113G, and the common electrode 115 over the common layer 114.

The light-emitting device 130B includes a pixel electrode 111B over the insulating layer 255c, an island-shaped layer 113B over the pixel electrode 111B, the common layer 114 over the island-shaped layer 113B, and the common electrode 115 over the common layer 114. In the light-emitting device 130B, the layer 113B and the common layer 114 can be collectively referred to as an EL layer.

In this specification and the like, in the EL layers included in the light-emitting devices, the island-shaped layer provided in each light-emitting device is referred to as the layer 113G or the layer 113B, and the layer shared by the plurality of light-emitting devices is referred to as the common layer 114. Note that in this specification and the like, only the layers 113G and 113B are sometimes referred to as island-shaped EL layers, EL layers formed in an island shape, or the like, in which case the common layer 114 is not included in the EL layer.

The layers 113G and 113B are isolated from each other. When the EL layer is provided in an island shape for each light-emitting device, a leakage current between adjacent light-emitting devices can be inhibited. This can prevent crosstalk due to unintended light emission, so that a display apparatus with extremely high contrast can be obtained. Specifically, a display apparatus having high current efficiency at low luminance can be obtained.

The end portions of the pixel electrodes 111R, 111G, and 111B each preferably have a tapered shape. Specifically, the end portions of the pixel electrodes 111R, 111G, and 111B each preferably have a tapered shape with a taper angle less than 90°. In the case where the end portions of the pixel electrodes have a tapered shape, the layers 113G and 113B provided along side surfaces of the pixel electrodes have an inclined portion. When the side surface of the pixel electrode has a tapered shape, coverage with the EL layer provided along the side surface of the pixel electrode can be improved.

FIG. 1B and the like illustrate a structure in which an angle formed by the insulating layer 255b and the sidewall of the depressed portion provided in the insulating layer 255c is almost equal to the taper angle of the tapered shape of the pixel electrodes 111R, 111G and 111B; however, one embodiment of the present invention is not limited thereto. For example, the tapered shape of the pixel electrodes 111R, 111G, and 111B may be different from that of the sidewall of the depressed portion formed in the insulating layer 255c.

In FIG. 1B, an insulating layer (also referred to as a partition wall, a bank, a spacer, or the like) covering a top end portion of the pixel electrode 111R is not provided between the pixel electrode 111R and the layer 113G. An insulating layer covering an end portion of the top surface of the pixel electrode 111G is not provided between the pixel electrode 111G and the layer 113G. Thus, the distance between adjacent light-emitting devices can be extremely shortened. Accordingly, the display apparatus can have a high resolution or a high definition. In addition, a mask for forming the insulating layer is not needed, which leads to a reduction in manufacturing cost of the display apparatus.

Furthermore, light emitted from the EL layer can be extracted efficiently with a structure where an insulating layer covering the end portion of the pixel electrode is not provided between the pixel electrode and the EL layer, i.e., a structure where an insulating layer is not provided between the pixel electrode and the EL layer. Therefore, the display apparatus of one embodiment of the present invention can significantly reduce the viewing angle dependence. A reduction in the viewing angle dependence leads to an increase in visibility of an image on the display apparatus. For example, in the display apparatus of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction.

The light-emitting device of this embodiment may have either a single structure (a structure including only one light-emitting unit) or a tandem structure (a structure including a plurality of light-emitting units). The light-emitting unit includes at least one light-emitting layer.

The layers 113G and 113B each include at least a light-emitting layer. The layer 113G can include a light-emitting layer emitting green light. The layer 113B can include a light-emitting layer emitting blue light. In other words, the layer 113G can contain a light-emitting material emitting green light, for example. The layer 113B can contain a light-emitting material emitting blue light.

In the case of using a light-emitting device having a tandem structure, the layer 113G preferably includes a plurality of light-emitting units each emitting green light, for example. The layer 113B preferably includes a plurality of light-emitting units each emitting blue light. A charge-generation layer is preferably provided between the light-emitting units. A light-emitting device having the tandem structure can achieve high-luminance emission.

The layers 113G and 113B may each include one or more of a hole-injection layer, a hole-transport layer, a hole-blocking layer, a charge-generation layer, an electron-blocking layer, an electron-transport layer, and an electron-injection layer.

For example, the layers 113G and 113B may each include a hole-injection layer, a hole-transport layer, a light-emitting layer, and an electron-transport layer in this order. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

Alternatively, the layers 113G and 113B may each include an electron-injection layer, an electron-transport layer, a light-emitting layer, and a hole-transport layer in this order, for example. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

Thus, the layers 113G and 113B each preferably include the light-emitting layer and a carrier-transport layer (an electron-transport layer or a hole-transport layer) over the light-emitting layer. Alternatively, the layers 113G and 113B each preferably include a light-emitting layer and a carrier-blocking layer (a hole-blocking layer or an electron-blocking layer) over the light-emitting layer. Alternatively, the layers 113G and 113B each preferably include a light-emitting layer, a carrier-blocking layer over the light-emitting layer, and a carrier-transport layer over the carrier-blocking layer. Since the surfaces of the layers 113G and 113B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be improved.

The upper temperature limit of the compounds contained in the layers 113G and 113B is preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition point (Tg) of these compounds is preferably higher than or equal to 100° C. and lower than or equal to 180° C., further preferably higher than or equal to 120° C. and lower than or equal to 180° C., still further preferably higher than or equal to 140° C. and lower than or equal to 180° C.

In particular, the upper temperature limit of the functional layers provided over the light-emitting layer is preferably high. It is further preferable that the upper temperature limit of the functional layer provided over and in contact with the light-emitting layer be high. When the functional layer has high heat resistance, the light-emitting layer can be effectively protected and less damaged.

In addition, the upper temperature limit of the light-emitting layer is preferably high. This can prevent the light-emitting layer from being damaged by heating and being decreased in emission efficiency and lifetime.

The light-emitting layer contains a light-emitting substance (also referred to as a light-emitting material, a light-emitting organic compound, a guest material, or the like) and an organic compound (also referred to as a host material or the like). Since the light-emitting layer contains more organic compound than light-emitting substance, Tg of the organic compound can be used as an indicator of the upper temperature limit of the light-emitting layer.

At least one of the layers 113G and 113B may include a first light-emitting unit, a charge-generation layer over the first light-emitting unit, and a second light-emitting unit over the charge-generation layer, for example.

It is preferable that the second light-emitting unit include a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the manufacturing process of the display apparatus, providing one or both of the carrier-transport layer over the light-emitting layer inhibits the light-emitting layer from being exposed on the outermost surface, so that damage to the light-emitting layer can be reduced. Accordingly, the reliability of the light-emitting device can be increased. Note that in the case where three or more light-emitting units are provided, the uppermost light-emitting unit preferably includes a light-emitting layer and one or both of a carrier-transport layer and a carrier-blocking layer over the light-emitting layer.

The common layer 114 includes, for example, an electron-injection layer or a hole-injection layer. Alternatively, the common layer 114 may be a stack of an electron-transport layer and an electron-injection layer, or may be a stack of a hole-transport layer and a hole-injection layer. The common layer 114 is shared by the light-emitting devices 130G and 130B.

FIG. 1B illustrates an example where the end portion of the layer 113G is positioned on the outer side of the end portion of the pixel electrode 111R. Note that although the pixel electrode 111R and the layer 113G are given as an example, the following description applies to the pixel electrode 111G and the layer 113G, and the pixel electrode 111B and the layer 113B.

In FIG. 1B, the layer 113G is formed to cover the end portion of the pixel electrode 111R. Such a structure enables the entire top surface of the pixel electrode to be a light-emitting region, and the aperture ratio can be easily increased as compared with the structure where the end portion of the island-shaped EL layer is positioned on the inner side of the end portion of the pixel electrode.

Covering the side surface of the pixel electrode with the EL layer inhibits contact between the pixel electrode and the common electrode 115, thereby inhibiting a short circuit of the light-emitting device. Furthermore, the distance between the light-emitting region (i.e., the region overlapping with the pixel electrode) in the EL layer and the end portion of the EL layer can be increased. Since the end portion of the EL layer might be damaged by processing, the use of a region away from the end portion of the EL layer as a light-emitting region can improve the reliability of the light-emitting device in some cases.

The layers 113G and 113B each preferably include the first region that is a light-emitting region and the second region (dummy region) on the outer side of the first region. The first region is positioned between the pixel electrode and the common electrode. The first region is covered with the mask layer during the manufacturing process of the display apparatus, which greatly reduces damage to the first region. Accordingly, a light-emitting device with high emission efficiency and a long lifetime can be achieved. Meanwhile, the second region includes an end portion of the EL layer the vicinity thereof, which might be damaged due to exposure to plasma, for example, in the manufacturing process of the display apparatus. By not using the second region as the light-emitting region, variation in characteristics of the light-emitting devices can be reduced.

A width L3 illustrated in FIGS. 1B and 1C corresponds to the width of a first region 113_1 (light-emitting region) in the layer 113G. A width L1 and a width L2 illustrated in FIGS. 1B and 1C each correspond to the width of a second region 113_2 (dummy region) in the layer 113G. As illustrated in FIG. 1C, the second region 113_2 is provided to surround the first region 113_1; thus, the width of the second region 113_2 can be observed on the left and right sides of the layer 113G in the cross-sectional views in FIG. 1B and the like. The width of the second region 113_2 can be the width L1 or L2, and may be the shorter one of the widths L1 and L2, for example. The widths L1 to L3 can be observed in a cross-sectional observation image or the like. Although description is made using a cross-sectional view in the X direction as an example in this embodiment, the widths of the light-emitting region and the dummy region can be observed also in a cross-sectional view in the Y direction.

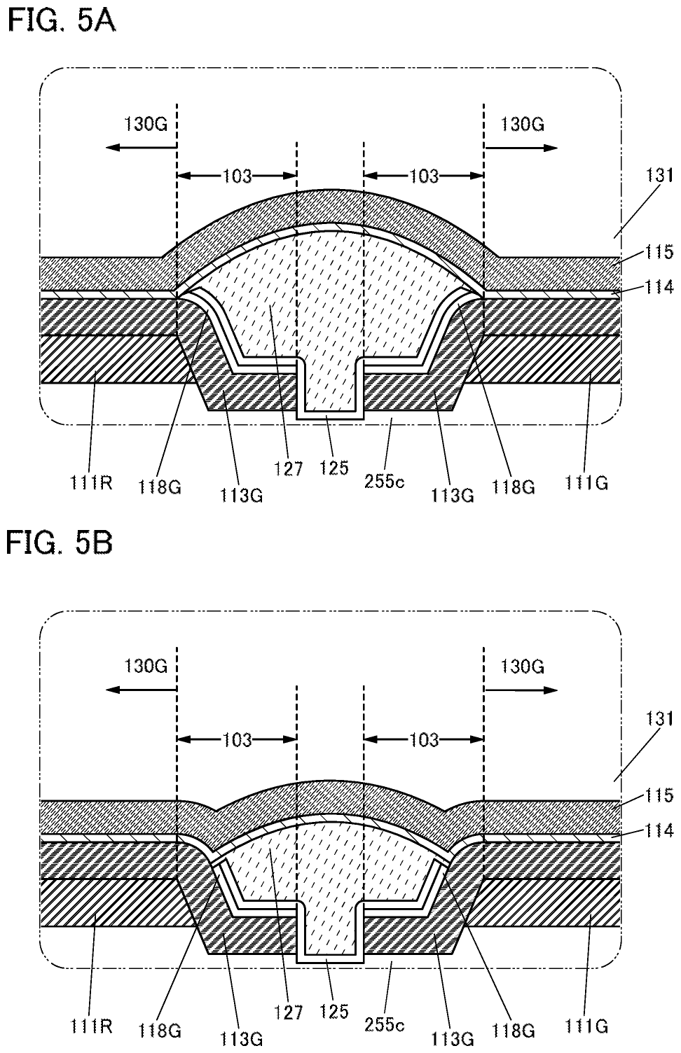

The enlarged view in FIG. 2A illustrates the width L2 of the second region 113_2. The second region 113_2 is a portion where the layer 113G overlaps with at least one of a mask layer 118G, the insulating layer 125, and the insulating layer 127. In the layer 113G or the like, a portion positioned on the outer side of the end portion of the top surface of the pixel electrode, like a region 103 illustrated in FIG. 5B, is a dummy region.

The width of the second region 113_2 is greater than or equal to 1 nm, preferably greater than or equal to 5 nm, greater than or equal to 50 nm, or greater than or equal to 100 nm. The width of the dummy region is preferably wider, in which case the quality of the light-emitting region can be more uniform and the light-emitting devices can have less variation in characteristics. In contrast, a narrower width of the dummy region can widen the light-emitting region and increase the aperture ratio of the pixel. Thus, the width of the second region 113_2 is preferably less than or equal to 50%, further preferably less than or equal to 40%, less than or equal to 30%, less than or equal to 20%, or less than or equal to 10% of the width L3 of the first region 113_1. Furthermore, for example, the width of the second region 113_2 in a small and high-resolution display apparatus, such as a display apparatus for a wearable device, is preferably less than or equal to 500 nm, further preferably less than or equal to 300 nm, less than or equal to 200 nm, or less than or equal to 150 nm.

Note that in the island-shaped EL layer, the first region (light-emitting region) is a region from which EL emission can be obtained. Furthermore, in the island-shaped EL layer, the first region (light-emitting region) and the second region (dummy region) are each a region from which photoluminescent (PL) emission can be obtained. Thus, the first and second regions can be distinguished from each other by observing EL emission and PL emission.

The common electrode 115 is shared by the light-emitting devices 130G and 130B. The common electrode 115 shared by the plurality of light-emitting devices is electrically connected to a conductive layer 123 provided in the connection portion 140 (see FIGS. 9A and 9B). The conductive layer 123 is preferably formed using a conductive layer formed using the same material and in the same step as the pixel electrode 111R, 111G, and 111B.

Note that FIG. 9A illustrates an example where the common layer 114 is provided over the conductive layer 123, and the conductive layer 123 and the common electrode 115 are electrically connected to each other through the common layer 114. The common layer 114 is not necessarily provided in the connection portion 140. In FIG. 9B, the conductive layer 123 and the common electrode 115 are directly connected to each other. For example, by using a mask for specifying a film formation area (also referred to as an area mask or a rough metal mask to be distinguished from a fine metal mask), the common layer 114 can be formed in a region different from a region where the common electrode 115 is formed.

In FIG. 1B, the mask layer 118G is positioned over the layer 113G of the light-emitting device 130G, and a mask layer 118B is positioned over the layer 113B of the light-emitting device 130B. The mask layers are provided to surround the first region 113_1 (light-emitting region). In other words, the mask layers have an opening in a portion overlapping with the light-emitting region. The top surface shape of the mask layer is the same as, substantially the same as, or similar to that of the second region 113_2 illustrated in FIG. 1C. The mask layer 118B is a remaining part of a mask layer provided in contact with the top surface of the layer 113B at the time of processing the layer 113B. Similarly, the mask layer 118G is a remaining part of a mask layer provided at the time of forming the layer 113G. Thus, the mask layer used to protect the EL layer in manufacture of the EL layer may partly remain in the display apparatus of one embodiment of the present invention. The mask layers 118G and 118B may be formed using the same material or different materials. Note that the mask layers 118G and 118B are sometimes collectively referred to as a mask layer 118 below.

In FIG. 1B, one end portion (an end portion opposite to the light-emitting region, i.e., an outer end portion) of the mask layer 118G is aligned or substantially aligned with the end portion of the layer 113G, and the other end portion of the mask layer 118G is positioned over the layer 113G. Here, the other end portion (an end portion on the light-emitting region side, i.e., an inner end portion) of the mask layer 118G preferably overlaps with the layer 113G and the pixel electrode 111R (or the pixel electrode 111G). In this case, the other end portion of the mask layer 118G is easily formed over a flat or substantially flat surface of the layer 113G. Note that the same applies to the mask layer 118B. The mask layer remains between the top surface of the island-shaped EL layer (the layer 113G or 113B) and the insulating layer 125. The mask layer will be described in detail in Embodiment 2.

In the case where end portions are aligned or substantially aligned with each other and the case where top surface shapes are the same or substantially the same, it can be said that outlines of stacked layers at least partly overlap with each other in a top view. For example, the case of patterning or partly patterning an upper layer and a lower layer with the use of the same mask pattern is included in the expression. The expression “end portions are aligned or substantially aligned with each other” or “top surface shapes are the same or substantially the same” also includes the case where the outlines do not completely overlap each other; for instance, the edge of the upper layer may be positioned on the inner side or the outer side of the edge of the lower layer.

Side surfaces of the layers 113G and 113B are each covered with the insulating layer 125. The insulating layer 127 overlaps with (covers) the side surfaces of the layers 113G and 113B with the insulating layer 125 therebetween.

The top surfaces of the layers 113G and 113B are each partly covered with the mask layer 118. The insulating layers 125 and 127 overlap with parts of the top surfaces of the layers 113G and 113B with the mask layers 118 therebetween. Note that the top surface of each of the layers 113G and 113B is not limited to the top surface of a flat portion overlapping with the top surface of the pixel electrode, and can include the top surfaces of the inclined portion and the flat portion (see the region 103 in FIG. 5A) which are positioned on the outer side of the top surface of the pixel electrode.

The side surface and part of the top surface of each of the layers 113G and 113B is covered with at least one of the insulating layer 125, the insulating layer 127, and the mask layer 118, so that the common layer 114 (or the common electrode 115) can be inhibited from being in contact with the side surfaces of the pixel electrodes 111R, 111G, and 111B and the layers 113G and 113B, leading to inhibition of a short circuit of the light-emitting devices. Accordingly, the reliability of the light-emitting devices can be improved.

Although the layers 113G and 113B have the same thickness in FIG. 1B, the present invention is not limited thereto. The layers 113G and 113B may have different thicknesses. For example, the thickness is preferably set in accordance with an optical path length for intensifying light emitted from the layer 113G or 113B. A microcavity structure can be achieved in this manner, and the color purity of each light-emitting device can be increased.

The insulating layer 125 is preferably in contact with the side surfaces of the layers 113G and 113B (see a portion surrounded by a dashed line in the end portion of the layer 113G and the vicinity thereof illustrated in FIG. 2A). The insulating layer 125 in contact with the layers 113G and 113B can prevent film separation of the layers 113G and 113B. When the insulating layer 125 is in close contact with the layers 113G and 113B, adjacent layers among the layers 113G and 113B can be fixed or bonded to each other by the insulating layer 125. In addition, contact between the insulating layer 125 and the insulating layer 255c also contributes to prevention of film separation of the layers 113G and 113B. Accordingly, the reliability of the light-emitting devices can be improved. The manufacturing yield of the light-emitting devices can also be improved.

As illustrated in FIG. 1B, the insulating layers 125 and 127 cover the side surface and part of the top surface of each of the layers 113G and 113B, whereby film separation of the EL layers can be prevented and the reliability of the light-emitting devices can be improved. The manufacturing yield of the light-emitting devices can also be improved.

In the example illustrated in FIG. 1B, the layer 113G, the mask layer 118G, the insulating layer 125, and the insulating layer 127 are stacked in the position over the end portion of the pixel electrode 111R. Similarly, the layer 113G, the mask layer 118G, the insulating layer 125, and the insulating layer 127 are stacked in the position over the end portion of the pixel electrode 111G; and the layer 113B, the mask layer 118B, the insulating layer 125, and the insulating layer 127 are stacked in the position over the end portion of the pixel electrode 111B.

In FIG. 1B and the like, the end portion of the pixel electrode 111R is covered with the layer 113G and the insulating layer 125 is in contact with the side surface of the layer 113G. Similarly, the end portion of the pixel electrode 111G is covered with the layer 113G, the end portion of the pixel electrode 111B is covered with the layer 113B, and the insulating layer 125 is in contact with the side surface of the layer 113G and the side surface of the layer 113B.

The insulating layer 127 is provided over the insulating layer 125 to fill a depressed portion formed by the insulating layer 125. The insulating layer 127 can overlap with the side surface and part of the top surface of each of the layers 113G and 113B with the insulating layer 125 therebetween. The insulating layer 127 preferably covers at least part of a side surface of the insulating layer 125.

The insulating layers 125 and 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 113G, the layer 113B, the mask layer 118, the insulating layer 125, and the insulating layer 127. Before the insulating layer 125 and the insulating layer 127 are provided, a step is generated due to a difference between a region where the pixel electrode and the island-shaped EL layer are provided and a region where neither the pixel electrode nor the island-shaped EL layer is provided (region between the light-emitting devices). In the display apparatus of one embodiment of the present invention, the step can be planarized with the insulating layer 125 and the insulating layer 127, and the coverage with the common layer 114 and the common electrode 115 can be improved. Thus, connection defects caused by step disconnection can be inhibited. In addition, an increase in electric resistance, which is caused by local thinning of the common electrode 115 due to the level difference, can be inhibited.

The top surface of the insulating layer 127 preferably has higher flatness, but may include a projection portion, a convex surface, a concave surface, or a depressed portion. For example, the top surface of the insulating layer 127 preferably has a convex shape with a highly flat and smooth surface.

Next, an example of materials for the insulating layers 125 and 127 are described.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an atomic layer deposition (ALD) method is used as the insulating layer 125, the insulating layer 125 can have few pin holes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating film against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as a function of less easily transmitting the substance). Alternatively, a barrier property refers to a function of capturing or fixing (also referred to as gettering) a particular substance.

When the insulating layer 125 has a function of the barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, it is desirable that one or both of the hydrogen concentration and the carbon concentration in the insulating layer 125 be sufficiently low.

Note that the insulating layer 125, the mask layer 118G, and the mask layer 118B can be formed using the same material. In this case, the boundary between the insulating layer 125 and the mask layer 118G or 118B is unclear and thus the layers cannot be distinguished from each other in some cases. Thus, the insulating layer 125 and the mask layer 118G or 118B are sometimes observed as one layer. In other words, in some cases, one layer is observed as being provided in contact with the side surface and part of the top surface of each of the layers 113G and 113B and the insulating layer 127 is observed as covering at least part of a side surface of the one layer.

The insulating layer 127 provided over the insulating layer 125 has a function of filling large unevenness of the insulating layer 125, which is formed between the adjacent light-emitting devices. In other words, the insulating layer 127 has an effect of improving the flatness of the formation surface of the common electrode 115.

As the insulating layer 127, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

Alternatively, the insulating layer 127 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, the insulating layer 127 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

The insulating layer 127 may be formed using a material absorbing visible light. When the insulating layer 127 absorbs light emitted from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using the resin material composed of stacked color filter materials of two or three or more colors is particularly preferred, in which case the effect of blocking visible light is enhanced. In particular, mixing color filter materials of three or more colors enables the formation of a black or nearly black resin layer.

Next, a structure of the insulating layer 127 and the vicinity thereof will be described with reference to FIGS. 2A and 2B. FIG. 2A is an enlarged cross-sectional view of a region including the insulating layer 127 between the light-emitting device 130G in the subpixel emitting red light and the light-emitting device 130G in the subpixel emitting green light, and the vicinity of the insulating layer 127. Although the insulating layer 127 between the adjacent two light-emitting devices 130G is described below as an example, the same applies to the insulating layer 127 between the light-emitting devices 130B and 130G. FIG. 2B is an enlarged view of an end portion of the insulating layer 127 over the layer 113G and the vicinity thereof illustrated in FIG. 2A. Note that the common layer 114 and the common electrode 115 are not illustrated in FIG. 2B. Although the end portion of the insulating layer 127 over the layer 113G is sometimes described below as an example, the same applies to an end portion of the insulating layer 127 over the layer 113B.

As illustrated in FIG. 2A, the layer 113G is provided to cover the pixel electrode 111R and another layer 113G is provided to cover the pixel electrode 111G. The mask layer 118G is provided in contact with part of the top surface of the layer 113G. The insulating layer 125 is provided in contact with the top and side surfaces of the mask layer 118G, the side surface of the layer 113G, and the top surface of the insulating layer 255c. The insulating layer 125 covers part of the top surface of the layer 113G. The insulating layer 127 is provided in contact with the top surface of the insulating layer 125. The insulating layer 127 overlaps with part of the top surface and side surface of the layer 113G with the insulating layer 125 therebetween, and is in contact with at least part of the side surface of the insulating layer 125. The common layer 114 is provided to cover the layer 113G, the mask layer 118G, the insulating layer 125, and the insulating layer 127, and the common electrode 115 is provided over the common layer 114.

The insulating layer 127 is formed in a region between two island-shaped EL layers (e.g., a region between the two layers 113G in FIG. 2A). At this time, at least part of the insulating layer 127 is positioned between a side end portion of one of the EL layers and a side end portion of the other of the EL layers. Providing the insulating layer 127 can prevent formation of a disconnected portion and a locally thinned portion in the common layer 114 and the common electrode 115 that are formed over the island-shaped EL layers and the insulating layer 127.

As illustrated in FIG. 2B, the end portion of the insulating layer 127 preferably has a tapered shape with a taper angle θ1 in the cross-sectional view of the display apparatus. The taper angle θ1 is an angle formed by a side surface (or end portion) of the insulating layer 127 and the substrate surface. Note that the taper angle θ1 is not limited to the angle with the substrate surface, and may be an angle formed by the side surface (end portion) of the insulating layer 127 and the top surface of the flat portion of the layer 113G or the top surface of the flat portion of the pixel electrode 111G.

The taper angle θ1 of the insulating layer 127 is less than 90°, preferably less than or equal to 60°, further preferably less than or equal to 45°, still further preferably less than or equal to 20°. When the end portion of the insulating layer 127 has such a forward tapered shape, the common layer 114 and the common electrode 115 that are provided over the insulating layer 127 can be formed with favorable coverage, thereby inhibiting step disconnection, local thinning, or the like. Accordingly, the in-place uniformity of the common layer 114 and the common electrode 115 can be improved, leading to higher display quality of the display apparatus.

As illustrated in FIG. 2A, in a cross-sectional view of the display apparatus, the top surface of the insulating layer 127 preferably has a convex shape. The convex top surface of the insulating layer 127 preferably bulges gently toward the center. It is also preferable that the convex portion in the center portion of the top surface of the insulating layer 127 be gently connected to the tapered end portion. When the insulating layer 127 has such a shape, the common layer 114 and the common electrode 115 can be formed with good coverage over the whole insulating layer 127.

As illustrated in FIG. 2B, the end portion of the insulating layer 127 is preferably positioned on the outer side of the end portion of the insulating layer 125. In this case, unevenness of the formation surface of the common layer 114 and the common electrode 115 can be reduced and coverage with the common layer 114 and the common electrode 115 can be improved.

As illustrated in FIG. 2B, the insulating layer 125 preferably has a tapered shape with a taper angle θ2 in the cross-sectional view of the display apparatus. The taper angle θ2 is an angle formed by the side surface (or end portion) of the insulating layer 125 and the substrate surface. Note that the taper angle θ2 is not limited to the angle with the substrate surface, and may be an angle formed by the side surface of the insulating layer 125 and the top surface of the flat portion of the layer 113G or the top surface of the flat portion of the pixel electrode 111G.

The taper angle θ2 of the insulating layer 125 is less than 90°, preferably less than or equal to 60°, further preferably less than or equal to 45°, still further preferably less than or equal to 20°.

As illustrated in FIG. 2B, the mask layer 118G preferably has a tapered shape with a taper angle θ3 in the cross-sectional view of the display apparatus. The taper angle θ3 is an angle formed by the side surface (or end portion) of the mask layer 118G and the substrate surface. Note that the taper angle θ3 may be an angle formed by the side surface of the mask layer 118G and the top surface of the flat portion of the layer 113G or the top surface of the flat portion of the pixel electrode 111G.

The taper angle θ3 of the mask layer 118G is less than 90°, preferably less than or equal to 60°, further preferably less than or equal to 45°, still further preferably less than or equal to 20°. When the end portion of the mask layer 118G has such a forward tapered shape, the common layer 114 and the common electrode 115 that are provided over the mask layer 118G can be formed with favorable coverage.

The end portions of the mask layers 118B and 118G are each preferably positioned on the outer side of the end portion of the insulating layer 125. In this case, unevenness of the formation surface of the common layer 114 and the common electrode 115 can be reduced and coverage with the common layer 114 and the common electrode 115 can be improved.

Although the details will be described in Embodiment 2, when the insulating layer 125 and the mask layer 118 are collectively etched, the insulating layer 125 and the mask layer 118 below the end portion of the insulating layer 127 are eliminated by side etching and accordingly a cavity (also referred to as a hole) is formed in some cases. The cavity causes unevenness in the formation surface of the common layer 114 and the common electrode 115, so that step disconnection is likely to occur in the common layer 114 and the common electrode 115. To avoid this, the etching treatment is performed twice with heat treatment performed therebetween, which enables a cavity formed by the first etching treatment to be filled with the insulating layer 127 deformed by the heat treatment. In addition, since the second etching treatment etches a thin film, the amount of side etching is small and thus a cavity is not easily formed or formed to be extremely small. Thus, generation of unevenness in the formation surface of the common layer 114 and the common electrode 115 can be inhibited and accordingly step disconnection of the common layer 114 and the common electrode 115 can be inhibited. Since the etching treatment is performed twice as described above, the taper angles θ2 and θ3 might be different from each other. The taper angles θ2 and θ3 may be the same. Each of the taper angles θ2 and θ3 might be less than the taper angle θ1.

The insulating layer 127 covers at least part of the side surface of the mask layer 118G in some cases. For example, FIG. 2B illustrates an example where the insulating layer 127 covers to be in contact with an inclined surface at an end portion of the mask layer 118G which is formed by the first etching treatment, and an inclined surface at an end portion of the mask layer 118G which is formed by the second etching treatment is exposed. In some cases, these two inclined surfaces can be distinguished from each other depending on their different taper angles. There might be almost no difference between the taper angles made at the side surfaces by the etching treatment performed twice; in this case, the inclined surfaces cannot be distinguished from each other.

As another example, FIGS. 3A and 3B illustrate an example where the insulating layer 127 covers the entire side surface of the mask layer 118G. Specifically, in FIG. 3B, the insulating layer 127 covers to be in contact with both of the two inclined surfaces. This is preferable because unevenness of the formation surface of the common layer 114 and the common electrode 115 can be further reduced. FIG. 3B illustrates an example where the end portion of the insulating layer 127 is positioned on the outer side of the end portion of the mask layer 118G. As illustrated in FIG. 2B, the end portion of the insulating layer 127 may be positioned on the inner side of the end portion of the mask layer 118G, or may be aligned or substantially aligned with the end portion of the mask layer 118G. As illustrated in FIG. 3B, the insulating layer 127 is in contact with the layer 113G in some cases.

The taper angles θ1 to 63 in FIG. 3B are also preferably within the above range.

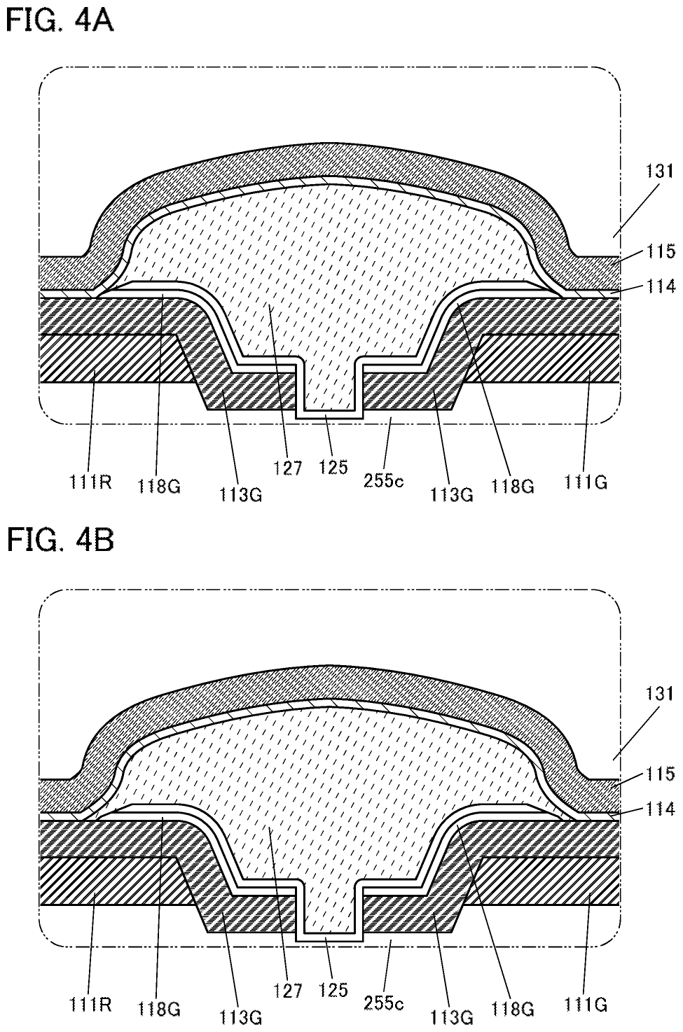

FIGS. 4A and 4B illustrate an example where the side surface of the insulating layer 127 has a concave shape (also referred to as a narrowed portion, a depressed portion, a dent, a hollow, or the like). Depending on the materials and the formation conditions (e.g., heating temperature, heating time, and heating atmosphere) of the insulating layer 127, the side surface of the insulating layer 127 has a concave shape in some cases.

FIG. 4A illustrates an example where the insulating layer 127 covers part of the side surface of the mask layer 118G and the other part of the side surface of the mask layer 118G is exposed. FIG. 4B illustrates an example where the insulating layer 127 covers to be in contact with the entire side surface of the mask layer 118G.

As illustrated in FIGS. 2A and 2B, FIGS. 3A and 3B, and FIGS. 4A and 4B, one end portion of the insulating layer 127 preferably overlaps with the top surface of the pixel electrode 111R and the other end portion of the insulating layer 127 preferably overlaps with the top surface of the pixel electrode 111G. Such a structure enables the end portion of the insulating layer 127 to be formed over a flat or substantially flat region of the layer 113G. This makes it relatively easy to form a taped shape in each of the insulating layer 127, the insulating layer 125, and the mask layer 118. In addition, film separation between the layer 113G and the pixel electrode 111R or 111G can be inhibited. Meanwhile, a portion where the top surface of the pixel electrode and the insulating layer 127 overlap with each other is preferably smaller because the light-emitting region of the light-emitting device can be wider and the aperture ratio can be higher.

Note that the insulating layer 127 does not necessarily overlap with the top surface of the pixel electrode. As illustrated in FIG. 5A, the insulating layer 127 does not necessarily overlap with the top surface of the pixel electrode, and one end portion of the insulating layer 127 may overlap with the side surface of the pixel electrode 111R and the other end portion of the insulating layer 127 may overlap with the side surface of the pixel electrode 111G. As illustrated in FIG. 5B, the insulating layer 127 does not necessarily overlap with the pixel electrode, and may be provided in a region interposed between the pixel electrodes 111R and 111G. In FIGS. 5A and 5B, part or the whole of the top surface of the layer 113G in the inclined portion and the flat portion (the region 103) positioned on the outer side of the top surface of the pixel electrode is covered with the mask layer 118, the insulating layer 125, and the insulating layer 127. Even such a structure can reduce unevenness of the formation surface of the common layer 114 and the common electrode 115 and improve the coverage with the common layer 114 and the common electrode 115, as compared with the structure where the mask layer 118, the insulating layer 125, and the insulating layer 127 are not provided. Note that the region 103 can be referred to as a dummy region.

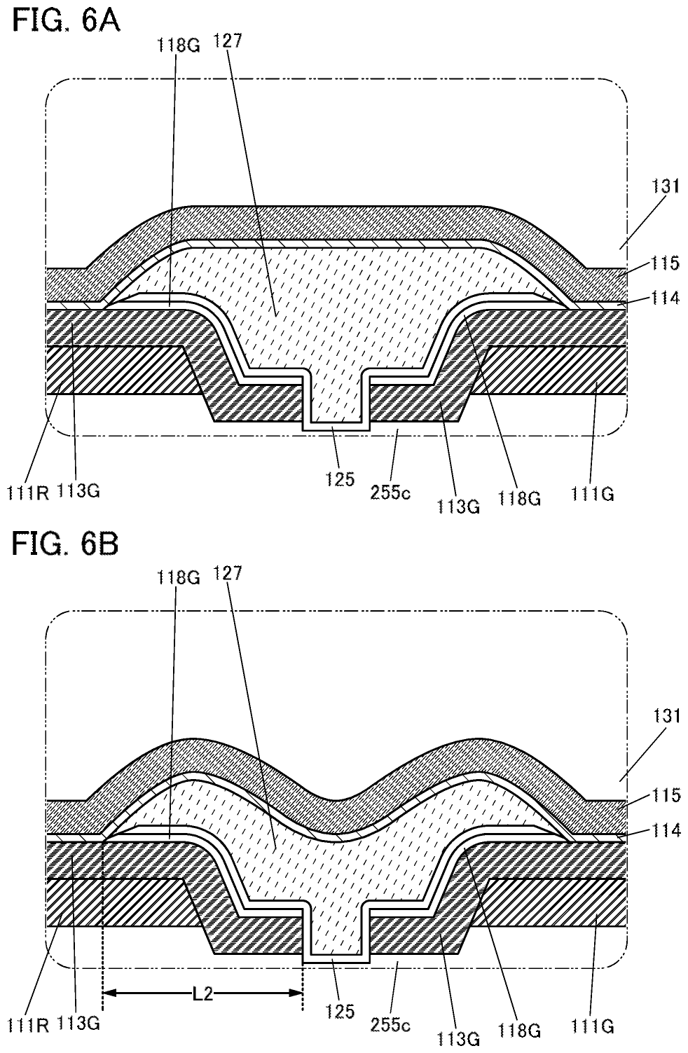

As illustrated in FIG. 6A, the top surface of the insulating layer 127 may have a flat portion in the cross-sectional view of the display apparatus.

As illustrated in FIG. 6B, the top surface of the insulating layer 127 may have a concave shape in a cross-sectional view of the display apparatus. In FIG. 6B, the top surface of the insulating layer 127 gently bulges toward the center, i.e., has convexities, and has a depressed portion in the center and its vicinity, i.e., has a concavity. In FIG. 6B, the convex portion of the top surface of the insulating layer 127 can be gently connected to the tapered end portion. Even when the insulating layer 127 has such a shape, the common layer 114 and the common electrode 115 can be formed with good coverage over the whole insulating layer 127.

For forming the insulating layer 127 including a concave surface in its center portion as illustrated in FIG. 6B, a light exposure method using a multi-tone mask (typically, a half-tone mask or a gray-tone mask) can be employed. Note that a multi-tone mask can achieve three levels of light exposure to obtain an exposed portion, a half-exposed portion, and an unexposed portion. Light has a plurality of intensity levels after passing through the multi-tone mask. The insulating layer 127 including regions with a plurality of (typically two kinds of) thicknesses can be formed with one photomask (one light exposure and development process).

Note that a method for forming a concave surface in the center portion of the insulating layer 127 is not limited to the above method. For example, an exposed portion and a half-exposed portion may be formed separately with the use of two photomasks. Alternatively, the viscosity of the resin material used for the insulating layer 127 may be adjusted, specifically to less than or equal to 10 cP, preferably greater than or equal to 1 cP and less than or equal to 5 cP.

Although not illustrated, the concave surface in the center portion of the insulating layer 127 is not necessarily continuous, and may be disconnected between adjacent light-emitting devices. In this case, part of the insulating layer 127 in the center portion illustrated in FIG. 6B is eliminated, so that the surface of the insulating layer 125 is exposed. In the case of such a structure, the common layer 114 and the common electrode 115 are formed to cover the insulating layer 125.

As described above, in each of the structures illustrated in FIGS. 2A and 2B, FIGS. 3A and 3B, FIGS. 4A and 4B, FIGS. 5A and 5B, and FIGS. 6A and 6B, the common layer 114 and the common electrode 115 can be formed with good coverage owing to the insulating layer 127, the insulating layer 125, and the mask layer 118G. It is also possible to prevent formation of a disconnected portion and a locally thinned portion in the common layer 114 and the common electrode 115. This can inhibit the common layer 114 and the common electrode 115 between adjacent light-emitting devices from having connection defects due to the disconnected portion and an increased electric resistance due to the locally thinned portion. Thus, the display quality of the display apparatus of one embodiment of the present invention can be improved.

The protective layer 131 is preferably provided over the light-emitting devices 130G and 130B. Providing the protective layer 131 can improve the reliability of the light-emitting devices. The protective layer 131 may have a single-layer structure or a stacked-layer structure including two or more layers.

There is no limitation on the conductivity of the protective layer 131. As the protective layer 131, at least one type of insulating films, semiconductor films, and conductive films can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Specific examples of these inorganic films are as listed in the description of the insulating layer 125. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stack of an aluminum oxide film and a silicon nitride film over the aluminum oxide film, or a stack of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127.

The protective layer 131 may have a stacked structure of two layers which are formed by different formation methods. Specifically, the first layer of the protective layer 131 may be formed by an ALD method, and the second layer of the protective layer 131 may be formed by a sputtering method.

A light-blocking layer may be provided on the surface of the substrate 120 on the resin layer 122 side. Moreover, a variety of optical members can be provided on the outer surface of the substrate 120 (the surface opposite to the resin layer 122). Examples of optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, it is preferable to provide, as the surface protective layer, a glass layer or a silica layer (SiOₓ layer) because the surface contamination or damage can be prevented. The surface protective layer may be formed using diamond like carbon (DLC), aluminum oxide (AlOₓ), a polyester-based material, a polycarbonate-based material, or the like. For the surface protective layer, a material having a high visible-light-transmitting property is preferably used. The surface protective layer is preferably formed using a material with high hardness.

For the substrate 120, glass, quartz, ceramic, sapphire, a resin, a metal, an alloy, a semiconductor, or the like can be used. The substrate through which light from the light-emitting device is extracted is formed using a material that transmits the light. When a flexible material is used for the substrate 120, the flexibility of the display apparatus can be increased. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film used as the substrate absorbs water, the shape of the display apparatus might be changed, e.g., creases might be caused. Thus, as the substrate, a film with a low water absorption rate is preferably used. For example, the water absorption rate of the film is preferably 1% or lower, further preferably 0.1% or lower, still further preferably 0.01% or lower.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferable. A two-component-mixture-type resin may be used. An adhesive sheet or the like may be used.

FIG. 7A illustrates a variation example of FIG. 1B. FIG. 7A illustrates an example where the top and side surfaces of the pixel electrodes 111R, 111G, and 111B are covered with a conductive layer 116R, a conductive layer 116G, and a conductive layer 116B, respectively. The conductive layers 116R, 116G, and 116B can be regarded as part of the pixel electrodes.

In FIG. 1B, the side surface of the pixel electrode 111R is in contact with the layer 113G. In the case where the pixel electrode 111R has a stacked-layer structure, a plurality of conductive layers are in contact with the layer 113G. In this case, the adhesion between the pixel electrode 111R and the layer 113G might be partly low. The same applies to the adhesion between the pixel electrode 111G and the layer 113G and the adhesion between the pixel electrode 111B and the layer 113B.

In the case where part of a film to be the conductive layers 116R, 116G, and 116B is removed by wet etching after the formation of the pixel electrodes 111R, 111G, and 111B, galvanic corrosion might occur in the pixel electrodes 111R, 111G, and 111B that are exposed to an etchant.

In FIG. 7A, the top and side surfaces of the pixel electrodes 111R, 111G, and 111B are covered with the conductive layers 116R, 116G, and 116B, respectively, whereby the pixel electrodes 111R, 111G, and 111B can be inhibited from being exposed to the etchant and deteriorating due to galvanic corrosion or the like. Accordingly, the range of choices of the material for the pixel electrode 111R can be widened. In addition, the layer 113G and the conductive layer 116R are in contact with each other, and thus uniform adhesion can be achieved.

In the case of a top-emission display apparatus, an electrode having a visible-light-reflecting property (a reflective electrode) is preferably used as the pixel electrodes 111R, 111G, and 111B, and an electrode having a visible-light-transmitting property (a transparent electrode) is preferably used as the conductive layers 116R, 116G, and 116B.

In FIG. 7B, the pixel electrode 111 has a two-layer structure and the conductive layer 116 has a single-layer structure. For example, a two-layer structure of a titanium film and an aluminum film over the titanium film is preferably used for the pixel electrode 111, and an oxide conductive layer (e.g., In—Si—Sn oxide (also referred to as ITSO)) is preferably used as the conductive layer 116. In FIG. 7C, the pixel electrode 111 has a three-layer structure and the conductive layer 116 has a single-layer structure. For example, a three-layer structure of a titanium film, an aluminum film, and a titanium film is preferably used for the pixel electrode 111, and an oxide conductive layer (e.g., ITSO) is preferably used as the conductive layer 116. An aluminum film is suitable for a reflective electrode because of its high reflectivity. However, when aluminum and the oxide conductive layer are in contact with each other, electrochemical corrosion might occur. For this reason, a titanium film is preferably provided between the aluminum film and the oxide conductive layer.

In FIG. 7D, the pixel electrode 111 has a two-layer structure and the conductive layer 116 has a two-layer structure. For example, a two-layer structure of a titanium film and an aluminum film over the titanium film is preferably used for the pixel electrode 111, and a two-layer structure of a titanium film and an oxide conductive layer (e.g., ITSO) is preferably used for the conductive layer 116. In FIG. 7E, the pixel electrode 111 has a three-layer structure and the conductive layer 116 has a two-layer structure. For example, a three-layer structure of a titanium film, an aluminum film, and a titanium film is preferably used for the pixel electrode 111, and a two-layer structure of a titanium film and an oxide conductive layer (e.g., ITSO) is preferably used for the conductive layer 116.

Note that the conductive layers 116R, 116G, and 116B may have different thicknesses. As illustrated in FIG. 7F, the thickness of the conductive layer 116R is preferably larger than that of the conductive layer 116G. Specifically, it is preferable that the thickness of the conductive layer 116R be set such that red light is intensified, the thickness of the conductive layer 116G be set such that green light is intensified, and the thickness of the conductive layer 116B be set such that blue light is intensified. In this manner, a microcavity structure can be achieved and the color purity of each light-emitting device can be increased.

FIG. 1B illustrates an example where the color conversion layer 135 and the coloring layer 132R are directly formed over the light-emitting device 130G with the protective layer 131 therebetween. With such a structure, the alignment accuracy of the light-emitting device and the color conversion layer or the coloring layer can be improved. It is preferable to shorten the distance between the light-emitting device and the coloring layer because color mixing can be inhibited and the viewing angle characteristics can be improved.

FIGS. 8A to 8C and FIGS. 9C and 9D are cross-sectional views along the dashed-dotted line X1-X2 in FIG. 1A.

As illustrated in FIG. 8A, the substrate 120 provided with the color conversion layer 135 and the coloring layer 132R may be bonded to the protective layer 131 with the resin layer 122. Providing the color conversion layer 135 and the coloring layer 132R on the substrate 120 allows heat treatment to be performed at higher temperature in the formation step of the color conversion layer 135 and the coloring layer 132R.

As illustrated in FIGS. 8B and 8C, a lens array 133 may be provided in the display apparatus. The lens array 133 can be provided so as to overlap with the light-emitting device.

FIG. 8B illustrates an example where the color conversion layer 135 and the coloring layer 132R are provided over the light-emitting device 130G with the protective layer 131 therebetween, an insulating layer 134 is provided over the color conversion layer 135 and the coloring layer 132R, and the lens array 133 is provided over the insulating layer 134. The color conversion layer 135, the coloring layer 132R, and the lens array 133 are directly formed over the substrate provided with the light-emitting devices, whereby the accuracy of positional alignment of the light-emitting device and the color conversion layer, the coloring layer, or the lens array can be enhanced.

For the insulating layer 134, one or both of an inorganic insulating material and an organic insulating material can be used. The insulating layer 134 may have either a single-layer structure or a stacked-layer structure. The insulating layer 134 can be formed using a material that can be used for the protective layer 131, for example. Since light emitted from the light-emitting device is extracted through the insulating layer 134, the insulating layer 134 preferably has a high visible-light-transmitting property.

In FIG. 8B, light emitted from the light-emitting device is extracted to the outside of the display apparatus after passing through the color conversion layer, the coloring layer, and the lens array 133. It is preferable to shorten the distance between the light-emitting device and the coloring layer because color mixing can be inhibited and the viewing angle characteristics can be improved. Note that a structure may be employed where the lens array 133 is provided over the light-emitting device and the color conversion layer and the coloring layer are provided over the lens array 133.

FIG. 8C illustrates an example where the substrate 120 provided with the coloring layer 132R, the color conversion layer 135, and the lens array 133 is bonded over the protective layer 131 with the resin layer 122. Providing the coloring layer 132R, the color conversion layer 135, and the lens array 133 on the substrate 120 allows heat treatment to be performed at higher temperature in the formation process of the coloring layer 132R, the color conversion layer 135, and the lens array 133.

FIG. 8C illustrates an example where the coloring layer 132R is provided in contact with the substrate 120, the color conversion layer 135 is provided in contact with the coloring layer 132R, the insulating layer 134 is provided in contact with the color conversion layer 135, and the lens array 133 is provided in contact with the insulating layer 134.

In FIG. 8C, light emitted from the light-emitting device passes through the lens array 133 and is converted into red light by the color conversion layer 135, and the red light is extracted to the outside of the display apparatus through the coloring layer 132R. Note that a structure may be employed where the lens array 133 is provided in contact with the substrate 120, the insulating layer 134 is provided in contact with the lens array 133, the color conversion layer is provided in contact with the insulating layer 134, and the coloring layer is provided in contact with the color conversion layer. In this case, light emitted from the light-emitting device is converted into red light by the color conversion layer, the red light passes through the coloring layer, and then passes through the lens array 133, resulting in being extracted to the outside of the display apparatus.

Although FIGS. 1B, 8B, and the like illustrate an example where a layer having a planarization function is used as the protective layer 131, the protective layer 131 does not necessarily have a planarization function as illustrated in FIGS. 8A and 8C. For example, the protective layer 131 can have a flat top surface when formed using an organic film. Alternatively, the protective layer 131 illustrated in FIGS. 8A and 8C can be formed using an inorganic film, for example.

FIG. 9C illustrates an example where the lens array 133 is provided over the light-emitting device 130G with the protective layer 131 therebetween, and the substrate 120 provided with the coloring layer 132R and the color conversion layer 135 is bonded over the lens array 133 and the protective layer 131 with the resin layer 122.

Unlike in FIG. 9C, the lens array 133 may be provided over the substrate 120 and the color conversion layer 135 and the coloring layer 132R may be formed directly over the protective layer 131. In this manner, one of the lens array and the coloring layer may be provided over the protective layer 131 and the other may be provided over the substrate 120. When the color conversion layer 135 and the coloring layer 132R are compared, the color conversion layer 135 is positioned closer to the light-emitting device 130G than the coloring layer 132R. For example, the color conversion layer 135 may be provided over the protective layer 131 and the coloring layer 132R may be provided over the substrate 120.

The lens array 133 may have a convex surface facing the substrate 120 side or a convex surface facing the light-emitting device.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used. The lens array 133 may be directly formed over the substrate or the light-emitting device. Alternatively, a lens array separately formed may be bonded.

As illustrated in FIG. 9D, a coloring layer 132G transmitting green light may be provided so as to overlap with the green-light-emitting device 130G. For example, light with an unnecessary wavelength emitted from the light-emitting device 130G can be blocked by the coloring layer 132G transmitting green light. Similarly, a coloring layer 132B transmitting blue light may be provided so as to overlap with the blue-light-emitting device 130B. For example, light with an unnecessary wavelength emitted from the blue-light-emitting device 130B can be blocked by the coloring layer 132B transmitting blue light. Such a structure can further increase the color purity of light emitted from each light-emitting device.

Providing the coloring layer so as to overlap with the light-emitting device is preferable because external light reflection can be greatly reduced. When the light-emitting device has a microcavity structure, external light reflection can be further reduced. As described above, when one, preferably both of the coloring layer and the microcavity structure are employed, external light reflection can be sufficiently reduced even without using an optical member such as a circular polarizing plate for the display apparatus. When a circular polarizing plate is not used for the display apparatus, decay of light emission from the light-emitting device can be inhibited and thus the outcoupling efficiency of the light-emitting device can be increased. This can reduce the power consumption of the display apparatus.

It is also preferable that coloring layers of different colors include a region where they overlap with each other. The region where the coloring layers of different colors overlap with each other can function as a light-blocking layer. Such a structure can further reduce external light reflection.

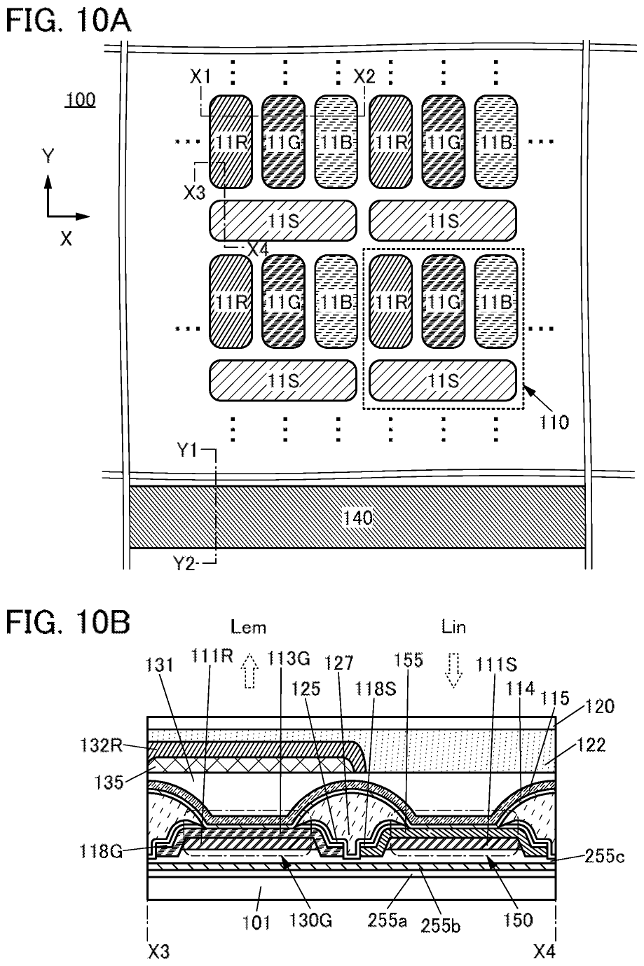

FIG. 10A is a top view of the display apparatus 100 different from that in FIG. 1A. The pixel 110 illustrated in FIG. 10A consists of four types of subpixels 11R, 11G, 11B, and 11S.

Three of the four subpixels included in the pixel 110 illustrated in FIG. 10A may each include a light-emitting device and the other one may include a light-receiving device.

As the light-receiving device, a PN photodiode or a PIN photodiode can be used, for example. The light-receiving device functions as a photoelectric conversion device (also referred to as a photoelectric conversion element) that detects light entering the light-receiving device and generate electric charge. The amount of electric charge generated from the light-receiving device depends on the amount of light entering the light-receiving device.

The light-receiving device can detect one or both of visible light and infrared light. In the case of detecting visible light, for example, one or more of blue light, violet light, bluish violet light, green light, yellowish green light, yellow light, orange light, red light, and the like can be detected. The infrared light is preferably detected because an object can be detected even in a dark environment.

It is particularly preferable to use an organic photodiode including a layer containing an organic compound as the light-receiving device. An organic photodiode, which is easily made thin, lightweight, and large in area and has a high degree of freedom for shape and design, can be used in a variety of display apparatuses.

In one embodiment of the present invention, an organic EL device is used as the light-emitting device, and an organic photodiode is used as the light-receiving device. The organic EL device and the organic photodiode can be formed over one substrate. Thus, the organic photodiode can be incorporated into the display apparatus including the organic EL device.

The light-receiving device is driven by application of reverse bias between the pixel electrode and the common electrode, whereby light entering the light-receiving device can be detected and electric charge can be generated and extracted as a current.

A manufacturing method similar to that of the light-emitting device can be employed for the light-receiving device. An island-shaped active layer (also referred to as a photoelectric conversion layer) included in the light-receiving device is formed by processing a film to be the active layer and formed on the entire surface, not by using a fine metal mask; thus, the island-shaped active layer can have a uniform thickness. Moreover, providing the mask layer over the active layer can reduce damage to the active layer in the manufacturing process of the display apparatus, resulting in an improvement in reliability of the light-receiving device.

Embodiment 6 can be referred to for the structure and the materials of the light-receiving device.

FIG. 10B is a cross-sectional view along the dashed-dotted line X3-X4 in FIG. 10A. See FIG. 1B for a cross-sectional view along the dashed-dotted line X1-X2 in FIG. 10A, and see FIG. 9A or 9B for a cross-sectional view along the dashed-dotted line Y1-Y2 in FIG. 10A.

As illustrated in FIG. 10B, in the display apparatus 100, an insulating layer is provided over the layer 101 including transistors, the light-emitting device 130G and a light-receiving device 150 are provided over the insulating layer, and the protective layer 131 is provided to cover the light-emitting device and the light-receiving device. The substrate 120 is bonded with the resin layer 122. Over the protective layer 131, the color conversion layer 135 and the coloring layer 132R are provided at a position overlapping with the light-emitting device 130G. In a region between the light-emitting device and the light-receiving device adjacent to each other, the insulating layer 125 and the insulating layer 127 over the insulating layer 125 are provided.

FIG. 10B illustrates an example where light is emitted from the light-emitting device 130G to the substrate 120 side and light enters the light-receiving device 150 from the substrate 120 side (see light Lem and light Lin).

The structures of the subpixel 11R and the light-emitting device 130G included in the subpixel 11R are as described above.

The light-receiving device 150 includes a pixel electrode 111S over the insulating layer 255c, a layer 155 over the pixel electrode 111S, the common layer 114 over the layer 155, and the common electrode 115 over the common layer 114. The layer 155 includes at least an active layer.

Here, the layer 155 includes at least an active layer, preferably includes a plurality of functional layers. Examples of the functional layer include carrier-transport layers (a hole-transport layer and an electron-transport layer) and carrier-blocking layers (a hole-blocking layer and an electron-blocking layer). In addition, one or more layers are preferably formed over the active layer. A layer between the active layer and the mask layer can inhibit the active layer from being exposed on the outermost surface during the manufacturing process of the display apparatus and can reduce damage to the active layer. Accordingly, the reliability of the light-receiving device 150 can be increased. Thus, the layer 155 preferably includes an active layer and a carrier-blocking layer (a hole-blocking layer or an electron-blocking layer) or a carrier-transport layer (an electron-transport layer or a hole-transport layer) over the active layer.

The layer 155 is provided in the light-receiving device 150, not in the light-emitting devices. Note that the functional layer other than the active layer in the layer 155 may include the same material as the functional layer other than the light-emitting layer in the layer 113B or 113G. Meanwhile, the common layer 114 is a continuous layer shared by the light-emitting device and the light-receiving device.

Here, a layer shared by the light-receiving device and the light-emitting device may have a different function depending on which device the layer is in. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-receiving device and the light-emitting device. The hole-transport layer functions as a hole-transport layer in both the light-emitting device and the light-receiving device, and the electron-transport layer functions as an electron-transport layer in both the light-emitting device and the light-receiving device.

The mask layer 118G is positioned between the layer 113G and the insulating layer 125, and a mask layer 118S is positioned between the layer 155 and the insulating layer 125. The mask layer 118G is a remaining part of the mask layer provided over the layer 113G at the time of processing the layer 113G. The mask layer 118S is a remaining part of a mask layer provided in contact with the top surface of the layer 155 at the time of processing the layer 155, which is a layer including the active layer. The mask layers 118G and 118S may contain the same material or different materials.

Although FIG. 10A illustrates an example where an aperture ratio (also referred to as a size or a size of the light-emitting region or the light-receiving region) of the subpixel 11S is higher than those of the subpixels 11R, 11G, and 11B, one embodiment of the present invention is not limited thereto. The aperture ratio of each of the subpixels 11R, 11G, 11B, and 11S can be determined as appropriate. The subpixels 11R, 11G, 11B, and 11S may have different aperture ratios, or two or more of the subpixels 11R, 11G, 11B, and 11S may have the same or the substantially the same aperture ratio.

The subpixel 11S may have a higher aperture ratio than at least one of the subpixels 11R, 11G, and 11B. The wide light-receiving area of the subpixel 11S can make it easy to detect an object in some cases. For example, in some cases, the aperture ratio of the subpixel 11S is higher than that of the other subpixels depending on the resolution of the display apparatus and the circuit structure or the like of the subpixel.

The subpixel 11S may have a lower aperture ratio than at least one of the subpixels 11R, 11G, and 11B. A small light-receiving area leads to a narrow image-capturing range, prevents a blur in a captured image, and improves the definition. Accordingly, high-resolution or high-definition image capturing can be performed, which is preferable.

As described above, the subpixel 11S can have a detection wavelength, a resolution, and an aperture ratio that are suitable for the intended use.

In the display apparatus of one embodiment of the present invention, each light-emitting device includes an island-shaped EL layer, which can inhibit generation of a leakage current between the subpixels. This can prevent crosstalk due to unintended light emission, so that a display apparatus with extremely high contrast can be obtained. An end portion of the island-shaped EL layer and the vicinity thereof, which might be damaged in the manufacturing process of the display apparatus, are set as a dummy region not to be used as the light-emitting region, whereby variations in the characteristics of the light-emitting devices can be inhibited. The insulating layer having a tapered end portion and being provided between adjacent island-shaped EL layers can prevent formation of step disconnection and a locally thinned portion in the common electrode at the time of forming the common electrode. This can inhibit the common layer and the common electrode from having connection defects due to the disconnected portion and an increased electric resistance due to the locally thinned portion. Thus, the display apparatus of one embodiment of the present invention can have both a higher resolution and higher display quality.

In addition, the display apparatus of one embodiment of the present invention achieves a subpixel emitting red light and a subpixel emitting green light by using light-emitting devices including the same light-emitting layer for the two subpixels and using a color conversion layer for one of the subpixels. A light-emitting device emitting blue light is used for a subpixel emitting blue light. Thus, subpixels of three colors can be formed separately just by forming light-emitting devices of two colors. In the case of separately forming two types of light-emitting devices, damage to the pixel electrodes can be suppressed and degradation of the characteristics of the light-emitting devices can be inhibited in the subpixels of respective colors, as compared with the case of separately forming three types of light-emitting devices. In addition, the number of times of processing of the light-emitting layer by a photolithography method can be two; thus, the display apparatus can be manufactured with high yield.

This embodiment can be combined with any of the other embodiments as appropriate. In this specification, in the case where a plurality of structure examples are shown in one embodiment, the structure examples can be combined as appropriate.

### Embodiment 2

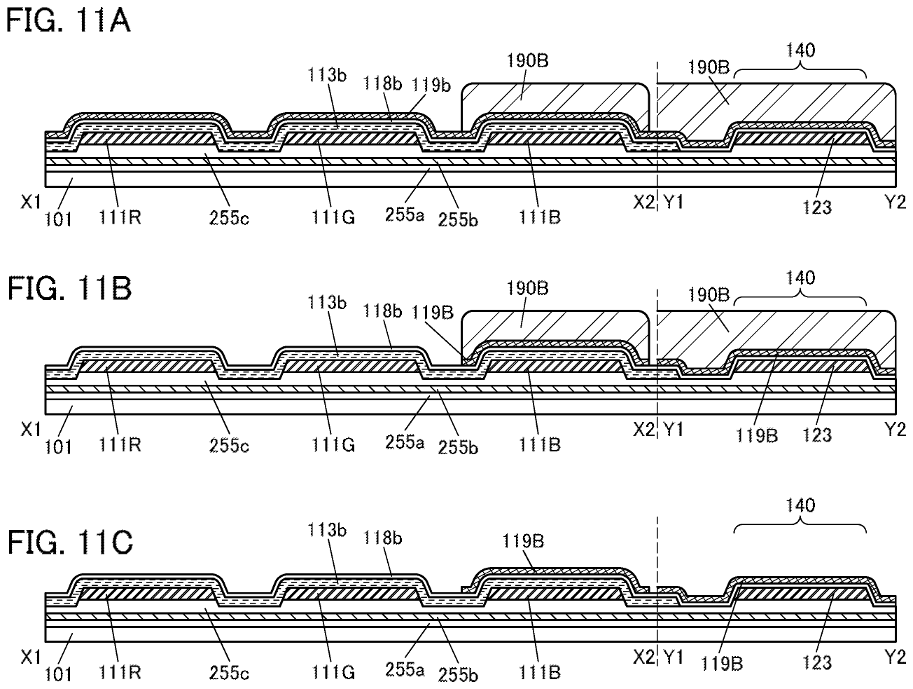

In this embodiment, a method for manufacturing a display apparatus of one embodiment of the present invention will be described with reference to FIGS. 11A to 11C, FIGS. 12A to 12C, FIGS. 13A to 13C, FIGS. 14A to 14C, FIGS. 15A and 15B, FIGS. 16A to 16E, and FIGS. 17A and 17B. Note that as for a material and a formation method of each component, portions similar to those described in Embodiment 1 are not described in some cases. The structure of the light-emitting device will be described in detail in Embodiment 5.

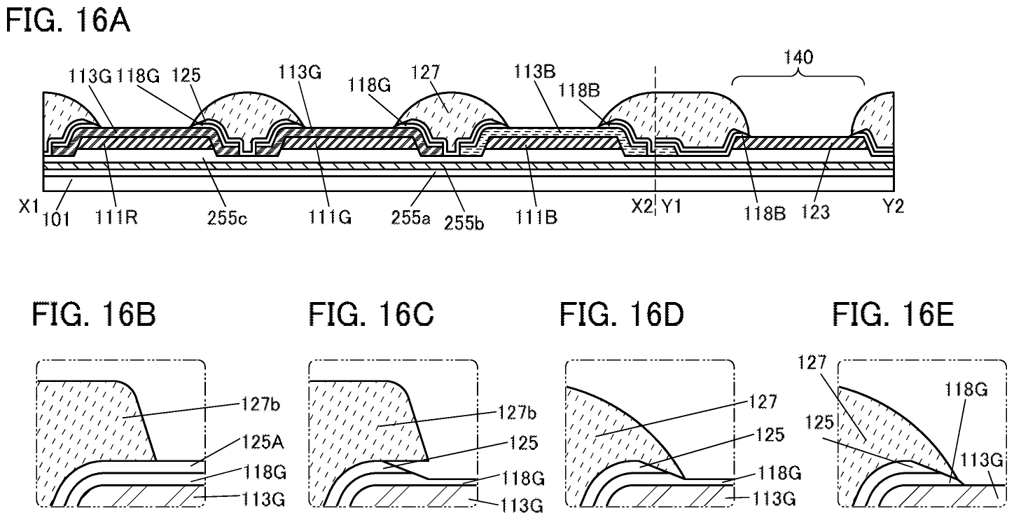

FIGS. 11A to 15B, FIG. 16A, and FIGS. 17A and 17B each illustrate a cross-section along the dashed-dotted line X1-X2 and a cross section along the dashed-dotted line Y1-Y2 in FIG. 1A side by side. FIGS. 16B to 16E are enlarged views of an end portion of the insulating layer 127 and the vicinity thereof.

Note that thin films included in the display apparatus (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic CVD (MOCVD) method.

Alternatively, thin films included in the display apparatus (e.g., insulating films, semiconductor films, and conductive films) can be formed by a wet process such as spin coating, dipping, spray coating, ink-jetting, dispensing, screen printing, or offset printing or with a doctor knife, a slit coater, a roll coater, a curtain coater, or a knife coater.

Specifically, for fabrication of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an inkjet method, screen printing (stencil), offset printing (planography), flexography (relief printing), gravure printing, or micro-contact printing), or the like.

Thin films included in the display apparatus can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Light exposure may be performed by liquid immersion exposure technique. As the light for exposure, extreme ultraviolet (EUV) light or X-rays may also be used. Furthermore, instead of the light for exposure, an electron beam can be used. It is preferable to use EUV, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

First, the insulating layers 255a, 255b, and 255c are formed in this order over the layer 101 including transistors. Next, the pixel electrodes 111R, 111G, and 111B, and the conductive layer 123 are formed over the insulating layer 255c (FIG. 11A). A conductive film to be the pixel electrodes can be formed by a sputtering method or a vacuum evaporation method, for example.

Then, the pixel electrode is preferably subjected to hydrophobic treatment. The hydrophobic treatment can change the property of the surface of a processing target from hydrophilic to hydrophobic, or can improve the hydrophobic property of the surface of the processing target. The hydrophobic treatment for the pixel electrodes can improve adhesion between the pixel electrode and a film to be formed in a later step (here, a film 113b), thereby inhibiting film separation. Note that the hydrophobic treatment is not necessarily performed.

The hydrophobic treatment can be performed by fluorine modification of the pixel electrode, for example. The fluorine modification can be performed by treatment using a gas containing fluorine, heat treatment, plasma treatment in a gas atmosphere containing fluorine, or the like. A fluorine gas can be used as the gas containing fluorine, and for example, a fluorocarbon gas can be used. As the fluorocarbon gas, a low-molecular-weight carbon fluoride gas such as a carbon tetrafluoride (CF₄) gas, a C₄F₆ gas, a C₂F₆ gas, a C₄F₈ gas, or a C₅F₈ gas can be used, for example. Alternatively, as the gas containing fluorine, an SF₆ gas, an NF₃ gas, a CHF₃ gas, or the like can be used, for example. Moreover, a helium gas, an argon gas, a hydrogen gas, or the like can be added to any of the above gases as appropriate.

In addition, treatment using a silylating agent is performed on the surface of the pixel electrode after plasma treatment is performed in a gas atmosphere containing a Group 18 element such as argon, so that the surface of the pixel electrode can have a hydrophobic property. As the silylating agent, hexamethyldisilazane (HMDS), trimethylsilylimidazole (TMSI), or the like can be used. Alternatively, treatment using a silane coupling agent is performed on the surface of the pixel electrode after plasma treatment is performed in a gas atmosphere containing a Group 18 element such as argon, so that the surface of the pixel electrode can have a hydrophobic property.

Plasma treatment on the surface of the pixel electrode in a gas atmosphere containing a Group 18 element such as argon can apply damage to the surface of the pixel electrode. Accordingly, a methyl group included in the silylating agent such as HMDS is likely to bond to the surface of the pixel electrode. In addition, silane coupling by the silane coupling agent is likely to occur. As described above, treatment using a silylating agent or a silane coupling agent performed on the surface of the pixel electrode after plasma treatment in a gas atmosphere containing a Group 18 element such as argon enables the surface of the pixel electrode to have a hydrophobic property.

The treatment using a silylating agent, a silane coupling agent, or the like can be performed by application of the silylating agent, the silane coupling agent, or the like by a spin coating method, a dipping method, or the like. Alternatively, the treatment using a silylating agent, a silane coupling agent, or the like can be performed by forming a film containing the silylating agent, a film containing the silane coupling agent, or the like over the pixel electrode by a gas phase method, for example. In a gas phase method, first, a material containing a silylating agent, a material containing a silane coupling agent, or the like is evaporated so that the silylating agent or the silane coupling agent is contained in an atmosphere. Next, a substrate where the pixel electrode and the like are formed is put in the atmosphere. Accordingly, a film containing the silylating agent, a film containing the silane coupling agent, or the like can be formed over the pixel electrode, so that the surface of the pixel electrode can have a hydrophobic property.

Then, the film 113b to be the layer 113B later is formed over the pixel electrodes (FIG. 11A). The film 113b (to be the layer 113B later) contains a light-emitting material emitting blue light.

As illustrated in FIG. 11A, the film 113b is not formed over the conductive layer 123 in the cross-sectional view along the dashed-dotted line Y1-Y2. The film 113b can be formed only in a desired region using an area mask, for example. A light-emitting device can be manufactured through a relatively simple process, by employing a film formation step using an area mask and a processing step using a resist mask.

As described in Embodiment 1, a material with high heat resistance is used for the light-emitting device of the display apparatus of one embodiment of the present invention. Specifically, the upper temperature limit of a compound contained in the film 113b is preferably higher than or equal to 100° C. and lower than or equal to 180° C., further preferably higher than or equal to 120° C. and lower than or equal to 180° C., still further preferably higher than or equal to 140° C. and lower than or equal to 180° C. In this case, the reliability of the light-emitting device can be improved. In addition, the upper limit of the temperature that can be applied in the manufacturing process of the display apparatus can be increased. Therefore, the range of choices of the materials and the formation method of the display apparatus can be widened, thereby improving the manufacturing yield and the reliability.

The film 113b can be formed by an evaporation method, specifically a vacuum evaporation method, for example. The film 113b may be formed by a transfer method, a printing method, an inkjet method, a coating method, or the like.

Next, a mask film 118b to be the mask layer 118B later and a mask film 119b to be the mask layer 119B later are formed in this order over the film 113b and the conductive layer 123 (FIG. 11A).

Although this embodiment describes an example where the mask film is formed with a two-layer structure of the mask films 118b and 119b, the mask film may have a single-layer structure or a stacked-layer structure of three or more layers.

Providing the mask layer over the film 113b can reduce damage to the film 113b in the manufacturing process of the display apparatus, resulting in an improvement in reliability of the light-emitting device.

As the mask film 118b, a film highly resistant to the processing conditions of the film 113b, i.e., a film having high etching selectivity to the film 113b, is used. As the mask film 119b, a film having high etching selectivity to the mask film 118b is used.

The mask films 118b and 119b are formed at a temperature lower than the upper temperature limit of the film 113b. The typical substrate temperatures in formation of the mask films 118b and 119b are lower than or equal to 200° C., preferably lower than or equal to 150° C., further preferably lower than or equal to 120° C., still further preferably lower than or equal to 100° C., yet still further preferably lower than or equal to 80° C.

Examples of indicators of the upper temperature limit are the glass transition point, the softening point, the melting point, the thermal decomposition temperature, and the 5% weight loss temperature. The upper temperature limit of the films 113b and 113g (i.e., the layers 113B and 113G) can be any of the above temperatures that are indicators of the upper temperature limit, preferably the lowest one among the temperatures.

As described above, a material with high heat resistance is used for the light-emitting device of the display apparatus of one embodiment of the present invention. Thus, the substrate temperature in formation of the mask film can be higher than or equal to 100° C., higher than or equal to 120° C., or higher than or equal to 140° C. For example, an inorganic insulating film formed at a higher temperature can be denser and have a higher barrier property. Therefore, forming the mask film at such a temperature can further reduce damage to the film 113b and improve the reliability of the light-emitting device.

As each of the mask films 118b and 119b, a film that can be removed by a wet etching method is preferably used. The use of a wet etching method can reduce damage to film 113b in processing of the mask films 118b and 119b as compared with the case of using a dry etching method.

The mask films 118b and 119b can be formed by a sputtering method, an ALD method (including a thermal ALD method or a PEALD method), a CVD method, or a vacuum evaporation method, for example. Alternatively, the aforementioned wet process may be used for the formation.

The mask film 118b, which is formed over and in contact with the film 113b, is preferably formed by a formation method that causes less damage to the film 113b than a formation method of the mask film 119b. For example, the mask film 118b is preferably formed by an ALD method or a vacuum evaporation method rather than a sputtering method.

As each of the mask films 118b and 119b, it is possible to use one or more of a metal film, an alloy film, a metal oxide film, a semiconductor film, an organic insulating film, and an inorganic insulating film, for example.

For each of the mask films 118b and 119b, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet rays for one or both of the mask films 118b and 119b is preferable, in which case the film 113b can be inhibited from being irradiated with ultraviolet rays and deteriorating.

The use of a metal film or an alloy film as one or both of the mask films 118b and 119b is preferable, in which case the film 113b can be inhibited from being damaged by plasma and deteriorating. Specifically, the film 113b can be inhibited from being damaged by plasma in a step using a dry etching method, a step performing ashing, or the like. It is particularly preferable to use a metal film such as a tungsten film or an alloy film as the mask film 119b.

The mask films 118b and 119b can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used.

As the mask film, a film containing a material having a light-blocking property, particularly with respect to ultraviolet rays, can be used. For example, a film having a reflecting property with respect to ultraviolet rays or a film absorbing ultraviolet rays can be used. Although a variety of materials, such as a metal having a light-blocking property with respect to ultraviolet rays, an insulator, a semiconductor, and a metalloid, can be used as the material having a light-blocking property, a film capable of being processed by etching is preferable, and a film having good processability is particularly preferable because part or the whole of the mask film is removed in a later step.

For example, a semiconductor material such as silicon or germanium can be used as a material with an affinity for the semiconductor manufacturing process. Alternatively, oxide or nitride of the semiconductor material can be used. Alternatively, a non-metallic metal material such as carbon or a compound thereof can be used. Alternatively, a metal, such as titanium, tantalum, tungsten, chromium, or aluminum, or an alloy containing one or more of these metals can be used. Alternatively, oxide containing the above-described metal, such as titanium oxide or chromium oxide, or nitride such as titanium nitride, nitride chromium, or tantalum nitride can be used.

The use of a film containing a material having a light-blocking property with respect to ultraviolet rays can inhibit the EL layer from being irradiated with ultraviolet rays in a light exposure step or the like. The EL layer is inhibited from being damaged by ultraviolet rays, so that the reliability of the light-emitting device can be improved.

Note that the film containing a material having a light-blocking property with respect to ultraviolet rays can have the same effect even when used as an insulating film 125A to be described later.

As the mask films 118b and 119b, any of a variety of inorganic insulating films that can be used as the protective layer 131 can be used. In particular, an oxide insulating film is preferable because its adhesion to the film 113b is higher than that of a nitride insulating film. For example, an inorganic insulating material such as aluminum oxide, hafnium oxide, or silicon oxide can be used for the mask films 118b and 119b. As the mask films 118b and 119b, an aluminum oxide film can be formed by an ALD method, for example. The use of an ALD method is preferable, in which case damage to a base (in particular, the EL layer) can be reduced.

For example, an inorganic insulating film (e.g., an aluminum oxide film) formed by an ALD method can be used as the mask film 118b, and an inorganic film (e.g., an In—Ga—Zn oxide film, a silicon film, or a tungsten film) formed by a sputtering method can be used as the mask film 119b.

Note that the same inorganic insulating film can be used for both the mask film 118b and the insulating layer 125 that is to be formed later. For example, an aluminum oxide film formed by an ALD method can be used for both the mask film 118b and the insulating layer 125. For the mask film 118b and the insulating layer 125, the same film formation condition may be used or different film formation conditions may be used. For example, when the mask film 118b is formed under conditions similar to those of the insulating layer 125, the mask film 118b can be an insulating layer having a high barrier property against at least one of water and oxygen. Meanwhile, since most or all of the mask film 118b is to be removed in a later step, the mask film 118b is preferably easy to process. Therefore, the mask film 118b is preferably formed at a substrate temperature lower than that in formation of the insulating layer 125.

An organic material may be used for one or both of the mask films 118b and 119b. For example, as the organic material, a material that can be dissolved in a solvent chemically stable with respect to at least the uppermost film of the film 113b. Specifically, a material that can be dissolved in water or alcohol can be suitably used. In forming a film of such a material, it is preferable to apply the material dissolved in a solvent such as water or alcohol by a wet process and then perform heat treatment for evaporating the solvent. At this time, the heat treatment is preferably performed under a reduced-pressure atmosphere, in which case the solvent can be removed at a low temperature in a short time and thermal damage to the film 113b can be accordingly reduced.

The mask films 118b and 119b may be formed using an organic material such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer.

For example, an organic film (e.g., a PVA film) formed by an evaporation method or the above wet process can be used as the mask film 118b, and an inorganic film (e.g., a silicon nitride film) formed by a sputtering method can be used as the mask film 119b.

Note that as described in Embodiment 1, part of the mask film sometimes remains as a mask layer in the display apparatus of one embodiment of the present invention.

Next, a resist mask 190B is formed over the mask film 119b (FIG. 11A). The resist mask 190B can be formed by application of a photosensitive resin (photoresist), light exposure, and development.

The resist mask 190B may be formed using either a positive resist material or a negative resist material.

The resist mask 190B is provided at a position overlapping with the pixel electrode 111B. Note that the resist mask 190B is preferably provided also at a position overlapping with the conductive layer 123. This can inhibit the conductive layer 123 from being damaged during the manufacturing process of the display apparatus. Note that the resist mask 190B is not necessarily provided over the conductive layer 123.

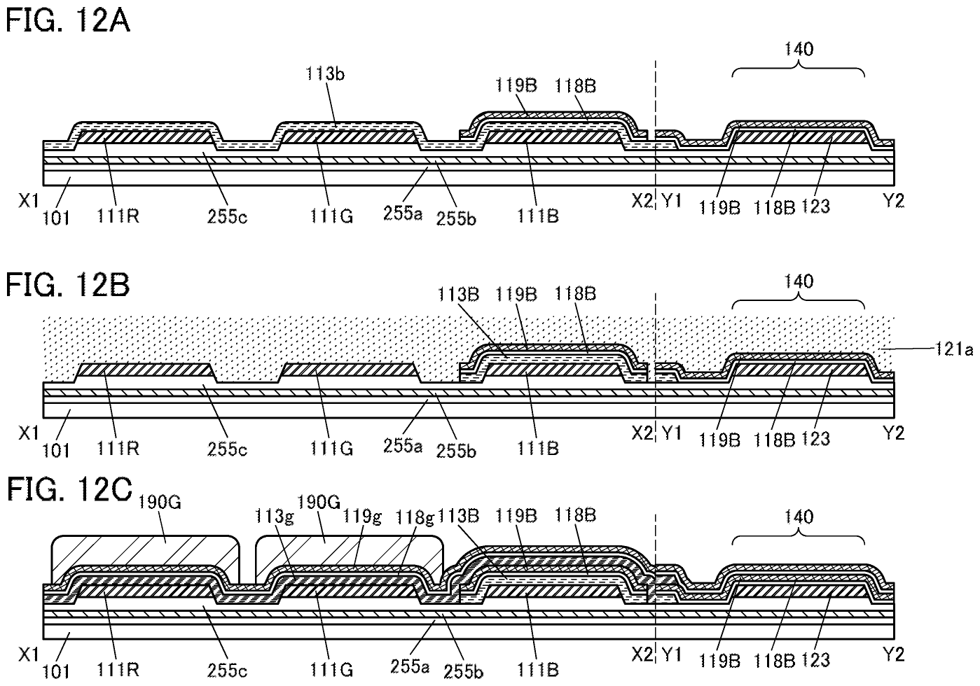

As illustrated in the cross-sectional view along Y1-Y2 in FIG. 11A, the resist mask 190B is preferably provided to cover a region from an end portion of the film 113b to an end portion of the conductive layer 123 (an end portion on the film 113b side). In this case, end portions of the mask layers 118B and 119B overlap with the end portion of the film 113b even after the mask films 118b and 119b are processed. Since the mask layers 118B and 119B are provided to cover a region from the end portion of the film 113b to the end portion of the conductive layer 123 (the end portion on the film 113b side), the insulating layer 255c can be inhibited from being exposed even after the film 113b is processed (see the cross-sectional view along Y1-Y2 in FIG. 12B). This can prevent elimination of the insulating layers 255a to 255c and part of the insulating layer included in the layer 101 including transistors, and exposure of the conductive layer included in the layer 101 including transistors. Thus, unintentional electrical connection between the conductive layer and another conductive layer can be inhibited. For example, a short circuit between the conductive layer and the common electrode 115 can be inhibited.

Next, part of the mask film 119b is removed with the use of the resist mask 190B, so that the mask layer 119B is formed (FIG. 11B). The mask layer 119B partly remains over the pixel electrode 111B and the conductive layer 123. After that, the resist mask 190B is removed (FIG. 11C). Next, part of the mask film 118b is removed using the mask layer 119B as a mask (also referred to as a hard mask), so that the mask layer 118B is formed (FIG. 12A).

The mask films 118b and 119b can be processed by a wet etching method or a dry etching method. The mask films 118b and 119b are preferably processed by anisotropic etching.

The use of a wet etching method can reduce damage to the film 113b in processing of the mask films 118b and 119b, compared with the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a mixed solution containing two or more of these materials, for example.

Since the film 113b is not exposed in processing of the mask film 119b, the range of choices of the processing method is wider than that for the mask film 118b. Specifically, deterioration of the mask film 119b can be further inhibited even when a gas containing oxygen is used as an etching gas for processing the mask film 119b.

In the case of using a dry etching method for processing the mask film 118b, deterioration of the film 113b can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas (also referred to as rare gas) such as He as the etching gas, for example.

For example, when an aluminum oxide film formed by an ALD method is used as the mask film 118b, the mask film 118b can be processed by a dry etching method using a combination of CHF₃ and He or a combination of CHF₃, He, and CH₄. In the case where an In—Ga—Zn oxide film formed by a sputtering method is used as the mask film 119b, the mask film 119b can be processed by a wet etching method using a diluted phosphoric acid. Alternatively, the mask film 119b may be processed by a dry etching method using CH₄ and Ar. Alternatively, the mask film 119b can be processed by a wet etching method using a diluted phosphoric acid. When a tungsten film formed by a sputtering method is used as the mask film 119b, the mask film 119b can be processed by a dry etching method using a combination of SF₆, CF₄, and O₂ or a combination of CF₄, Cl₂ and O₂.

The resist mask 190B can be removed by ashing using oxygen plasma, for example. Alternatively, an oxygen gas and any of CF₄, C₄F₈, SF₆, CHF₃, Cl₂, H₂O, BCl₃, and a noble gas such as He may be used. Alternatively, the resist mask 190B may be removed by wet etching. At this time, the mask film 118b is positioned on the outermost surface, and the film 113b is not exposed; thus, the film 113b can be inhibited from being damaged in the step of removing the resist mask 190B. In addition, the range of choices of the method for removing the resist mask 190B can be widened.

Next, the film 113b is processed to form the layer 113B. For example, part of the film 113b is removed using the mask layers 119B and 118B as a hard mask, so that the layer 113B is formed (FIG. 12B).

Accordingly, as illustrated in FIG. 12B, the stacked-layer structure of the layer 113B, the mask layer 118B, and the mask layer 119B remains over the pixel electrode 111B. In addition, the pixel electrodes 111R and 111G are exposed.

Here, when the film 113b is processed, the surfaces of the pixel electrodes 111R and 111G are exposed to an etching gas or an etchant. On the other hand, the surface of the pixel electrode 111B is not exposed to an etching gas, an etchant, or the like. As described above, in the light-emitting device of the color formed first, the surface of the pixel electrode is not damaged by the etching step, whereby the interface between the pixel electrode and the EL layer can be kept favorable.

The film 113b is preferably processed by anisotropic etching. In particular, anisotropic dry etching is preferably employed. Alternatively, wet etching may be employed.

FIG. 12B illustrates an example where the film 113b is processed by a dry etching method. In a dry etching apparatus, an etching gas is brought into a plasma state. Thus, a surface of the display apparatus under manufacturing is exposed to plasma (plasma 121a). Here, a metal film or an alloy film is preferably used for one or both of the mask layers 118B and 119B, in which case a remaining portion of the film 113b (a portion to be the layer 113B later) can be inhibited from being damaged by the plasma and deterioration of the layer 113B can be inhibited. In particular, a metal film such as a tungsten film or an alloy film is preferably used for the mask layer 119B.

In the case of using a dry etching method, deterioration of the film 113b can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the film 113b can be suppressed. Furthermore, a defect such as attachment of a reaction product generated at the etching can be inhibited.

In the case of using a dry etching method, it is preferable to use, as the etching gas, a gas containing at least one of H₂, CF₄, C₄F₈, SF₆, CHF₃, Cl₂, H₂O, BCl₃, and a noble gas (also referred to as a rare gas) such as He and Ar, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas. As another example, a gas containing H₂ and Ar and a gas containing oxygen can be used as the etching gas.

Alternatively, a dry etching apparatus including a high-density plasma source can be used as the dry etching apparatus. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, different high-frequency voltages may be applied to one of the parallel plate electrodes. Alternatively, high-frequency voltages with the same frequency may be applied to the parallel plate electrodes. Alternatively, high-frequency voltages with different frequencies may be applied to the parallel plate electrodes.

FIG. 12B illustrates an example where an end portion of the layer 113B is positioned on the outer side of the end portion of the pixel electrode 111B. A pixel with such a structure can have a high aperture ratio. Although not illustrated in FIG. 12B, a depressed portion is sometimes formed by the etching treatment in a region of the insulating layer 255c not overlapping with the layer 113B.

When the layer 113B covers the top and side surfaces of the pixel electrode 111B, the following steps can be performed without exposing the pixel electrode 111B. When the end portion of the pixel electrode 111B is exposed, corrosion might occur in the etching step or the like. A product generated by corrosion of the electrode 111B might be unstable; for example, the product might be dissolved in a solution in wet etching and might be diffused in an atmosphere in dry etching. The product dissolved in a solution or diffused in an atmosphere might be attached to a surface to be processed, the side surface of the layer 113B, and the like, which adversely affects the characteristics of the light-emitting device or forms a leakage path between the light-emitting devices in some cases. In a region where the end portion of the pixel electrode 111B is exposed, adhesion between contacting layers is reduced, which might facilitate film separation of the layer 113B or the pixel electrode 111B.

Thus, when the layer 113B covers the top and side surfaces of the pixel electrode 111B, the yield and characteristics of the light-emitting device can be improved, for example.

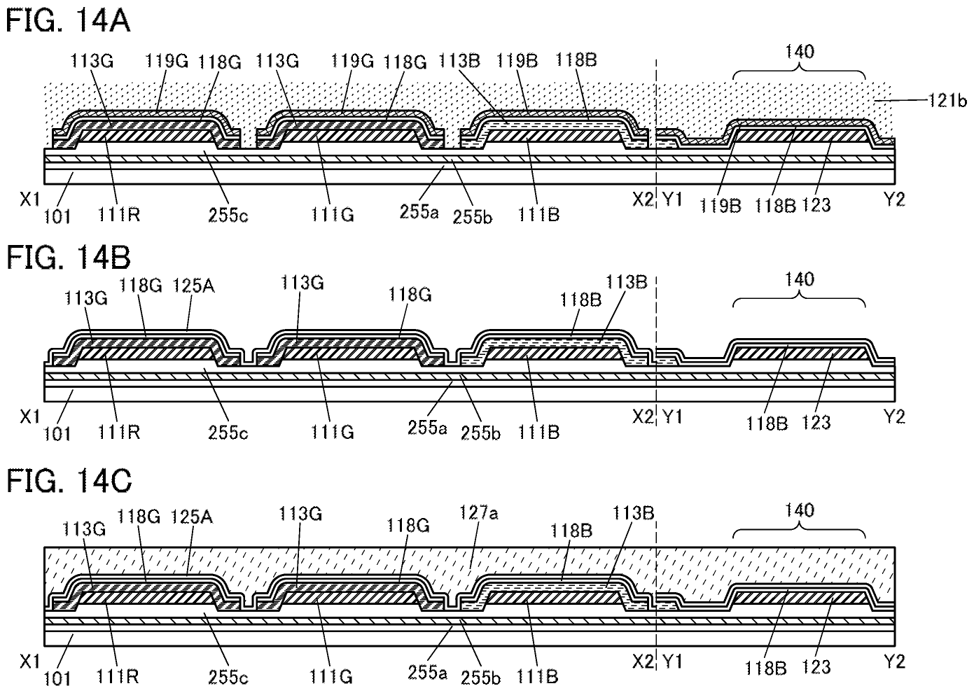

In addition, as described in Embodiment 1, the layer 113B covers the top and side surfaces of the pixel electrode 111B, and thus the layer 113B includes a dummy region outside the light-emitting region (a region positioned between the pixel electrode 111B and the common electrode 115). Here, the end portion of the layer 113B is sometimes damaged at the time of processing the film 113b. In addition, the end portion of the layer 113B is sometimes damaged by being exposed to plasma in a later step (see plasma 121b in FIG. 14A). The end portion of the layer 113B and the vicinity thereof are dummy regions and not used for light emission; thus, such regions are less likely to adversely affect the characteristics of the light-emitting device even when being damaged. On the other hand, the light-emitting region of the layer 113B is covered with the mask layer, and thus is not exposed to plasma and plasma damage is sufficiently reduced. The mask layer is preferably provided to cover not only the top surface of a flat portion of the layer 113B overlapping with the top surface of the pixel electrode 111B, but also the top surfaces of an inclined portion and a flat portion of the layer 113B that are positioned on the outer side of the top surface of the pixel electrode 111B. A portion of the layer 113B with reduced damage in the manufacturing process is used as the light-emitting region in this manner; thus, a light-emitting device having high emission efficiency and a long lifetime can be achieved.

In a region corresponding to the connection portion 140, a stacked-layer structure of the mask layers 118B and 119B remains over the conductive layer 123.

As described above, in the cross-sectional view along Y1-Y2 in FIG. 12B, the mask layers 118B and 119B are provided to cover the end portions of the layer 113B and the conductive layer 123, and the top surface of the insulating layer 255c is not exposed. This can prevent removal of the insulating layers 255a to 255c and part of the insulating layer included in the layer 101 including transistors, and exposure of the conductive layer included in the layer 101 including transistors. Thus, unintentional electrical connection between the conductive layer and another conductive layer can be inhibited.

As described above, in one embodiment of the present invention, the mask layer 119B is formed in the following manner: the resist mask 190B is formed over the mask film 119b, and part of the mask film 119b is removed using the resist mask 190B. After that, part of the film 113b is removed using the mask layer 119B as a hard mask, so that the layer 113B is formed. In other words, the layer 113B can be formed by processing the film 113b by a photolithography method. Note that part of the film 113b may be removed using the resist mask 190B. Then, the resist mask 190B may be removed.

Next, the pixel electrode is preferably subjected to hydrophobic treatment. In processing of the film 113b, the surface state of the pixel electrode changes to a hydrophilic state in some cases. The hydrophobic treatment for the pixel electrodes can improve adhesion between the pixel electrodes and a film to be formed in a later step (here, a film 113g), thereby inhibiting film separation. Note that the hydrophobic treatment is not necessarily performed.

Next, the film 113g to be the layer 113G later is formed over the pixel electrode 111R, the pixel electrode 111G, and the mask layer 119B (FIG. 12C). The film 113g (to be the layer 113G later) contains a light-emitting material emitting shorter-wavelength light than the light-emitting material used for the film 113b. For example, the film 113g contains a light-emitting material emitting green light.

The film 113g can be formed by a method similar to that for the film 113b.

Next, over the film 113g, a mask film 118g to be the mask layer 118G later and a mask film 119g to be a mask layer 119G later are formed in this order over the film 113g, and then a resist mask 190G is formed (FIG. 12C). The materials and the formation methods of the mask films 118g and 119g are similar to those for the mask films 118b and 119b. The materials and the formation method of the resist mask 190G are similar to those for the resist mask 190B.

The resist mask 190G is provided at a position overlapping with the pixel electrode 111R and a position overlapping with the pixel electrode 111G. Note that it is preferable that a region not overlapping with the resist mask 190G exist between the pixel electrodes 111R and 111G.

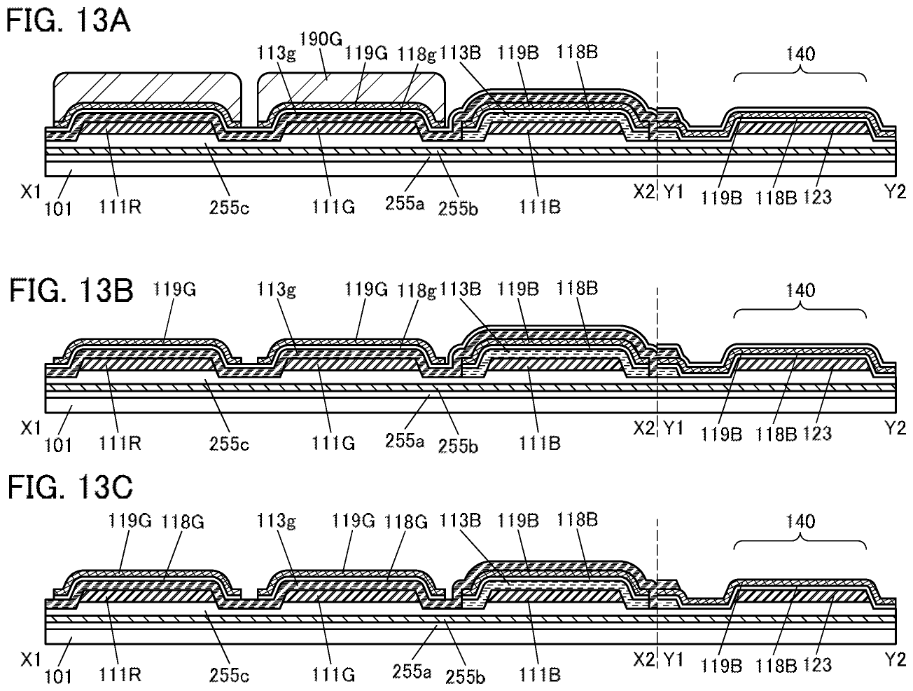

Next, part of the mask film 119g is removed using the resist mask 190G, so that the mask layer 119G is formed (FIG. 13A). The mask layer 119G remains over the pixel electrodes 111R and 111G. After that, the resist mask 190G is removed (FIG. 13B). Next, part of the mask film 118g is removed using the mask layer 119G as a mask, so that the mask layer 118G is formed (FIG. 13C). Then, the film 113g is processed, whereby the layer 113G is formed. For example, part of the film 113g is removed using the mask layers 119G and 118G as a hard mask, so that the layer 113G is formed (FIG. 14A).

Here, in processing of the film 113g, the surface of each pixel electrode is not exposed to an etching gas, an etchant, or the like. That is, the surface of the pixel electrode is not exposed to the etching step in the light-emitting device of the color formed first, and the surface of the pixel electrode is exposed to the first etching step in the light-emitting device of the color formed second. In the case where light-emitting devices of three colors are separately formed, the surface of the pixel electrode is exposed to the first and second etching steps in the light-emitting device of the color formed third. Since light-emitting devices of two colors are separately formed in this embodiment, damage to the pixel electrodes by etching can be reduced. Thus, the characteristics of the light-emitting devices of respective colors can be favorable.

Although this embodiment describes an example where the layer 113G is formed after formation of the layer 113B, the layer 113B may be formed after formation of the layer 113G. In this case, only the pixel electrode 111B is exposed to the etching step, thereby increasing the proportion of non-damaged pixel electrodes (the pixel electrodes 111R and 111G).

FIG. 14A illustrates an example where the film 113g is processed by a dry etching method. The surface of the display apparatus under manufacturing is exposed to plasma (the plasma 121b). Here, a metal film or an alloy film is preferably used for one or both of the mask layers 118B and 119B, in which case the layer 113B can be inhibited from being damaged by the plasma and deteriorating. A metal film or an alloy film is preferably used for one or both of the mask layers 118B and 119B, in which case a remaining portion of the film 113g (a portion to be the layer 113G later) can be inhibited from being damaged by the plasma and deterioration of the layer 113G can be inhibited. In particular, a metal film such as a tungsten film or an alloy film is preferably used for the mask layer 119G.

Accordingly, as illustrated in FIG. 14A, the stacked-layer structure of the layer 113G, the mask layer 118G, and the mask layer 119G remains over the pixel electrodes 111R and 111G. In addition, the mask layer 119B is exposed.

Note that side surfaces of the layers 113B and 113G are preferably perpendicular or substantially perpendicular to their formation surfaces. For example, the angle between the formation surfaces and these side surfaces is preferably greater than or equal to 60° and less than or equal to 90°.

As described above, the distance between adjacent layers in the layers 113B and 113G formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between facing end portions of adjacent layers in the layers 113B and 113G. When the distance between the island-shaped EL layers is shortened in this manner, a display apparatus with a high resolution and a high aperture ratio can be provided.

Next, the mask layers 119B and 119G are preferably removed (FIG. 14B). The mask layers 118B, 118G, 119B, and 119G remain in the display apparatus in some cases, depending on the later steps. Removing the mask layers 119B and 119G at this stage can inhibit the mask layers 119B and 119G from remaining in the display apparatus. For example, in the case where a conductive material is used for the mask layers 119B and 119G, removing the mask layers 119B and 119G in advance can inhibit generation of a leakage current due to the remaining mask layers 119B and 119G, formation of a capacitor, or the like.

Although this embodiment describes an example where the mask layers 119B and 119G are removed, the mask layers 119B and 119G are not necessarily removed. For example, in the case where the mask layers 119B and 119G contain the aforementioned material having a light-blocking property with respect to ultraviolet rays, the process preferably proceeds to the next step without removing the mask layers, in which case the island-shaped EL layer can be protected from ultraviolet rays.

The step of removing the mask layers can be performed by a method similar to that for the step of processing the mask layers. In particular, when a wet etching method is used, damage to the layers 113B and 113G at the time of removing the mask layers can be reduced as compared with the case where a dry etching method is used.

In the case where a metal film or an alloy film is used for the mask layers 119B and 119G, the mask layers 119B and 119G can inhibit plasma damage to the EL layers. Thus, film processing can be performed by a dry etching method in the steps before the removal of the mask layers 119B and 119G. In contrast, in and after the step of removing the mask layers 119B and 119G, the film inhibiting plasma damage to the EL layers does not exist; thus, film processing is preferably performed by a method that does not use plasma, such as a wet etching method.

The mask layer may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed to remove water contained in the layers 113B and 113G and water adsorbed onto the surfaces of the layers 113B and 113G. For example, heat treatment in an inert gas atmosphere such as a nitrogen atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere because drying at a lower temperature is possible.

Next, the insulating film 125A to be the insulating layer 125 later is formed to cover the pixel electrodes, the layer 113B, the layer 113G, the mask layer 118B, and the mask layer 118G (FIG. 14B).

As described later, an insulating film 127a is formed in contact with the top surface of the insulating film 125A. Thus, the top surface of the insulating film 125A preferably has high adhesion to a resin composite (e.g., a photosensitive resin composite containing an acrylic resin) that is used for the insulating film 127a. To improve the adhesion, the top surface of the insulating film 125A is preferably made to be hydrophobic (or more hydrophobic) by surface treatment. For example, the treatment is preferably performed using a silylating agent such as hexamethyldisilazane (HMDS). By making the top surface of the insulating film 125A hydrophobic in this manner, the insulating film 127a can be formed with high adhesion. Note that the above-described hydrophobic treatment may be performed as the surface treatment.

Then, the insulating film 127a is formed over the insulating film 125A (FIG. 14C).

The insulating films 125A and 127a are preferably formed by a formation method that causes less damage to the layers 113B and 113G. In particular, the insulating film 125A, which is formed in contact with the side surfaces of the layers 113B and 113G, is preferably formed by a formation method that causes less damage to the layers 113B and 113G than the method for forming the insulating film 127a.

The insulating films 125A and 127a are formed at a temperature lower than the upper temperature limit of the layers 113B and 113G. When the insulating film 125A is formed at a high substrate temperature, the formed insulating film 125A, even with a small thickness, can have a high impurity concentration and a high barrier property against at least one of water and oxygen.

The insulating films 125A and 127a are preferably formed at a substrate temperature, for example, higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As described above, a material with high heat resistance is used for the light-emitting device of the display apparatus of one embodiment of the present invention. Thus, the insulating films 125A and 127a can be formed at a substrate temperature higher than or equal to 100° C., higher than or equal to 120° C., or higher than or equal to 140° C. For example, an inorganic insulating film formed at a higher temperature can be more dense and have a higher barrier property. Therefore, forming the insulating film 125A at such a temperature can further reduce damage to the layers 113B and 113G and improve the reliability of the light-emitting device.

As the insulating film 125A, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125A is preferably formed by an ALD method, for example. The use of an ALD method is preferable, in which case deposition damage is reduced and a film with good coverage can be formed. As the insulating film 125A, an aluminum oxide film is preferably formed by an ALD method, for example.

Alternatively, the insulating film 125A may be formed by a sputtering method, a CVD method, or a PECVD method that provides a higher deposition rate than an ALD method. In this case, a highly reliable display apparatus can be manufactured with high productivity.

The insulating film 127a is preferably formed by the aforementioned wet process. For example, the insulating film 127a is preferably formed by spin coating using a photosensitive resin, specifically, a photosensitive resin composite containing an acrylic resin.

Heat treatment (also referred to as pre-baking) is preferably performed after formation of the insulating film 127a. The heat treatment is performed at a temperature lower than the upper temperature limit of the layers 113B and 113G. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the insulating film 127a can be removed.

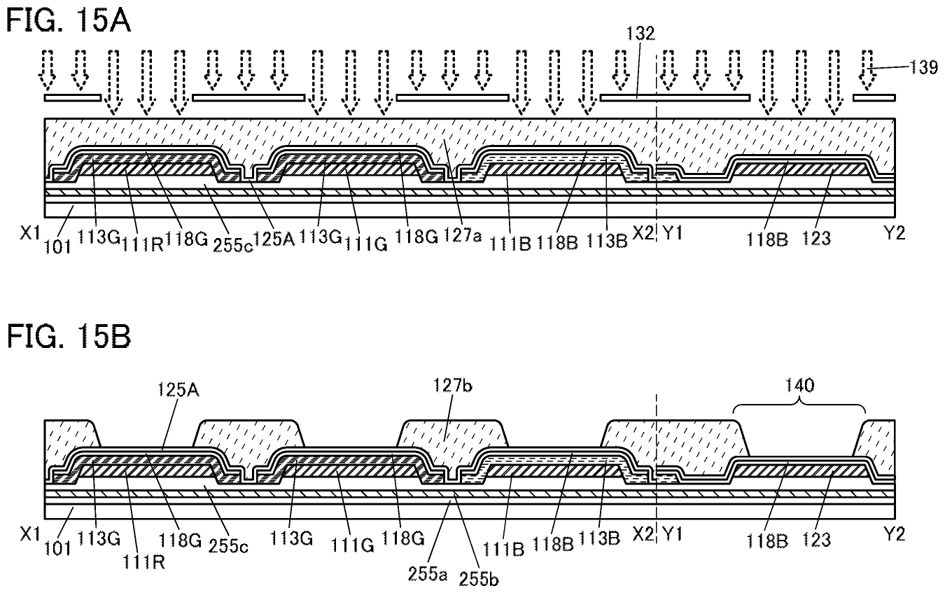

Next, part of the insulating film 127a is irradiated with visible light or ultraviolet rays as light exposure (FIG. 15A). In the case where a positive photosensitive resin composite containing an acrylic resin is used for the insulating film 127a, a region where the insulating layer 127 is not formed in a later step is irradiated with visible light or ultraviolet rays using a mask 132. The insulating layer 127 is formed in regions interposed between adjacent two pixel electrodes among the pixel electrodes 111R, 111G, and 111B, and a region surrounding the conductive layer 123. Thus, as illustrated in FIG. 15A, in the insulating film 127a, a portion overlapping with the pixel electrode 111R, a portion overlapping with the pixel electrode 111G, a portion overlapping the pixel electrode 111B, and a portion overlapping with the conductive layer 123 are irradiated with light 139.

Note that the width of the insulating layer 127 to be formed later can be controlled by the region exposed to light here. In this embodiment, the insulating film 127a is processed such that the insulating layer 127 includes a portion overlapping with the top surface of the pixel electrode (FIG. 2A). As illustrated in FIG. 5A or 5B, the insulating layer 127 does not necessarily include a portion overlapping with the top surface of the pixel electrode.

Light used for exposure preferably includes the i-line (wavelength: 365 nm). The light used for exposure may include at least one of the g-line (wavelength: 436 nm) and the h-line (wavelength: 405 nm).

Although FIG. 15A illustrates an example where a positive photosensitive resin is used for the insulating film 127a and a region where the insulating layer 127 is not formed is irradiated with visible light or ultraviolet rays, the present invention is not limited thereto. For example, a negative photosensitive resin may be used for the insulating film 127a. In this case, a region where the insulating layer 127 is formed is irradiated with visible light or ultraviolet rays.

Next, the region of the insulating film 127a exposed to light is removed by development as illustrated in FIG. 15B, so that an insulating layer 127b is formed. The insulating layer 127b is formed in regions interposed between adjacent two pixel electrodes among the pixel electrodes 111R, 111G, and 111B, and a region surrounding the conductive layer 123. In the case where an acrylic resin is used for the insulating film 127a, an alkaline solution is preferably used as a developer, and for example, an aqueous solution of tetramethyl ammonium hydroxide (TMAH) can be used.

Note that a step for removing a development residue (what is called a scum) may be performed after development. For example, the residue can be removed by ashing using oxygen plasma. The step for removing a residue may be performed after each development step described below.

Etching may be performed to adjust the surface level of the insulating layer 127b. The insulating layer 127b may be processed by ashing using oxygen plasma, for example.

Note that after development and before post-baking, light exposure may be performed on the entire substrate, by which the insulating layer 127b is irradiated with visible light or ultraviolet rays. The energy density of the light used for exposure is preferably greater than 0 mJ/cm² and less than or equal to 800 mJ/cm², further preferably greater than 0 mJ/cm² and less than or equal to 500 mJ/cm². Performing such light exposure after development can improve the transparency of the insulating layer 127b in some cases. In addition, the insulating layer 127b can be changed into a tapered shape at low temperature in some cases.

In contrast, when light exposure is not performed on the insulating layer 127b, the shape of the insulating layer 127b can be easily changed or the insulating layer 127 can be easily changed into a tapered shape in a later step in some cases. Thus, sometimes it is preferable not to perform light expose on the insulating layer 127b after development.

After that, heat treatment (also referred to as post-baking) is performed. As illustrated in FIG. 16A, the heat treatment can change the insulating layer 127b into the insulating layer 127 with a tapered side surface. The heat treatment is performed at a temperature lower than the upper temperature limit of the EL layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced pressure atmosphere. The heat treatment is preferably performed in a reduced pressure atmosphere because drying at a lower temperature is possible. The heat treatment in this step is preferably performed at a higher substrate temperature than the heat treatment (pre-baking) after formation of the insulating film 127a. In this case, adhesion between the insulating layers 127 and 125 and the corrosion resistance of the insulating layer 127 can be improved.

As illustrated in FIGS. 4A and 4B, the side surface of the insulating layer 127 might have a concave shape depending on the materials for the insulating layer 127, or the temperature, time, and atmosphere of post-baking. For example, the insulating layer 127 is more likely to be changed in shape to have a concave shape as the post-baking is performed at higher temperature or for a longer time. In addition, as described above, the insulating layer 127 is sometimes likely to be changed in shape at the time of post-baking, in the case where light exposure is not performed on the insulating layer 127b after development.

Next, as illustrated in FIG. 16A, etching treatment is performed using the insulating layer 127 as a mask to remove parts of the insulating film 125A and the mask layers 118B and 118G. Consequently, openings are formed in the mask layers 118B and 118G, and the top surfaces of the layer 113B, the layer 113G, and the conductive layer 123 are exposed.

The etching treatment can be performed by dry etching or wet etching. Note that the insulating film 125A is preferably formed using a material similar to that for the mask layers 118B and 118G, in which case etching treatment can be performed collectively.

In the case of performing dry etching, a chlorine-based gas is preferably used. As the chlorine-based gas, any of Cl₂, BCl₃, SiCl₄, CCl₄, and the like can be used alone or in combination. Furthermore, one or more of an oxygen gas, a hydrogen gas, a helium gas, an argon gas, and the like can be mixed as appropriate with the chlorine-based gas. By employing dry etching, the thin regions of the mask layers 118B and 118G can be formed with a favorable in-plane uniformity.

In the case of performing dry etching, a by-product generated by the dry etching is sometimes deposited on the top and side surfaces of the insulating layer 127b, for example. Thus, a component contained in the etching gas, a component contained in the insulating film 125A, components contained in the mask layers 118B and 118G, or the like might be contained in the insulating layer 127 after the display apparatus is completed.

Furthermore, etching treatment is preferably performed by wet etching. The use of a wet etching method can reduce damage to the layers 113B and 113G compared with the case of using a dry etching method. For example, wet etching can be performed using an alkaline solution or the like. For example, wet etching of an aluminum oxide film is preferably performed using an aqueous solution of tetramethyl ammonium hydroxide (TMAH) that is an alkaline solution. In this case, the wet etching can be performed by a paddle method.

As described above, providing the insulating layer 127, the insulating layer 125, the mask layer 118B, and the mask layer 118G can inhibit the common layer 114 and the common electrode 115 between the light-emitting devices from having connection defects due to a disconnected portion and an increase in electric resistance due to a locally thinned portion. Thus, the display quality of the display apparatus of one embodiment of the present invention can be improved.

After parts of the layers 113B and 113G are exposed, additional heat treatment may be performed. The heat treatment can remove water contained in the EL layer, water adsorbed onto the surface of the EL layer, and the like. In addition, the heat treatment changes the shape of the insulating layer 127 in some cases. Specifically, the insulating layer 127 may be extended to cover at least one of the end portion of the insulating layer 125, the end portions of the mask layers 118B and 118G, and the top surfaces of the layers 113B and 113G. For example, the insulating layer 127 may have a shape illustrated in FIGS. 3A and 3B. For example, heat treatment in an inert gas atmosphere or a reduced pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced pressure atmosphere because dehydration at a lower temperature is possible. Note that the temperature range of the heat treatment is preferably set as appropriate in consideration of the upper temperature limit of the EL layer. In consideration of the upper temperature limit of the EL layer, temperatures from 70° C. to 120° C. are particularly preferable in the above temperature range.

Here, when the insulating layer 125 and the mask layer are collectively etched after post-baking, the insulating layer 125 and the mask layers below the end portion of the insulating layer 127 are eliminated and accordingly a cavity is formed in some cases. The cavity causes unevenness in the formation surface of the common layer 114 and the common electrode 115, so that step disconnection is likely to be generated in the common layer 114 and the common electrode 115. To avoid this, the etching treatment for the insulating layer 125 and etching treatment for the mask layer are preferably performed separately before and after the post-baking.

A method for performing etching treatment for the insulating layer 125 and the mask layer separately before and after the post-baking is described below with reference to FIGS. 16B to 16E.

FIG. 16B is an enlarged view of the layer 113G, the end portion of the insulating layer 127b, and the vicinity thereof illustrated in FIG. 15B. In other words, FIG. 16B illustrates the insulating layer 127b formed by development.

Next, as illustrated in FIG. 16C, etching treatment is performed using the insulating layer 127b as a mask to remove part of the insulating film 125A, so that the mask layers 118B and 118G are partly thinned. Accordingly, the insulating layer 125 is formed below the insulating layer 127b. In addition, the surfaces of the thinned portions of the mask layers 118B and 118G are exposed. Note that the etching treatment using the insulating layer 127b as a mask is referred to as first etching treatment below in some cases.

The first etching treatment can be performed by dry etching or wet etching.

As illustrated in FIG. 16C, etching is performed using the insulating layer 127b with a tapered side surface as a mask, so that the side surface of the insulating layer 125, the upper end portions of the side surfaces of the mask layers 118B and 118G can be tapered relatively easily.

As illustrated in FIG. 16C, the first etching treatment is stopped when the mask layers 118B and 118G are thinned, before completely removing the mask layers. The mask layers 118B and 118G remain over the layers 113B and 113G in this manner, so that the layers 113B and 113G can be prevented from being damaged in treatment in a later step.

Although the mask layers 118B and 118G are thinned in FIG. 16C, the present invention is not limited thereto. For example, depending on the thicknesses of the insulating film 125A, the mask layer 118B, and the mask layer 118G, the first etching treatment might be stopped before the insulating film 125A is processed into the insulating layer 125. Specifically, the first etching treatment might be stopped after only part of the insulating film 125A is thinned. In the case where the insulating film 125A is formed using a material similar to those for the mask layers 118B and 118G and accordingly a boundary between the insulating film 125A and each of the mask layers 118B and 118G is unclear, whether the insulating layer 125 is formed or whether the mask layers 118B and 118G are thinned cannot be determined in some cases.

Although FIG. 16C illustrates an example where the shape of the insulating layer 127b is not changed from that in FIG. 16B, the present invention is not limited thereto. For example, the end portion of the insulating layer 127b sags and covers the end portion of the insulating layer 125 in some cases. In another case, the end portion of the insulating layer 127b is in contact with the top surfaces of the mask layers 118B and 118G, for example. As described above, in the case where light exposure is not performed on the insulating layer 127b after development, the shape of the insulating layer 127b is likely to change in some cases.

Next, post-baking is performed. As illustrated in FIG. 16D, the post-baking can change the insulating layer 127b into the insulating layer 127 with a tapered side surface. As described above, in some cases, the insulating layer 127b is already changed in shape and has a tapered side surface at the time when the first etching treatment is finished.

The first etching treatment does not remove the mask layers 118B and 118G completely to make the thinned mask layers 118B and 118G remain, thereby preventing the layers 113B and 113G from being damaged by the heat treatment and deteriorating. Thus, the reliability of the light-emitting device can be improved.

Next, as illustrated in FIG. 16E, etching treatment is performed using the insulating layer 127 as a mask to remove parts of the mask layers 118B and 118G. Consequently, openings are formed in the mask layers 118B and 118G, and the top surfaces of the layer 113B, the layer 113G, and the conductive layer 123 are exposed. Note that the etching treatment using the insulating layer 127 as a mask is referred to as second etching treatment in some cases below.

The end portion of the insulating layer 125 is covered with the insulating layer 127. FIG. 16E illustrates an example where part of the end portion of the mask layer 118G (specifically, a tapered portion formed by the first etching treatment) is covered with the insulating layer 127 and the tapered portion formed by the second etching treatment is exposed. That is, the structure in FIG. 16E corresponds to that in FIGS. 2A and 2B.

When etching is performed before and after post-baking in this manner, even when a cavity is formed by side etching of the insulating layer 125 and the mask layer in the first etching treatment, the subsequent post-baking can make the insulating layer 127 fill the cavity. Since the following second etching treatment etches the thinned mask layer, the amount of side etching is small and thus a cavity is not easily formed or formed to be extremely small. Therefore, the flatness of the formation surface of the common layer 114 and the common electrode 115 can be improved.

Note that as illustrated in FIGS. 3A, 4B, and 5B, the insulating layer 127 may cover the entire end portion of the mask layer 118G. For example, the end portion of the insulating layer 127 sags and covers the end portion of the mask layer 118G in some cases. Alternatively, for example, the end portion of the insulating layer 127 is in contact with the top surface(s) of one or both of the layers 113B and 113G in some cases. As described above, in the case where light exposure is not performed on the insulating layer 127b after development, the shape of the insulating layer 127 is likely to change in some cases.

The second etching treatment is preferably performed by wet etching. The use of a wet etching method can reduce damage to the layers 113B and 113G compared with the case of using a dry etching method. The wet etching can be performed using an alkaline solution or the like.

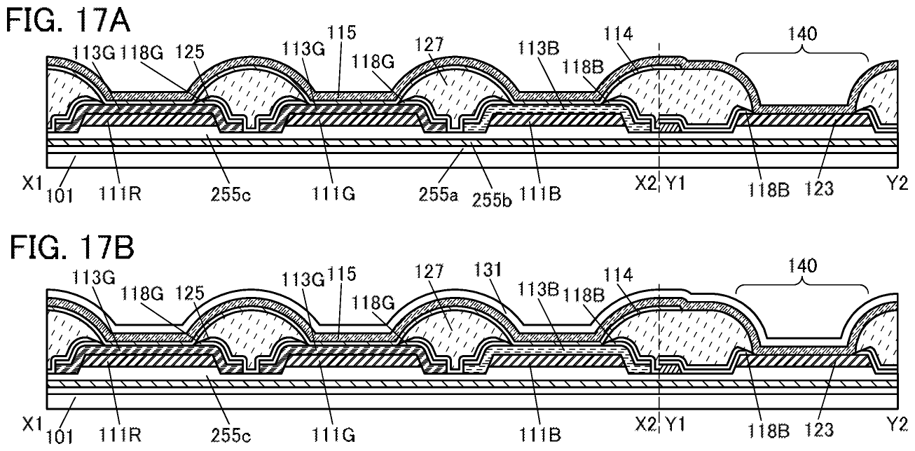

Next, the common layer 114 and the common electrode 115 are formed in this order over the insulating layer 127, the layer 113B, and the layer 113G (FIG. 17A), and the protective layer 131 is formed thereover (FIG. 17B). In the case of employing a structure including a color conversion layer and a coloring layer over the protective layer 131 as illustrated in FIG. 1B and the like, the color conversion layer 135 is provided over the protective layer 131 and the coloring layer 132R is provided over the color conversion layer 135 after the above step. Then, the substrate 120 is bonded over the protective layer 131 with the resin layer 122, whereby the display apparatus can be manufactured (FIG. 1B). In the case of employing a structure including a coloring layer and a color conversion layer on the substrate 120 side as illustrated in FIG. 8A and the like, the coloring layer 132R and the color conversion layer 135 are provided over the substrate 120 in advance and then the substrate 120 is bonded, whereby the display apparatus can be manufactured.

The common layer 114 can be formed by an evaporation method (including a vacuum evaporation method), a transfer method, a printing method, an inkjet method, a coating method, or the like.

The common electrode 115 can be formed by a sputtering method or a vacuum evaporation method, for example. Alternatively, a film formed by an evaporation method and a film formed by a sputtering method may be stacked.

Examples of methods for forming the protective layer 131 include a vacuum evaporation method, a sputtering method, a CVD method, and an ALD method.

As described above, in the method for manufacturing a display apparatus of one embodiment of the present invention, the island-shaped layers 113B and 113G are formed by processing a film formed on the entire surface, not by using a fine metal mask; thus, the island-shaped layers can have a uniform thickness. Consequently, a high-resolution display apparatus or a display apparatus with a high aperture ratio can be obtained. Furthermore, even when the resolution or the aperture ratio is high owing to an extremely short distance between subpixels, contact between the layers 113B and 113G or between the layers 113G can be inhibited. Accordingly, generation of a leakage current between subpixels can be inhibited. This can prevent crosstalk due to unintended light emission, so that a display apparatus with extremely high contrast can be obtained.

Furthermore, in the method for manufacturing a display apparatus of this embodiment, subpixels of three colors can be separately formed just by forming light-emitting devices of two colors. This can reduce damage to the pixel electrodes in the subpixels of respective colors, thereby inhibiting degradation of the characteristics of the light-emitting devices. In addition, the number of times of processing of the light-emitting layer by a photolithography method can be two; thus, the display apparatus can be manufactured with high yield.

In the method for manufacturing a display apparatus of this embodiment, a layer containing a light-emitting material emitting blue light is formed to have an island shape, and then a layer containing a light-emitting material emitting light having a longer wavelength than blue light is formed to have an island shape. Thus, the blue-light-emitting device can be inhibited from having an increased driving voltage and a shortened lifetime. In addition, the light-emitting device of each color can emit light at high luminance. Furthermore, an increase in the driving voltage of the light-emitting device of each color can be suppressed. Furthermore, the lifetime of the light-emitting device of each color can be longer and the reliability of the display apparatus can be improved.

The insulating layer 127 having a tapered end portion and being provided between adjacent island-shaped EL layers can prevent step disconnection and a locally thinned portion to be formed in the common electrode 115 at the time of forming the common electrode 115. This can inhibit the common layer 114 and the common electrode 115 to have connection defects due to the disconnected portion and an increased electric resistance due to the locally thinned portion. Thus, the display apparatus of one embodiment of the present invention can have both a higher resolution and higher display quality.

This embodiment can be combined with any of the other embodiments as appropriate.

### Embodiment 3

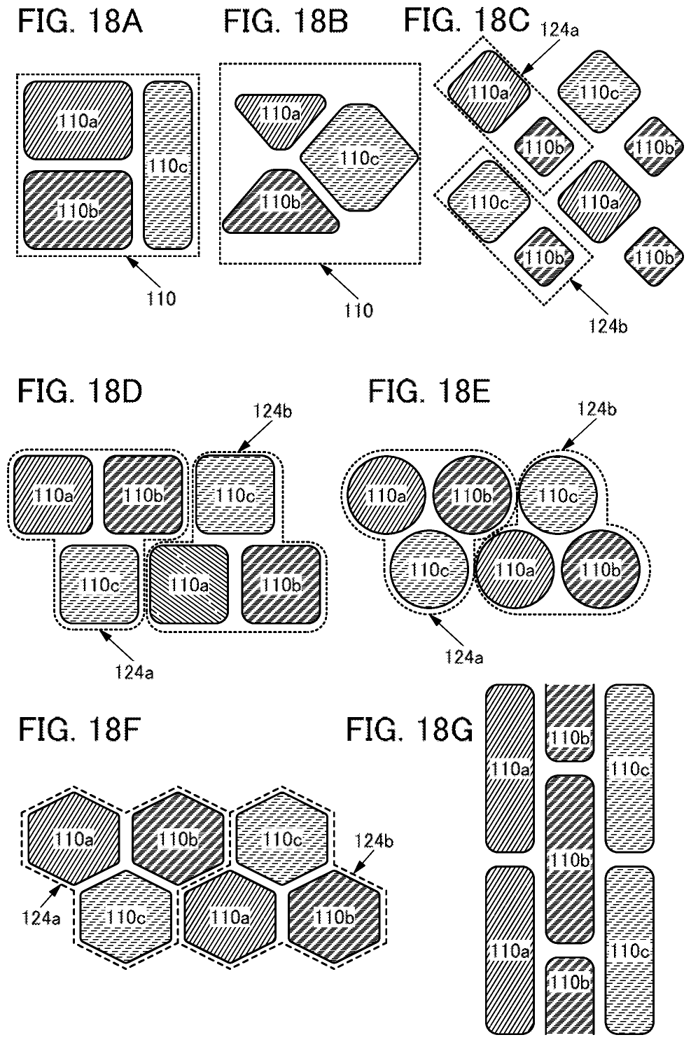

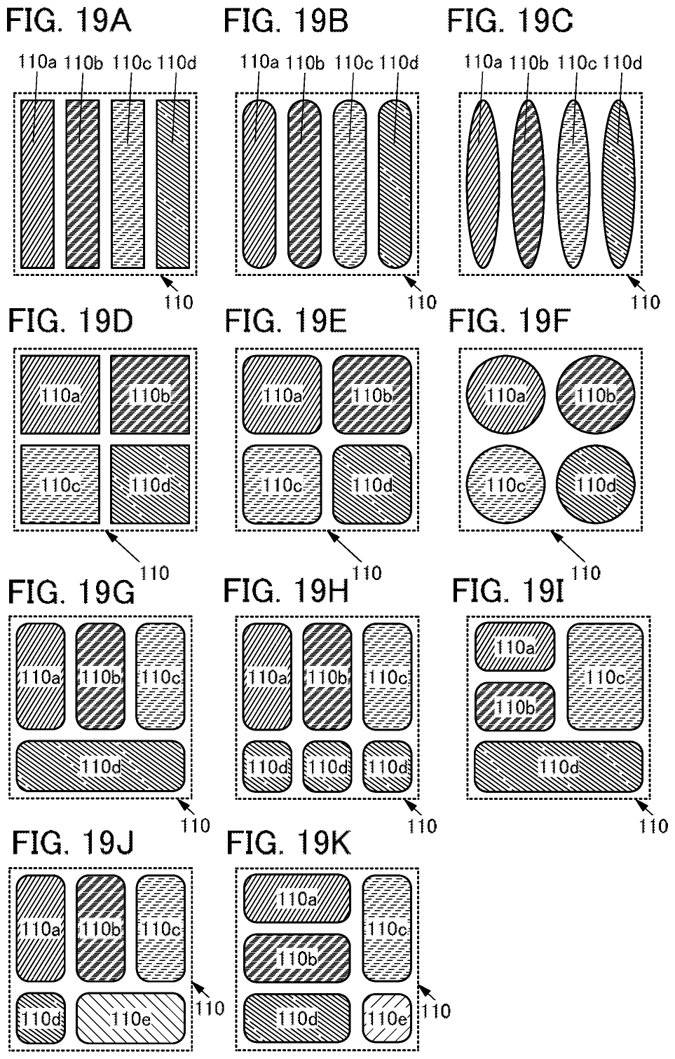

In this embodiment, a display apparatus of one embodiment of the present invention will be described with reference to FIGS. 18A to 18G and FIGS. 19A and 19K.

### [Pixel Layout]

In this embodiment, pixel layouts different from those in FIG. 1A will be mainly described. There is no particular limitation on the arrangement of subpixels, and a variety of methods can be employed. Examples of the arrangement of subpixels include stripe arrangement, S stripe arrangement, matrix arrangement, delta arrangement, Bayer arrangement, and PenTile arrangement.

The top surface shape of the subpixel illustrated in the diagrams in this embodiment corresponds to the top surface shape of a light-emitting region (or a light-receiving region).

Examples of the top surface shape of the subpixel include polygons such as a triangle, a tetragon (including a rectangle and a square), and a pentagon; polygons with rounded corners; an ellipse; and a circle.

The range of the circuit layout for forming the subpixels is not limited to the range of the subpixels illustrated in the diagrams, and the components of the circuit may be placed outside the range of the subpixels.

The pixel 110 illustrated in FIG. 18A employs S-stripe arrangement. The pixel 110 illustrated in FIG. 18A consists of three subpixels 110a, 110b, and 110c.

The pixel 110 illustrated in FIG. 18B includes the subpixel 110a whose top surface has a rough triangle or rough trapezoidal shape with rounded corners, the subpixel 110b whose top surface has a rough triangle or rough trapezoidal shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

A pixel 124a and a pixel 124b illustrated in FIG. 18C employ PenTile arrangement. FIG. 18C illustrates an example where the pixels 124a including the subpixels 110a and 110b and the pixels 124b including the subpixels 110b and 110c are alternately arranged.

The pixels 124a and 124b illustrated in FIGS. 18D and 18F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row).

FIG. 18D illustrates an example where the top surface of each subpixel has a rough square shape with rounded corners, FIG. 18E illustrates an example where the top surface of each subpixel has a circular shape, and FIG. 18F illustrates an example where the top surface of each subpixel has a rough hexagonal shape with rounded corners.

In FIG. 18F, each subpixel is provided inside one of the closest-packed hexagonal regions. Focusing on one of the subpixels, the subpixel is placed so as to be surrounded by six subpixels. In addition, the subpixels are arranged such that subpixels exhibiting the same color are not adjacent to each other. For example, focusing on the subpixel 110a, three subpixels 110b and three subpixels 110c are alternately provided so as to surround the subpixel 110a.

FIG. 18G illustrates an example where subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view.

For example, in each pixel in FIGS. 18A to 18G, it is preferable that the subpixel 110a be a subpixel R emitting red light, the subpixel 110b be a subpixel G emitting green light, and the subpixel 110c be a subpixel B emitting blue light. Note that the structures of the subpixels are not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing the display apparatus of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a transferred pattern agrees with a design pattern (an optical proximity correction (OPC) technique) may be used. Specifically, with the OPC technique, a pattern for correction is added to a corner portion or the like of a figure on a mask pattern.

As illustrated in FIGS. 19A to 191, the pixel can include four types of subpixels.

The pixel 110 illustrated in FIGS. 19A to 19C employs stripe arrangement.

FIG. 19A illustrates an example where each subpixel has a rectangular top surface shape, FIG. 19B illustrates an example where each subpixel has a top surface shape formed by combining two half circles and a rectangle, and FIG. 19C illustrates an example where each subpixel has an elliptical top surface shape.

The pixel 110 illustrated in FIGS. 19D to 19F employs matrix arrangement.

FIG. 19D illustrates an example where the top surface of each subpixel has a square shape, FIG. 19E illustrates an example where the top surface of each subpixel has a rough square shape with rounded corners, and FIG. 19F illustrates an example where the top surface of each subpixel has a circular shape.

FIGS. 19G and 19H each illustrate an example where one pixel 110 is composed of two rows and three columns.

The pixel 110 illustrated in FIG. 19G includes three subpixels (the subpixels 110a, 110b, and 110c) in the upper row (first row) and one subpixel (subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 19H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Matching the positions of the subpixels in the upper row and the lower row as illustrated in FIG. 19H enables dust and the like that would be produced in the manufacturing process to be removed efficiently. Thus, a display apparatus having high display quality can be provided.

FIG. 19I illustrates an example where one pixel 110 is composed of three rows and two columns.

The pixel 110 illustrated in FIG. 19I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixel 110 illustrated in FIGS. 19A to 191 includes four types of subpixels 110a, 110b, 110c, and 110d.

The subpixels 110a, 110b, 110c, and 110d include light-emitting devices that emit light of different colors. The subpixels 110a, 110b, 110c, and 110d can be of four colors of R, G, B, and white (W), of four colors of R, G, B, and Y, or of R, G, B and infrared (IR) light, for example.

In the pixel 110 illustrated in FIGS. 19A to 191, it is preferable that the subpixel 110a be the subpixel R emitting red light, the subpixel 110b be the subpixel G emitting green light, the subpixel 110c be the subpixel B emitting blue light, and the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixel 110 illustrated in FIGS. 19G and 19H, leading to an increase in the display quality. In the pixel 110 illustrated in FIG. 19I, what is called S stripe arrangement is employed as the layout of R, G, and B, leading to higher display quality.

The pixel 110 may include a subpixel including a light-receiving device.

In the pixel 110 illustrated in FIGS. 19A to 191, any one of the subpixels 110a to 110d may be a subpixel including a light-receiving device.

In the pixel 110 illustrated in FIGS. 19A to 191, for example, it is preferable that the subpixel 110a be the subpixel R emitting red light, the subpixel 110b be the subpixel G emitting green light, the subpixel 110c be the subpixel B emitting blue light, and the subpixel 110d be a subpixel S including a light-receiving device. In the case of such a structure, stripe arrangement is employed as the layout of R, G, and B in the pixel 110 illustrated in FIGS. 19G and 19H, leading to higher display quality. In addition, what is called S stripe arrangement is employed as the layout of R, G, and B in the pixel 110 illustrated in FIG. 19I, leading to higher display quality.

There is no particular limitation on the wavelength of light detected by the subpixel S including a light-receiving device. The subpixel S can have a structure in which one or both of infrared light and visible light can be detected.

As illustrated in FIGS. 19J and 19K, the pixel can include five types of subpixels.

FIG. 19J illustrates an example where one pixel 110 is composed of two rows and three columns.

The pixel 110 illustrated in FIG. 19J includes three subpixels (the subpixels 110a, 110b, and 110c) in the upper row (first row) and two subpixels (the subpixel 110d and a subpixel 110e) in the lower row (second row). In other words, the pixel 110 includes the subpixels 110a and 110d in the left column (first column), the subpixel 110b in the center column (second column), the subpixel 110c in the right column (third column), and the subpixel 110e across the second and third columns.

FIG. 19K illustrates an example where one pixel 110 is composed of three rows and two columns.

The pixel 110 illustrated in FIG. 19K includes the subpixel 110a in the upper row (first row), the subpixel 110b in the center row (second row), the subpixel 110c across the first and second rows, and two subpixels (the subpixels 110d and 110e) in the lower row (third row). In other words, the pixel 110 includes the subpixels 110a, 110b, and 110d in the left column (first column), and the subpixels 110c and 110e in the right column (second column).

In the pixel 110 illustrated in FIGS. 19J and 19K, for example, it is preferable that the subpixel 110a be the subpixel R emitting red light, the subpixel 110b be the subpixel G emitting green light, and the subpixel 110c be the subpixel B emitting blue light. In the case of such a structure, stripe arrangement is employed as the layout of R, G, and B in the pixel 110 illustrated in FIGS. 19J, leading to higher display quality. In addition, what is called S stripe arrangement is employed as the layout of R, G, and B in the pixel 110 illustrated in FIG. 19K, leading to higher display quality.

In the pixel 110 illustrated in FIGS. 19J and 19K, for example, it is preferable to use the subpixel S including a light-receiving device as at least one of the subpixels 110d and 110e. In the case where light-receiving devices are used in both the subpixels 110d and 110e, the light-receiving devices may have different structures. For example, the wavelength ranges of detected light may be different at least partly. Specifically, one of the subpixels 110d and 110e may include a light-receiving device mainly detecting visible light and the other may include a light-receiving device mainly detecting infrared light.

In the pixel 110 illustrated in FIGS. 19J and 19K, for example, it is preferable that the subpixel S including a light-receiving device be used as one of the subpixels 110d and 110e and a subpixel including a light-receiving device that can be used as a light source be used as the other. For example, it is preferable that one of the subpixels 110d and 110e be the subpixel IR emitting infrared light and the other be the subpixel S including a light-receiving device detecting infrared light.

In the pixel including the subpixels R, G, B, IR, and S, while displaying an image using the subpixels R, G, and B, the subpixel S can detect reflected light of infrared light emitted from the subpixel IR that is used as a light source.

As described above, the pixel composed of the subpixels each including the light-emitting device can employ any of a variety of layouts in the display apparatus of one embodiment of the present invention. The display apparatus of one embodiment of the present invention can have a structure in which the pixel includes both a light-emitting device and a light-receiving device. In this case, any of a variety of layouts can be employed.

This embodiment can be combined with any of the other embodiments as appropriate.

### Embodiment 4

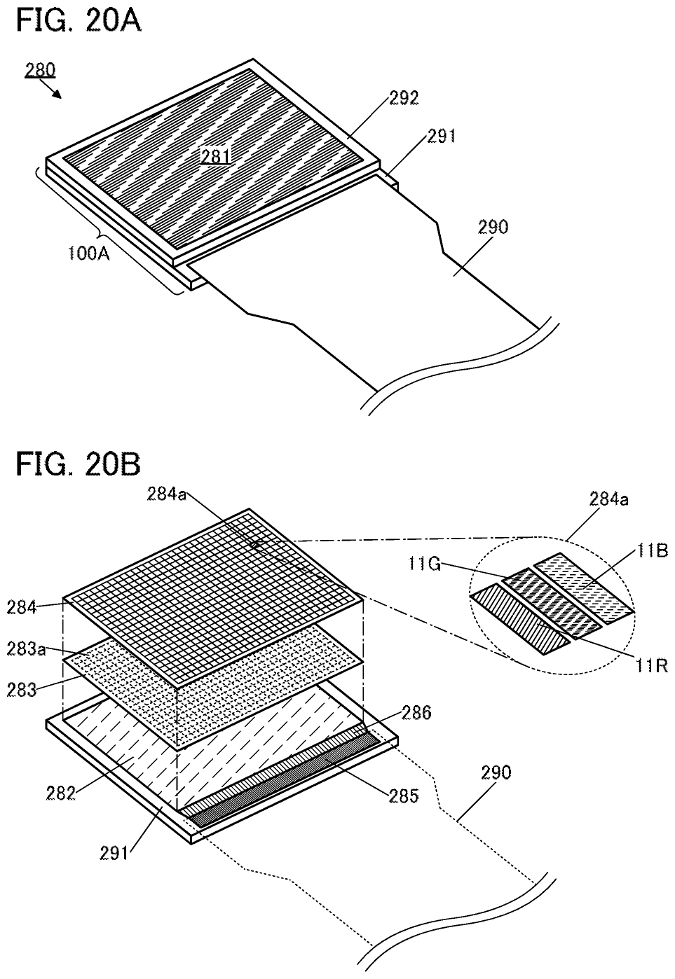

In this embodiment, display apparatuses of embodiments of the present invention are described with reference to FIGS. 20A and 20B, FIGS. 21A and 21B, and FIGS. 22 to 30.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus in this embodiment can be a high-definition display apparatus or a large-sized display apparatus. Accordingly, the display apparatus in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Module]

FIG. 20A is a perspective view of a display module 280. The display module 280 includes a display apparatus 100A and an FPC 290. Note that the display apparatus included in the display module 280 is not limited to the display apparatus 100A and may be any of display apparatuses 100B to 100F described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 20B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 20B. The pixel 284a can employ any of the structures described in the above embodiments. FIG. 20B illustrates an example where a structure similar to that of the pixel 110 illustrated in FIG. 1A is employed.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display apparatus is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, and further preferably greater than or equal to 60% and less than or equal to 95%. Furthermore, the pixels 284a can be arranged extremely densely and thus the display portion 281 can have greatly high resolution. For example, the pixels 284a are preferably arranged in the display portion 281 with a resolution greater than or equal to 2000 ppi, preferably greater than or equal to 3000 ppi, further preferably greater than or equal to 5000 ppi, and still further preferably greater than or equal to 6000 ppi, and less than or equal to 20000 ppi or less than or equal to 30000 ppi.

Such a display module 280 has extremely high resolution, and thus can be suitably used for a device for VR such as an HMD or a glasses-type device for AR. For example, even in the case of a structure in which the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Apparatus 100A]

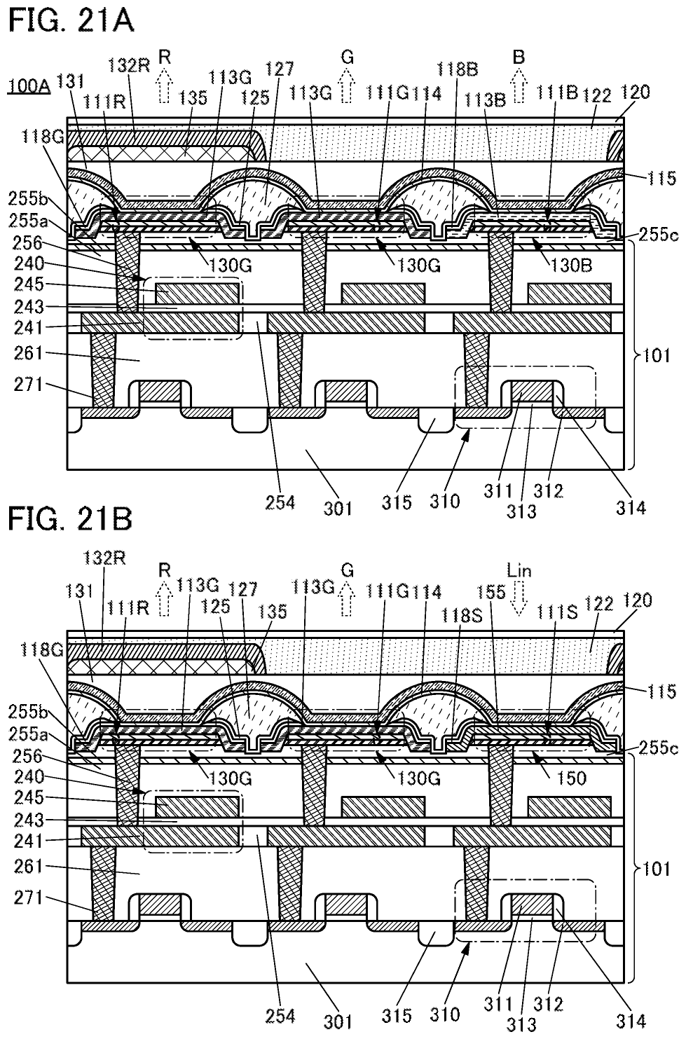

The display apparatus 100A illustrated in FIG. 21A includes a substrate 301, the light-emitting device 130G emitting green light, the light-emitting device 130B emitting blue light, the coloring layer 132R transmitting red light, the color conversion layer 135 converting green light into red light, a capacitor 240, and a transistor 310.

The subpixel 11R illustrated in FIG. 20B includes the light-emitting device 130G, the color conversion layer 135, and the coloring layer 132R, the subpixel 11G includes the light-emitting device 130G, and the subpixel 11B includes the light-emitting device 130B. In the subpixel 11R, light emitted from the light-emitting device 130G is extracted as red light (R) to the outside of the display apparatus 100A through the color conversion layer 135 and the coloring layer 132R. In the subpixel 11G, light emitted from the light-emitting device 130G is extracted as green light (G) to the outside of the display apparatus 100A. In the subpixel 11B, light emitted from the light-emitting device 130B is extracted as blue light (B) to the outside of the display apparatus 100A.

The substrate 301 corresponds to the substrate 291 in FIGS. 20A and 20B. A stacked-layer structure including the substrate 301 and the components thereover up to the insulating layer 255c corresponds to the layer 101 including transistors in Embodiment 1.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided between two adjacent transistors 310 so as to be embedded in the substrate 301.

Furthermore, an insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 101 including transistors. The conductive layer can be referred to as a guard ring. By providing the conductive layer, elements such as a transistor and a light-emitting device can be inhibited from being broken by high voltage application due to electronic discharge (ESD) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting devices 130G and 130B are provided over the insulating layer 255c. FIG. 21A illustrates an example where the light-emitting devices 130G and 130B each have the same structure as the stacked-layer structure illustrated in FIG. 1B. An insulator is provided in a region between adjacent light-emitting devices. In FIG. 21A and the like, the insulating layer 125 and the insulating layer 127 over the insulating layer 125 are provided in the region.

The mask layer 118G is positioned over the layer 113G included in the light-emitting device 130G, and the mask layer 118B is positioned over the layer 113B included in the light-emitting device 130B.

The pixel electrodes 111R, 111G, and 111B are each electrically connected to one of the source and the drain of the transistor 310 through a plug 256 embedded in the insulating layers 243, 255a, 255b, and 255c, the conductive layer 241 embedded in the insulating layer 254, and the plug 271 embedded in the insulating layer 261. The top surface of the insulating layer 255c and the top surface of the plug 256 are level with or substantially level with each other. Any of a variety of conductive materials can be used for the plugs. FIG. 21A and the like illustrate an example where the pixel electrode has a two-layer structure of a reflective electrode and a transparent electrode over the reflective electrode.

The protective layer 131 is provided over the light-emitting devices 130G and 130B. The color conversion layer 135 and the coloring layer 132R are stacked over the protective layer 131 at a position overlapping with part of the light-emitting device 130G, and the substrate 120 is bonded with the resin layer 122. Embodiment 1 can be referred to for the details of the light-emitting devices and the components thereover up to the substrate 120. The substrate 120 corresponds to the substrate 292 in FIG. 20A.

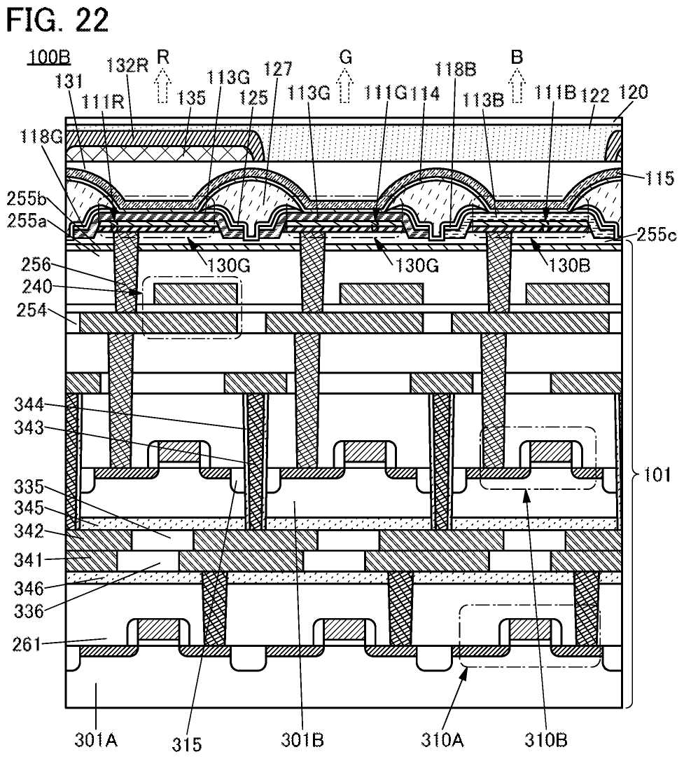

The display apparatus illustrated in FIG. 21B includes the light-emitting device 130G and the light-receiving device 150. Although not illustrated, the display apparatus also includes the light-emitting device 130B. The structure of the layer 101 including transistors in the display apparatus illustrated in FIG. 21B is not limited to that illustrated in FIG. 21A, and any of the structures illustrated in FIGS. 22 to 26 may be employed.

The light-receiving device 150 includes the pixel electrode 111S, the layer 155, the common layer 114, and the common electrode 115. Embodiments 1 and 6 can be referred to for the details of the display apparatus including the light-receiving device.

### [Display Apparatus 100B]

The display apparatus 100B illustrated in FIG. 22 has a structure where a transistor 310A and a transistor 310B in each of which a channel is formed in a semiconductor substrate are stacked. Note that in the following description of display apparatuses, the description of portions similar to those of the above-described display apparatuses may be omitted.

In the display apparatus 100B, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 over the substrate 301A. The insulating layers 345 and 346 function as protective layers and can inhibit diffusion of impurities into the substrates 301B and 301A. For the insulating layers 345 and 346, an inorganic insulating film that can be used for the protective layer 131 or an insulating layer 332 can be used.

The substrate 301B is provided with a plug 343 that penetrates the substrate 301B and the insulating layer 345. An insulating layer 344 is preferably provided to cover a side surface of the plug 343. The insulating layer 344 functions as a protective layer and can inhibit diffusion of impurities into the substrate 301B. For the insulating layer 344, an inorganic insulating film that can be used for the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layers 341 and 342 are bonded to each other, whereby the substrates 301A and 301B are electrically connected to each other. Here, improving the flatness of a plane formed by the conductive layer 342 and the insulating layer 335 and a plane formed by the conductive layer 341 and the insulating layer 336 allows the conductive layers 341 and 342 to be bonded to each other favorably.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layers 341 and 342. In this case, it is possible to employ copper-to-copper (Cu-to-Cu) direct bonding (a technique for achieving electrical continuity by connecting copper (Cu) pads).

### [Display Apparatus 100C]

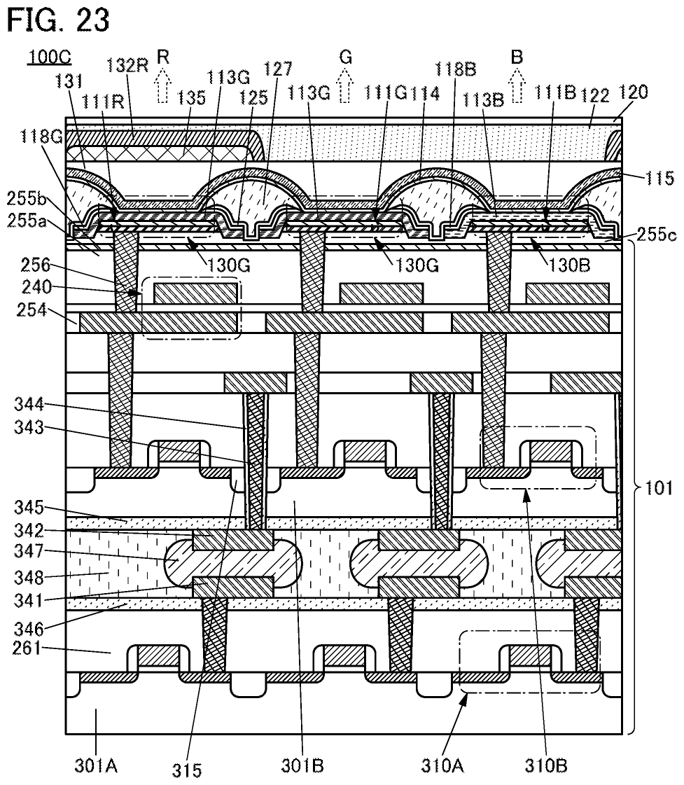

In the display apparatus 100C illustrated in FIG. 23, the conductive layers 341 and 342 are bonded to each other with a bump 347.

As illustrated in FIG. 23, providing the bump 347 between the conductive layers 341 and 342 enables the conductive layers 341 and 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layers 345 and 346. In the case where the bump 347 is provided, the insulating layers 335 and 336 may be omitted.

### [Display Apparatus 100D]

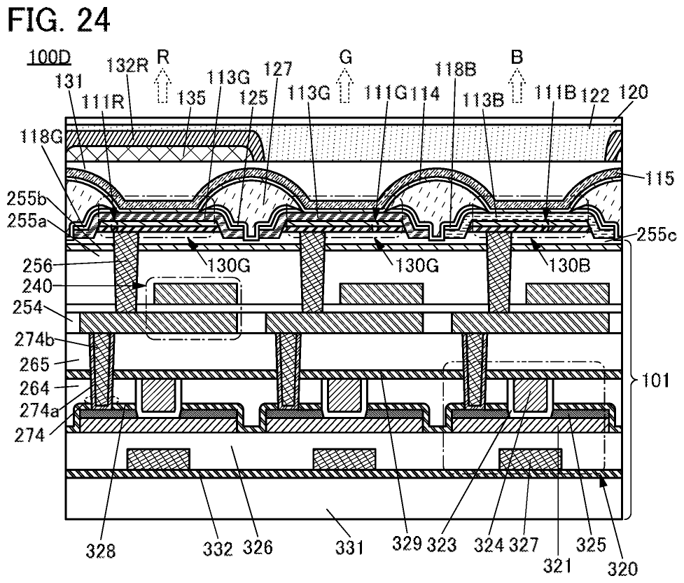

The display apparatus 100D illustrated in FIG. 24 differs from the display apparatus 100A mainly in a structure of a transistor.

A transistor 320 is a transistor that includes metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 illustrated in FIGS. 20A and 20B. A stacked-layer structure including the substrate 331 and the components thereover up to the insulating layer 255c corresponds to the layer 101 including transistors in Embodiment 1. As the substrate 331, an insulating substrate or a semiconductor substrate can be used.

The insulating layer 332 is provided over the substrate 331. The insulating layer 332 functions as a barrier layer that prevents diffusion of an impurity such as water or hydrogen from the substrate 331 into the transistor 320 and release of oxygen from the semiconductor layer 321 to the insulating layer 332 side. As the insulating layer 332, it is possible to use, for example, a film in which hydrogen or oxygen is less likely to diffuse than in a silicon oxide film, such as an aluminum oxide film, a hafnium oxide film, or a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 which is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used as the semiconductor layer 321. The pair of conductive layers 325 are provided over and in contact with the semiconductor layer 321, and function as a source electrode and a drain electrode.

An insulating layer 328 is provided to cover top and side surfaces of the pair of conductive layers 325, a side surface of the semiconductor layer 321, and the like, and an insulating layer 264 is provided over the insulating layer 328. The insulating layer 328 functions as a barrier layer that prevents diffusion of an impurity such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layers 328 and 264. The insulating layer 323 that is in contact with side surfaces of the insulating layers 264 and 328 and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level with or substantially level with each other, and an insulating layer 329 and an insulating layer 265 are provided to cover these layers.

The insulating layers 264 and 265 each function as an interlayer insulating layer. The insulating layer 329 functions as a barrier layer that prevents diffusion of an impurity such as water or hydrogen from the insulating layer 265 or the like into the transistor 320. As the insulating layer 329, an insulating film similar to the insulating layers 328 and 332 can be used.

A plug 274 electrically connected to one of the pair of conductive layers 325 is provided to be embedded in the insulating layers 265, 329, and 264. Here, the plug 274 preferably includes a conductive layer 274a that covers a side surface of an opening formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

### [Display Apparatus 100E]

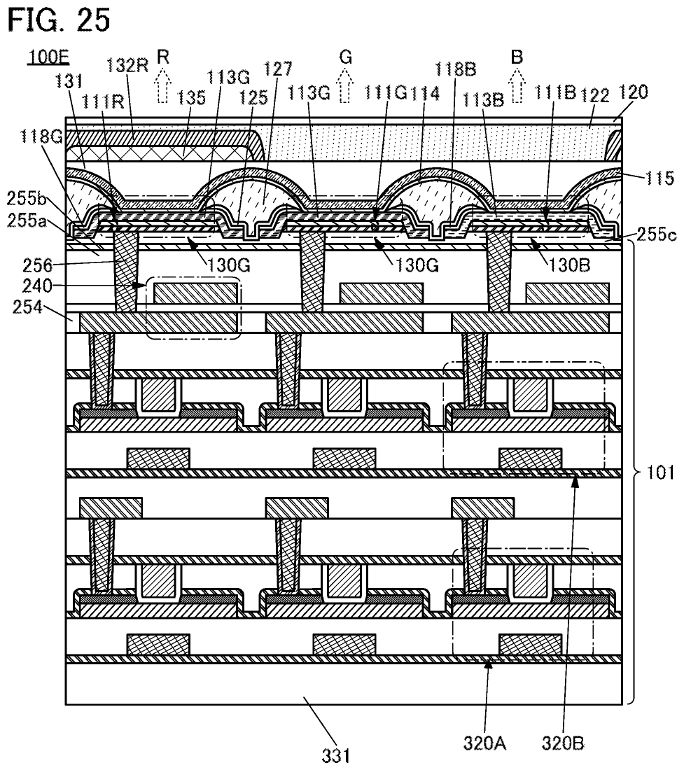

The display apparatus 100E illustrated in FIG. 25 has a structure in which a transistor 320A and a transistor 320B each including an oxide semiconductor in a semiconductor where a channel is formed are stacked.

The description of the display apparatus 100D can be referred to for the transistor 320A, the transistor 320B, and the components around them.

Although the structure in which two transistors each including an oxide semiconductor are stacked is described, one embodiment of the present invention is not limited thereto. For example, three or more transistors may be stacked.

### [Display Apparatus 100F]

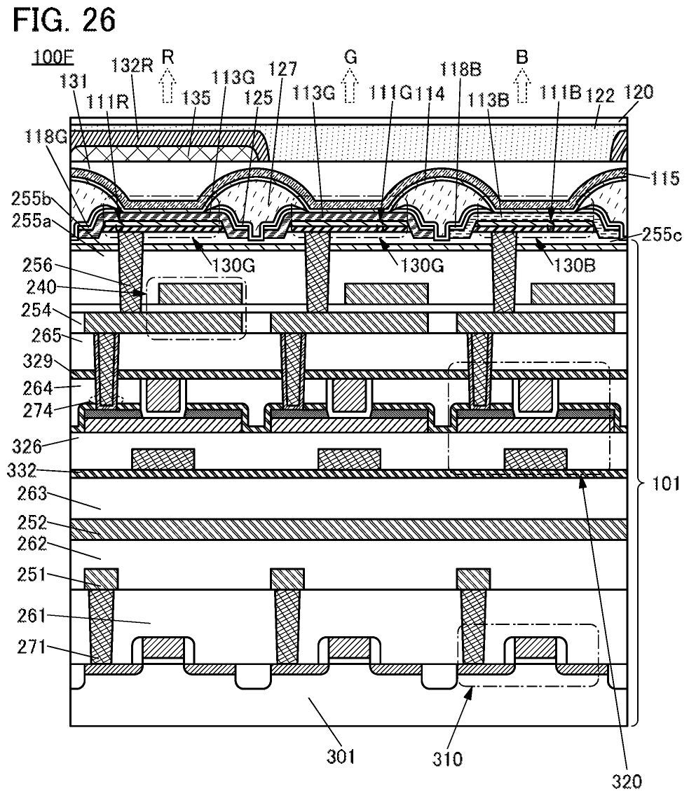

In the display apparatus 100F illustrated in FIG. 26, the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting device; thus, the display apparatus can be downsized as compared with the case where the driver circuit is provided around a display region.

### [Display Apparatus 100G]

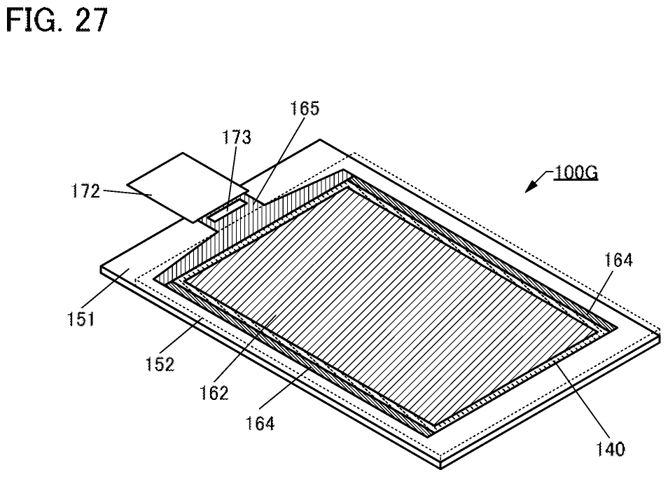

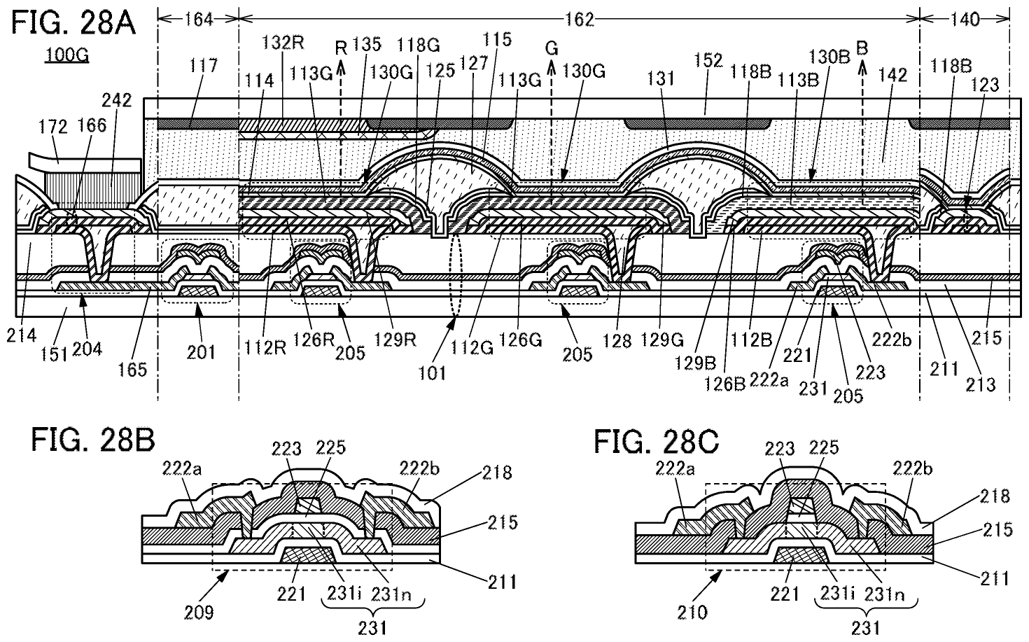

FIG. 27 is a perspective view of a display apparatus 100G, and FIG. 28A is a cross-sectional view of the display apparatus 100G.

In the display apparatus 100G, a substrate 152 and a substrate 151 are bonded to each other. In FIG. 27, the substrate 152 is indicated by a dashed line.

The display apparatus 100G includes a display portion 162, the connection portion 140, circuits 164, a wiring 165, and the like. FIG. 27 illustrates an example where an IC 173 and an FPC 172 are mounted on the display apparatus 100G. Thus, the structure illustrated in FIG. 27 can be regarded as a display module including the display apparatus 100G, the integrated circuit (IC), and the FPC.

The connection portion 140 is provided outside the display portion 162. The connection portion 140 can be provided along one or more sides of the display portion 162. The number of the connection portions 140 may be one or more. FIG. 27 illustrates an example where the connection portion 140 is provided to surround the four sides of the display portion. The common electrode of the light-emitting device is electrically connected to a conductive layer in the connection portion 140, and thus a potential can be supplied to the common electrode.

As the circuit 164, a scan line driver circuit can be used, for example.

The wiring 165 has a function of supplying a signal and power to the display portion 162 and the circuits 164. The signal and power are input to the wiring 165 from the outside through the FPC 172 or from the IC 173.

FIG. 27 illustrates an example where the IC 173 is provided over the substrate 151 by a chip on glass (COG) method, a chip on film (COF) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 28A illustrates an example of cross sections of part of a region including the FPC 172, part of the circuit 164, part of the display portion 162, part of the connection portion 140, and part of a region including an end portion of the display apparatus 100G.

The display apparatus 100G illustrated in FIG. 28A includes, between the substrate 151 and the substrate 152, a transistor 201, a transistor 205, the light-emitting device 130G emitting green light, the light-emitting device 130B emitting blue light, the color conversion layer 135 converting green light into red light, the coloring layer 132R transmitting red light, and the like.

Other than a difference in the structure of pixel electrode, the light-emitting devices 130G and 130B each have a structure similar to the stacked-layer structure illustrated in FIG. 1B. Embodiment 1 can be referred to for the details of the light-emitting devices.

The light-emitting device 130G overlapping with the color conversion layer 135 and the coloring layer 132R includes a conductive layer 112R, a conductive layer 126R over the conductive layer 112R, and a conductive layer 129R over the conductive layer 126R. All of the conductive layers 112R, 126R, and 129R can be referred to as pixel electrodes, or one or two of them can be referred to as pixel electrodes.

The light-emitting device 130G not overlapping with the color conversion layer 135 and the coloring layer 132R includes a conductive layer 112G, a conductive layer 126G over the conductive layer 112G, and a conductive layer 129G over the conductive layer 126G.

The light-emitting device 130B includes a conductive layer 112B, a conductive layer 126B over the conductive layer 112B, and a conductive layer 129B over the conductive layer 126B.

The conductive layer 112R is connected to a conductive layer 222b included in the transistor 205 through the opening provided in the insulating layer 214. An end portion of the conductive layer 126R is positioned on the outer side of an end portion of the conductive layer 112R. The end portion of the conductive layer 126R and the end portion of the conductive layer 129R are aligned or substantially aligned with each other. A conductive layer functioning as a reflective electrode can be used as the conductive layer 112R and the conductive layer 126R, and a conductive layer functioning as a transparent electrode can be used as the conductive layer 129R, for example.

Since the conductive layers 112G, 126G, and 129G and the conductive layers 112B, 126B, and 129B are similar to the conductive layers 112R, 126R, and 129R, the detailed description thereof is omitted.

The conductive layers 112R, 112G, and 112B are formed to cover the openings provided in the insulating layer 214. A layer 128 is embedded in the depressed portion of the conductive layers 112R, 112G, and 112B.

The layer 128 has a function of filling the depressed portions formed by the conductive layers 112R, 112G, and 112B. The conductive layers 126R, 126G, and 126B electrically connected to the conductive layers 112R, 112G, and 112B, respectively, are provided over the conductive layers 112R, 112G, and 112B and the layer 128. Thus, regions overlapping with the depressed portions of the conductive layers 112R, 112G, and 112B can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material, particularly preferably formed using an organic insulating material. For the layer 128, an organic insulating material that can be used for the insulating layer 127 can be used, for example.

The top and side surfaces of the conductive layers 126R and 129R are covered with the layer 113G. Similarly, the top and side surfaces of the conductive layers 126G and 129G are covered with the layer 113G, and the top and side surfaces of the conductive layers 126B and 129B are covered with the layer 113B. Accordingly, regions provided with the conductive layers 126R, 126G, and 126B can be entirely used as the light-emitting regions of the light-emitting devices 130G and 130B, thereby increasing the aperture ratio of the pixels.

The side surface and part of the top surface of each of the layers 113B and 113G is covered with the insulating layers 125 and 127. The mask layer 118B is positioned between the layer 113B and the insulating layer 125. The mask layer 118G is positioned between the layer 113G and the insulating layer 125. The common layer 114 is provided over the layers 113B and 113G and the insulating layers 125 and 127, and the common electrode 115 is provided over the common layer 114. The common layer 114 and the common electrode 115 are each one continuous film shared by a plurality of light-emitting devices.

The protective layer 131 is provided over the light-emitting devices 130G and 130B. The protective layer 131 and the substrate 152 are bonded to each other with an adhesive layer 142. The substrate 152 is provided with a light-blocking layer 117, the coloring layer 132R, and the color conversion layer 135. A solid sealing structure, a hollow sealing structure, or the like can be employed to seal the light-emitting devices. In FIG. 28A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In this case, the adhesive layer 142 may be provided not to overlap with the light-emitting devices. Alternatively, the space may be filled with a resin other than the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit 164. It is further preferable that the protective layer 131 be provided to extend to the end portion of the display apparatus 100G. Meanwhile, a connection portion 204 has a portion not provided with the protective layer 131 so that the FPC 172 and the conductive layer 166 are electrically connected to each other.

The connection portion 204 is provided in a region of the substrate 151 not overlapping with the substrate 152. In the connection portion 204, the wiring 165 is electrically connected to the FPC 172 through the conductive layer 166 and a connection layer 242. An example is illustrated where the conductive layer 166 has a stacked-layer structure of a conductive film obtained by processing the same conductive film as the conductive layers 112R, 112G, and 112B; a conductive film obtained by processing the same conductive film as the conductive layers 126R, 126G, and 126B; and a conductive film obtained by processing the same conductive film as the conductive layers 129R, 129G, and 129B. On the top surface of the connection portion 204, the conductive layer 166 is exposed. Thus, the connection portion 204 and the FPC 172 can be electrically connected to each other through the connection layer 242.

For example, the protective layer 131 is formed over the entire surface of the display apparatus 100G and then a region of the protective layer 131 overlapping with the conductive layer 166 is removed, so that the conductive layer 166 can be exposed.

Furthermore, a stacked-layer structure of at least one organic layer and a conductive layer may be provided over the conductive layer 166, and the protective layer 131 may be provided over the stacked-layer structure. Then, a peeling trigger (a portion that can be a trigger of peeling) may be formed in the stacked-layer structure using laser or a sharp cutter (e.g., a needle or a utility knife) to selectively remove the stacked-layer structure and the protective layer 131 thereover, so that the conductive layer 166 may be exposed. For example, the protective layer 131 can be selectively removed when an adhesive roller is pressed to the substrate 151 and then moved relatively while being rolled. Alternatively, an adhesive tape may be attached to the substrate 151 and then peeled. Since adhesion between the organic layer and the conductive layer or between the organic layers is low, separation occurs at the interface between the organic layer and the conductive layer or in the organic layer. Thus, a region of the protective layer 131 overlapping with the conductive layer 166 can be selectively removed. Note that when the organic layer and the like remain over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layer 113B or 113G, for example. The organic layer may be formed concurrently with the layer 113B or 113G, or may be provided separately. The conductive layer can be formed using the same process and the same material as the common electrode 115. An ITO film is preferably formed as the common electrode 115 and the conductive layer, for example. Note that in the case where a stacked-layer structure is used for the common electrode 115, at least one of the layers included in the common electrode 115 is provided as the conductive layer.

The top surface of the conductive layer 166 may be covered with a mask so that the protective layer 131 is not provided over the conductive layer 166. As the mask, a metal mask (area metal mask) or a tape or a film having adhesiveness or attachability may be used. The protective layer 131 is formed while the mask is placed and then the mask is removed, so that the conductive layer 166 can be kept exposed even after the protective layer 131 is formed.

With such a method, a region not provided with the protective layer 131 can be formed in the connection portion 204, and the conductive layer 166 and the FPC 172 can be electrically connected to each other through the connection layer 242 in the region.

The conductive layer 123 is provided over the insulating layer 214 in the connection portion 140. An example is illustrated where the conductive layer 123 has a stacked-layer structure of a conductive film obtained by processing the same conductive film as the conductive layers 112R, 112G, and 112B; a conductive film obtained by processing the same conductive film as the conductive layers 126R, 126G, and 126B; and a conductive film obtained by processing the same conductive film as the conductive layers 129R, 129G, and 129B. The end portion of the conductive layer 123 is covered with the mask layer 118B, the insulating layer 125, and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are directly and electrically connected to each other.

The display apparatus 100G is a top-emission display apparatus. Light emitted from the light-emitting devices is emitted toward the substrate 152. For the substrate 152, a material having a high visible-light-transmitting property is preferably used. The pixel electrode contains a material that reflects visible light, and the counter electrode (the common electrode 115) contains a material that transmits visible light.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same materials in the same steps.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and improve the reliability of a display apparatus.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 214 may have a stacked-layer structure of an organic insulating layer and an inorganic insulating layer. The outermost layer of the insulating layer 214 preferably has a function of an etching protective layer. Thus, the formation of a depressed portion in the insulating layer 214 can be inhibited in processing the conductive layer 112R, the conductive layer 126R, the conductive layer 129R, or the like. Alternatively, a depressed portion may be formed in the insulating layer 214 in processing the conductive layer 112R, the conductive layer 126R, the conductive layer 129R, or the like.

Each of the transistors 201 and 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for the transistors 201 and 205. The two gates may be connected to each other and supplied with the same signal to operate the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

It is preferable that a semiconductor layer of a transistor contain a metal oxide (also referred to as an oxide semiconductor). That is, a transistor including a metal oxide in its channel formation region (hereinafter also referred to as an OS transistor) is preferably used in the display apparatus of this embodiment.

As the oxide semiconductor having crystallinity, a c-axis aligned crystalline oxide semiconductor (CAAC-OS), a nanocrystalline oxide semiconductor (nc-OS), and the like are given.

Alternatively, a transistor containing silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display unit. This allows simplification of an external circuit mounted on the display apparatus and a reduction in costs of parts and mounting costs.

The OS transistor has much higher field-effect mobility than a transistor containing amorphous silicon. In addition, the OS transistor has an extremely low leakage current between a source and a drain in an off state (hereinafter also referred to as off-state current), and electric charge accumulated in a capacitor that is connected in series to the transistor can be held for a long period. Furthermore, the power consumption of the display apparatus can be reduced with the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher withstand voltage between a source and a drain than a Si transistor; hence, high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor in the pixel circuit, a current flowing between the source and the drain can be set minutely in accordance with a change in gate-source voltage; hence, the amount of current flowing through the light-emitting device can be controlled. Accordingly, the gray level in the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, with use of an OS transistor as a driving transistor included in the pixel circuit, it is possible to achieve “inhibition of black floating”, “increase in emission luminance”, “increase in gray level”, “inhibition of variation in light-emitting devices”, and the like.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

When the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide are In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the vicinity thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the vicinity thereof, the case is included where the atomic proportion of Ga is greater than 0.1 and less than or equal to 2 and the atomic proportion of Zn is greater than 0.1 and less than or equal to 2 with the atomic proportion of In being 1.

The transistors included in the circuit 164 and the transistors included in the display portion 162 may have the same structure or different structures. One structure or two or more kinds of structures may be employed for a plurality of transistors included in the circuit 164. Similarly, one structure or two or more kinds of structures may be employed for a plurality of transistors included in the display portion 162.

All of the transistors included in the display portion 162 may be OS transistors or Si transistors. Alternatively, some of the transistors included in the display portion 162 may be OS transistors and the others may be Si transistors.

For example, when both an LTPS transistor and an OS transistor are used in the display portion 162, the display apparatus can have low power consumption and high drive capability. Note that a structure in which the LTPS transistor and the OS transistor are combined is referred to as LTPO in some cases. As a favorable example, a structure is given in which the OS transistor is used as a transistor functioning as a switch for controlling electrical continuity and discontinuity between wirings and the LTPS transistor is used as a transistor for controlling current.

For example, one transistor included in the display portion 162 may function as a transistor for controlling current flowing through the light-emitting device and be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

By contrast, another transistor included in the display portion 162 may function as a switch for controlling selection or non-selection of a pixel and be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or lower); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having a metal maskless (MML) structure. With this structure, the leakage current that might flow through the transistor and the leakage current that might flow between adjacent light-emitting devices (also referred to as a lateral leakage current, a side leakage current, or the like) can become extremely low. With the structure, a viewer can observe any one or more of the image clearness, the image sharpness, a high chroma, and a high contrast ratio in an image displayed on the display apparatus. When the leakage current that might flow through the transistor and the lateral leakage current that might flow between light-emitting devices are extremely low, display with little leakage of light at the time of black display (what is called black floating) can be achieved.

In particular, in the case where a light-emitting device having an MML structure employs the above-described SBS structure, a layer provided between light-emitting devices (for example, also referred to as an organic layer or a common layer which is shared by the light-emitting devices) is disconnected; accordingly, display with no or extremely small lateral leakage can be achieved.

FIGS. 28B and 28C illustrate other structure examples of the transistor.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 28B illustrates an example of the transistor 209 where the insulating layer 225 covers the top and side surfaces of the semiconductor layer 231. The conductive layers 222a and 222b are connected to the corresponding low-resistance regions 231n through openings provided in the insulating layers 225 and 215. One of the conductive layers 222a and 222b functions as a source, and the other functions as a drain.

In the transistor 210 illustrated in FIG. 28C, the insulating layer 225 overlaps with the channel formation region 231i of the semiconductor layer 231 and does not overlap with the low-resistance regions 231n. The structure illustrated in FIG. 28C is obtained by processing the insulating layer 225 using the conductive layer 223 as a mask, for example. In FIG. 28C, the insulating layer 215 is provided to cover the insulating layer 225 and the conductive layer 223, and the conductive layers 222a and 222b are connected to the corresponding low-resistance regions 231n through the openings in the insulating layer 215.

The coloring layer 132R and the color conversion layer 135 are provided on a surface of the substrate 152 on the substrate 151 side. Some of the plurality of light-emitting devices 130G included in the display apparatus (specifically, the light-emitting devices 130G included in the subpixels emitting red light) each overlap with the color conversion layer 135 and the coloring layer 132R. The light-blocking layer 117 is preferably provided on the surface. The light-blocking layer 117 can be provided over a region between adjacent light-emitting devices, in the connection portion 140, in the circuit 164, and the like. A variety of optical members can be arranged on the outer surface of the substrate 152.

A material that can be used for the substrate 120 can be used for each of the substrates 151 and 152.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100H]

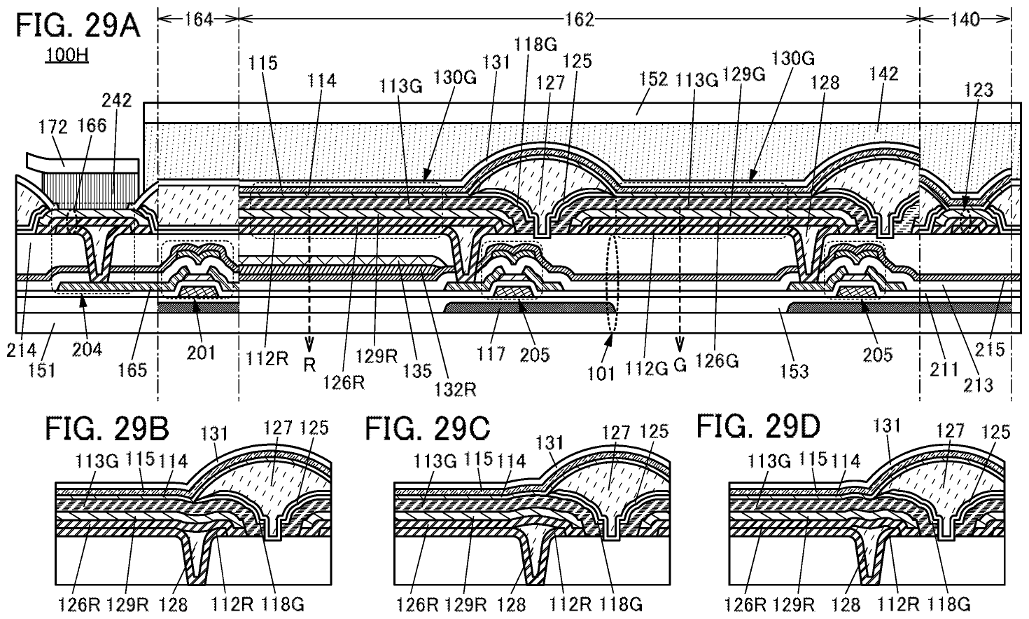

A display apparatus 100H in FIG. 29A differs from the display apparatus 100G mainly in having a bottom-emission structure.

Light from the light-emitting device is emitted toward the substrate 151. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor 201 and between the substrate 151 and the transistor 205. FIG. 29A illustrates an example where the light-blocking layer 117 is provided over the substrate 151, an insulating layer 153 is provided over the light-blocking layer 117, and the transistors 201 and 205 and the like are provided over the insulating layer 153. The color conversion layer 135 and the coloring layer 132R are provided over the insulating layer 215.

The light-emitting device 130G overlapping with the color conversion layer 135 and the coloring layer 132R includes the conductive layer 112R, the conductive layer 126R over the conductive layer 112R, and the conductive layer 129R over the conductive layer 126R.

The light-emitting device 130G not overlapping with the color conversion layer 135 or the coloring layer 132R includes the conductive layer 112G, the conductive layer 126G over the conductive layer 112G, and the conductive layer 129G over the conductive layer 126G.

A material having a visible-light-transmitting property is used for each of the conductive layers 112R, 112G, 126R, 126G, 129R, and 129G. A material that reflects visible light is preferably used for the common electrode 115.

Although FIG. 28A, FIG. 29A, and the like illustrate an example where the top surface of the layer 128 includes a flat portion, the shape of the layer 128 is not particularly limited. FIGS. 29B to 29D illustrate variation examples of the layer 128.

As illustrated in FIGS. 29B and 29D, the top surface of the layer 128 can have a shape in which its center and vicinity thereof fall, i.e., a shape including a concave surface, in the cross-sectional view.

As illustrated in FIG. 29C, the top surface of the layer 128 can have a shape in which its center and vicinity thereof bulge, i.e., a shape including a convex surface, in the cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 112R may be the same or substantially the same, or may be different from each other. For example, the level of the top surface of the layer 128 may be either lower or higher than the level of the top surface of the conductive layer 112R.

FIG. 29B can be regarded as an example where the layer 128 fits in the depressed portion formed by the conductive layer 112R. In contrast, as illustrated in FIG. 29D, the layer 128 may exist also outside the depressed portion formed by the conductive layer 112R, that is, the top surface of the layer 128 may extend beyond the depressed portion.

### <<Display Apparatus 100J>>

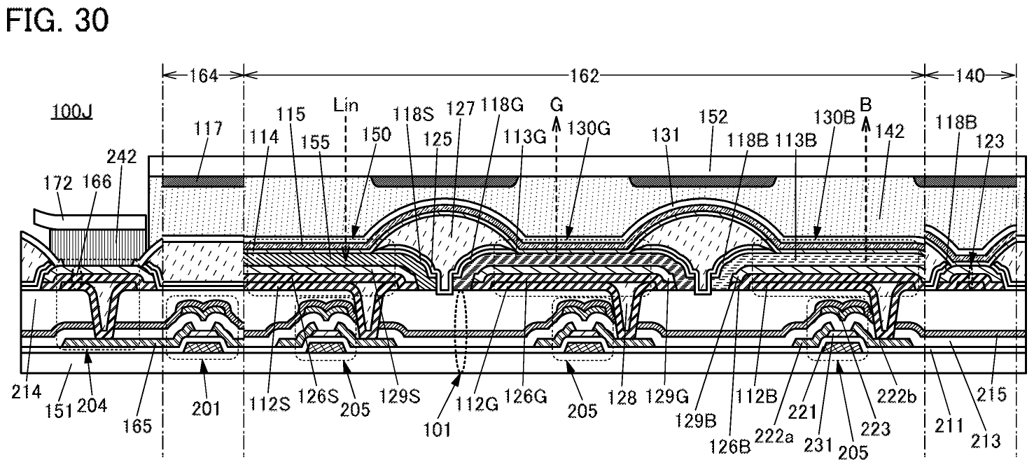

A display apparatus 100J illustrated in FIG. 30 differs from the display apparatus 100G mainly in including the light-receiving device 150.

The light-receiving device 150 includes a conductive layer 112S, a conductive layer 126S over the conductive layer 112S, and a conductive layer 129S over the conductive layer 126S.

The conductive layer 112S is connected to the conductive layer 222b included in the transistor 205 through the opening provided in the insulating layer 214.

The top surface and a side surface of the conductive layer 126S and the top and side surfaces of the conductive layer 129S are covered with the layer 155. The layer 155 includes at least an active layer.

The side surface and part of the top surface of the layer 155 is covered with the insulating layers 125 and 127. The mask layer 118S is positioned between the layer 155 and the insulating layer 125. The common layer 114 is provided over the layer 155 and the insulating layers 125 and 127, and the common electrode 115 is provided over the common layer 114. The common layer 114 is a continuous film shared by the light-receiving device and the light-emitting devices.

For example, the display apparatus 100J can employ the pixel layout described in Embodiment 3 with reference to FIGS. 19A to 19K. Embodiments 1 and 6 can be referred to for the details of the display apparatus including the light-receiving device.

This embodiment can be combined with any of the other embodiments as appropriate.

### Embodiment 5

In this embodiment, a light-emitting device that can be used in the display apparatus of one embodiment of the present invention will be described.

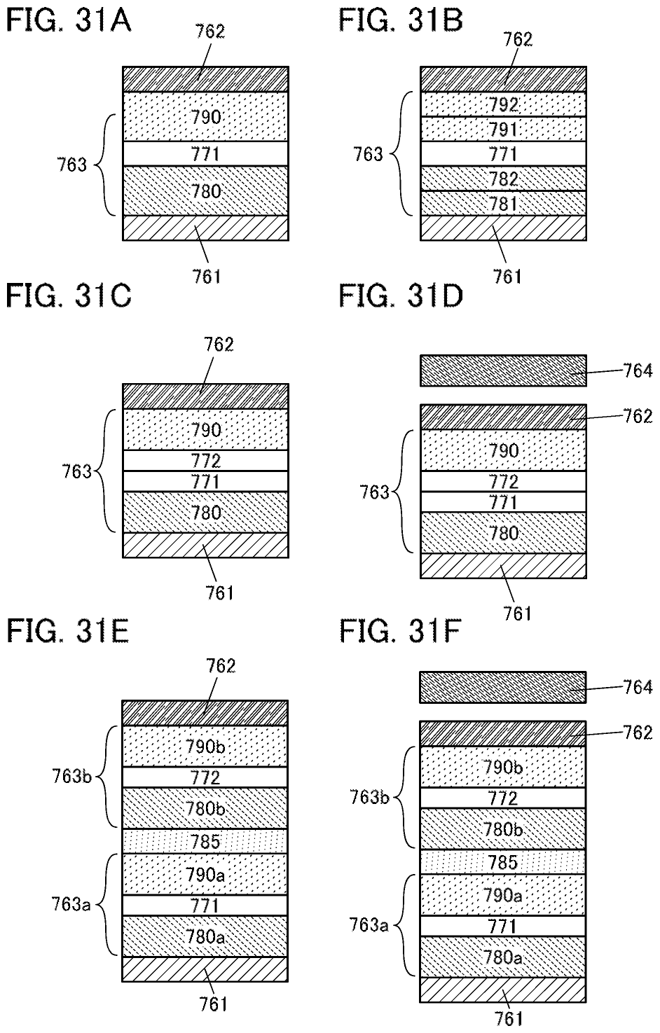

As illustrated in FIG. 31A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). The layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layers 780 and 790 are replaced with each other.

The structure including the layer 780, the light-emitting layer 771, and the layer 790, which is provided between a pair of electrodes, can function as a single light-emitting unit, and the structure in FIG. 31A is referred to as a single structure in this specification.

FIG. 31B is a variation example of the EL layer 763 included in the light-emitting device illustrated in FIG. 31A. Specifically, the light-emitting device illustrated in FIG. 31B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (light-emitting layers 771 and 772) are provided between the layers 780 and 790 as illustrated in FIGS. 31C and 31D are other variations of the single structure. Although FIGS. 31C and 31D illustrate the examples where two light-emitting layers are included, the light-emitting device having a single structure may include three or more light-emitting layers. In addition, the light-emitting device having a single structure may include a buffer layer between two light-emitting layers. The buffer layer can be formed using a material that can be used for the hole-transport layer or the electron-transport layer, for example.

In this specification, as illustrated in FIGS. 31E and 31F, a structure where a plurality of light-emitting units (a light-emitting unit 763a and a light-emitting unit 763b) are connected in series with a charge-generation layer 785 (also referred to as an intermediate layer) therebetween is referred to as a tandem structure. Note that a tandem structure may be referred to as a stack structure. The tandem structure enables a light-emitting device capable of high-luminance light emission. Furthermore, a tandem structure allows the amount of current needed for obtaining the same luminance to be reduced as compared to the case of using a single structure, and thus can improve the reliability.

Note that FIGS. 31D and 31F illustrate examples where the display apparatus includes a layer 764 overlapping with the light-emitting device. FIG. 31D illustrates an example where the layer 764 overlaps with the light-emitting device illustrated in FIG. 31C, and FIG. 31F illustrates an example where the layer 764 overlaps with the light-emitting device illustrated in FIG. 31E. In FIGS. 31D and 31F, a conductive film transmitting visible light is used for the upper electrode 762 to extract light to the upper electrode 762 side.

One or both of a color conversion layer and a color filter (coloring layer) can be used as the layer 764.

In FIGS. 31C to 31F, light-emitting substances emitting light of the same color or the same light-emitting substance may be used for the light-emitting layers 771 and 772. For example, in a subpixel emitting blue light, a light-emitting substance emitting blue light may be used for each of the light-emitting layers 771 and 772. Thus, blue light emitted from the light-emitting device can be extracted. In a subpixel emitting red light and a subpixel emitting green light, a light-emitting substance emitting green light may be used for each of the light-emitting layers 771 and 772. Thus, green light emitted from the light-emitting device can be extracted in the subpixel emitting green light. In the subpixel emitting red light, a color conversion layer is provided as the layer 764 illustrated in FIG. 31D or 31F, so that green light emitted from the light-emitting device can be extracted as red light. In the subpixel emitting red light, the layer 764 may have a stacked-layer structure of the light conversion layer and a red coloring layer.

In FIGS. 31C to 31F, light-emitting substances emitting light of different colors may be used for the light-emitting layers 771 and 772.

In the case where the light-emitting device having any of the structures illustrated in FIG. 31E or 31F is used for the subpixels emitting different colors, the subpixels may use different light-emitting substances. For example, in the subpixel emitting red light and the subpixel emitting green light, a light-emitting substance emitting green light is used for each of the light-emitting layers 771 and 772. In the light-emitting device included in the subpixel emitting blue light, a light-emitting substance emitting blue light is used for each of the light-emitting layers 771 and 772. A display apparatus having such a structure can be regarded as employing a light-emitting device with the tandem structure and the SBS structure. Thus, such a display apparatus takes advantages of both the tandem structure and the SBS structure. Thus, a light-emitting device being capable of high-luminance light emission and having high reliability can be obtained.

Although FIGS. 31E and 31F illustrate examples where the light-emitting unit 763a includes one light-emitting layer 771 and the light-emitting unit 763b includes one the light-emitting layer 772, one embodiment of the present invention is not limited thereto. The light-emitting units 763a and 763b may each include two or more light-emitting layers.

In addition, although FIGS. 31E and 31F illustrate the light-emitting device including two light-emitting units, one embodiment of the present invention is not limited thereto. The light-emitting device may include three or more light-emitting units.

In FIGS. 31C and 31D, each of the layers 780 and 790 may independently has a stacked-layer structure of two or more layers as in FIG. 31B.

In FIGS. 31E and 31F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, and the layers 780a and 780b each include one or more of a hole-injection layer, a hole-transport layer, and an electron-blocking layer. The layers 790a and 790b each include one or more of an electron-injection layer, an electron-transport layer, and a hole-blocking layer. In the case where the lower electrode 761 is a cathode and the upper electrode 762 is an anode, the structures of the layers 780a and 790a are replaced with each other, and the structures of the layers 780b and 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 771 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 771 and the hole-transport layer.

In the case of manufacturing a light-emitting device having a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

Next, materials that can be used for the light-emitting device will be described.

A conductive film transmitting visible light is used as the electrode through which light is extracted, which is either the lower electrode 761 or the upper electrode 762. A conductive film reflecting visible light is preferably used as the electrode through which light is not extracted. In the case where a display apparatus includes a light-emitting device emitting infrared light, a conductive film transmitting visible light and infrared light is used as the electrode through which light is extracted, and a conductive film reflecting visible light and infrared light is preferably used as the electrode through which light is not extracted.

A conductive film that transmitting visible light may be used also for the electrode through which light is not extracted. In this case, this electrode is preferably provided between the reflective layer and the EL layer 763. In other words, light emitted from the EL layer 763 may be reflected by the reflective layer to be extracted from the display apparatus.

For the pair of electrodes of the light-emitting device, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (In—Sn oxide, also referred to as ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include a Group 1 element and a Group 2 element of the periodic table, which are not described above (e.g., lithium, cesium, calcium, and strontium), rare earth metals such as europium and ytterbium, an alloy containing any of these elements in appropriate combination, and graphene.

The light-emitting device preferably employs a microcavity structure. Therefore, one of the pair of electrodes of the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer having a visible-light-transmitting property (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used in the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance with a high hole-injection property, a substance with a high hole-transport property, a hole-blocking material, a substance with a high electron-transport property, an electron-blocking material, a substance with a high electron-injection property, a substance with a bipolar property (also referred to as a substance with a high electron- and hole-transport property or a bipolar material), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed, for example, by an evaporation method (including a vacuum evaporation method), a transfer method, a printing method, an inkjet method, or a coating method.

The light-emitting layer can contain one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (guest material). As the one or more kinds of organic compounds, one or both of a substance having a high hole-transport property (a hole-transport material) and a substance having a high electron-transport property (an electron-transport material) can be used. As the hole-transport material, it is possible to use a substance having a high hole-transport property which can be used for the hole-transport layer and will be described later. As the electron-transport material, it is possible to use a substance having a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer injects holes from the anode to the hole-transport layer and contains a substance with a high hole-injection property. Examples of a substance with a high hole-injection property include an aromatic amine compound and a composite material containing a hole-transport material and an acceptor material (electron-accepting material).

As the hole-transport material, it is possible to use a substance having a high hole-transport property which can be used for the hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can also be used.

For example, a hole-transport material and a material containing an oxide of a metal belonging to any of Groups 4 to 8 of the periodic table (typically, molybdenum oxide) may be used as the substance having a high hole-injection property.

The hole-transport layer transports holes injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. As the hole-transport material, substances with a high hole-transport property, such as a n-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

The electron-transport layer transports electrons injected from the cathode by the electron-injection layer, to the light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. As the electron-transport material, any of the following substances with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a n-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

The electron-injection layer injects electrons from the cathode to the electron-transport layer and contains a substance with a high electron-injection property. As the substance with a high electron-injection property, an alkali metal, an alkaline earth metal, or a compound thereof can be used. As the substance with a high electron-injection property, a composite material containing an electron-transport material and a donor material (electron-donating material) can also be used.

The difference between the LUMO level of the substance having a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFx, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

In addition, the charge-generation layer preferably includes a layer containing a substance having a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be used for the electron-injection buffer layer.

The charge-generation layer preferably includes a layer containing a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II)phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other in some cases depending on the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

This embodiment can be combined with any of the other embodiments as appropriate.

### Embodiment 6

In this embodiment, a light-receiving device that can be used for a display apparatus of one embodiment of the present invention, and a display apparatus having a light-emitting and light-receiving function will be described.

### [Light-Receiving Device]

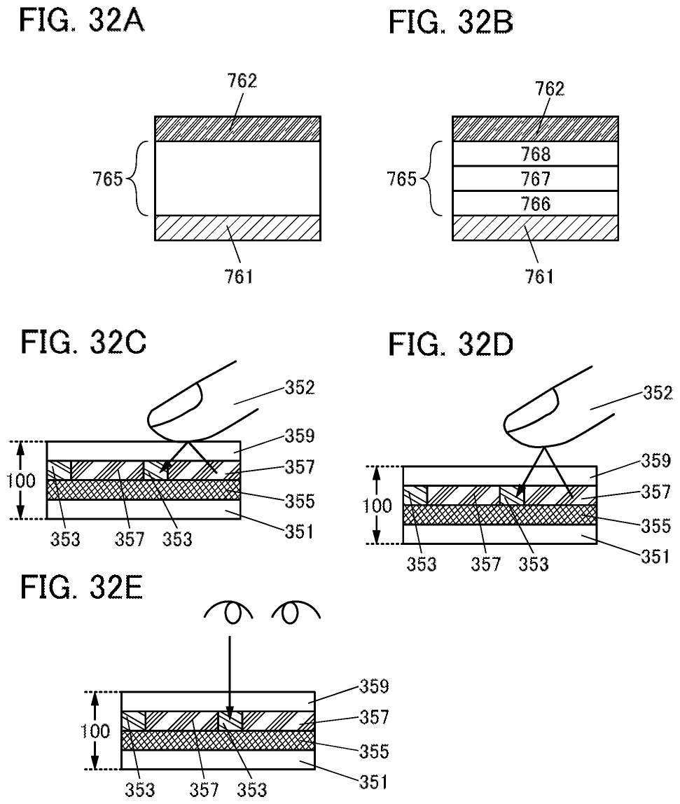

As illustrated in FIG. 32A, the light-receiving device includes a layer 765 between a pair of electrodes (the lower electrode 761 and the upper electrode 762). The layer 765 includes at least one active layer, and may further include another layer.

FIG. 32B is a variation example of the EL layer 765 included in the light-receiving device illustrated in FIG. 32A. Specifically, the light-receiving device illustrated in FIG. 32B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layers 766 and 768 are replaced with each other.

Next, materials that can be used for the light-receiving device will be described.

Either a low molecular compound or a high molecular compound can be used for the light-receiving device, and an inorganic compound may also be included. Each layer included in the light-receiving device can be formed, for example, by an evaporation method (including a vacuum evaporation method), a transfer method, a printing method, an inkjet method, or a coating method.

The active layer included in the light-receiving device includes a semiconductor. Examples of the semiconductor include an inorganic semiconductor such as silicon and an organic semiconductor including an organic compound. This embodiment describes an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer are electron-accepting organic semiconductor materials such as fullerene (e.g., C₆₀ and C₇₀) and fullerene derivatives. Other examples of fullerene derivatives include [6,6]-phenyl-C₇₁-butyric acid methyl ester (abbreviation: PC₇₀BM), [6,6]-phenyl-C₆₁-butyric acid methyl ester (abbreviation: PC₆₀BM), and 1′,1″,4′,4″-tetrahydro-di[1,4]methanonaphthaleno[1,2:2′,3′,56,60:2″,3″][5,6]fullerene-C₆₀ (abbreviation: ICBA).

Examples of the material of the n-type semiconductor include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

Three or more kinds of materials may be used for the active layer. For example, a third material may be mixed with an n-type semiconductor material and a p-type semiconductor material in order to extend the absorption wavelength range. In this case, the third material may be a low molecular compound or a high molecular compound.

In addition to the active layer, the light-receiving device may further include a layer containing a substance having a high hole-transport property, a substance having a high electron-transport property, a substance having a bipolar property (a substance having a high electron- and hole-transport property), or the like. Without limitation to the above, the light-receiving device may further include a substance having a high hole-injection property, a hole-blocking material, a substance having a high electron-injection property, an electron-blocking material, or the like. Layers other than the active layer in the light-receiving device can be formed using a material that can be used for the light-emitting device.

As the hole-transport material or the electron-blocking material, a high molecular compound such as poly(3,4-ethylenedioxythiophene)/poly(styrenesulfonic acid) (PEDOT/PSS), or an inorganic compound such as a molybdenum oxide or copper iodide (CuT) can be used, for example. As the electron-transport material or the hole-blocking material, an inorganic compound such as zinc oxide (ZnO), or an organic compound such as polyethylenimine ethoxylate (PETE) can be used. The light-receiving device may include a mixed film of PETE and ZnO, for example.

### [Display Apparatus Having Light Detection Function]

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by sensing light at the display portion, an image can be captured or the approach or contact of an object (e.g., a finger, a hand, or a stylus) can be detected.

Furthermore, in the display apparatus of one embodiment of the present invention, the light-emitting devices can be used as a light source of the sensor. In the display apparatus of one embodiment of the present invention, when an object reflects (or scatters) light emitted from the light-emitting device included in the display portion, the light-receiving device can detect the reflected light (or the scattered light); thus, image capturing or touch sensing is possible even in a dark place.

Accordingly, a light-receiving portion and a light source do not need to be provided separately from the display apparatus; hence, the number of components of an electronic device can be reduced. For example, a biometric authentication device provided in the electronic device, a capacitive touch panel for scroll operation, or the like is not necessarily provided separately. Thus, with the use of the display apparatus of one embodiment of the present invention, the electronic device can be provided at lower manufacturing costs.

Specifically, the display apparatus of one embodiment of the present invention includes a light-emitting device and a light-receiving device in a pixel. In the display apparatus of one embodiment of the present invention, organic EL devices are used as the light-emitting devices, and organic photodiodes are used as the light-receiving devices. The organic EL device and the organic photodiode can be formed over one substrate. Thus, the organic photodiode can be incorporated into the display apparatus including the organic EL device.

The display apparatus can detect the touch or approach of an object while displaying an image because the pixel included in the display apparatus includes the light-emitting device and the light-receiving device and thus has a light-receiving function. For example, an image can be displayed by using all the subpixels included in a display apparatus; or light can be emitted by some of the subpixels as a light source, light can be detected by some other subpixels, and an image can be displayed by using the remaining subpixels.

When the light-receiving device is used as an image sensor, the display apparatus can capture an image with the use of the light-receiving device. For example, the display apparatus of this embodiment can be used as a scanner.

For example, image capturing for personal authentication with the use of a fingerprint, a palm print, the iris, the shape of a blood vessel (including the shape of a vein and the shape of an artery), a face, or the like is possible by using the image sensor.

For example, an image of the periphery, surface, or inside (e.g., fundus) of an eye of a user of a wearable device can be captured with the use of the image sensor. Therefore, the wearable device can have a function of sensing one or more selected from blinking, movement of an iris, and movement of an eyelid of the user.

Moreover, the light-receiving device can be used in a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect an approach or contact of an object (e.g., a finger, a hand, or a pen).

The touch sensor can detect the object when the display apparatus and the object come in direct contact with each other. Furthermore, the near touch sensor can detect the object even when the object is not in contact with the display apparatus. For example, the display apparatus is preferably capable of sensing an object positioned in the range of 0.1 mm to 300 mm inclusive, more preferably 3 mm to 50 mm inclusive from the display apparatus. This structure enables the display apparatus to be operated without direct contact of an object. In other words, the display apparatus can be operated in a contactless (touchless) manner. With the above-described structure, the display apparatus can be controlled with a reduced risk of being dirty or damaged, or can be controlled without the object directly touching a dirt (e.g., dust, bacteria, or a virus) attached to the display apparatus.

The refresh rate of the display apparatus of one embodiment of the present invention can be variable. For example, the refresh rate is adjusted (in the range from 1 Hz to 240 Hz, for example) in accordance with contents displayed on the display apparatus, whereby power consumption can be reduced. The driving frequency of the touch sensor or the near touch sensor may be changed in accordance with the refresh rate. In the case where the refresh rate of the display apparatus is 120 Hz, for example, the drive frequency of a touch sensor or a near touch sensor can be higher than 120 Hz (typically 240 Hz). With this structure, low power consumption can be achieved, and the response speed of the touch sensor or the near touch sensor can be increased.

The display apparatus 100 illustrated in FIGS. 32C to 32E includes, between a substrate 351 and a substrate 359, a layer 353 including a light-receiving device, a functional layer 355, and a layer 357 including a light-emitting device.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure not provided with a switch or a transistor may be employed.

For example, after light emitted from the light-emitting device in the layer 357 including light-emitting devices is reflected by a finger 352 that touches the display apparatus 100 as illustrated in FIG. 32C, the light-receiving device in the layer 353 including light-receiving devices detects the reflected light. Thus, the touch of the finger 352 on the display apparatus 100 can be detected.

The display apparatus may have a function of detecting an object that is approaching (but is not touching) the display apparatus or capturing an image of such an object, as illustrated in FIGS. 32D and 32E. FIG. 32D illustrates an example where a human finger is detected, and FIG. 32E illustrates an example where information on the periphery, surface, or inside of the human eye (e.g., the number of blinks, the movement of an eyeball, and the movement of an eyelid) is detected.

This embodiment can be combined with any of the other embodiments as appropriate.

### Embodiment 7

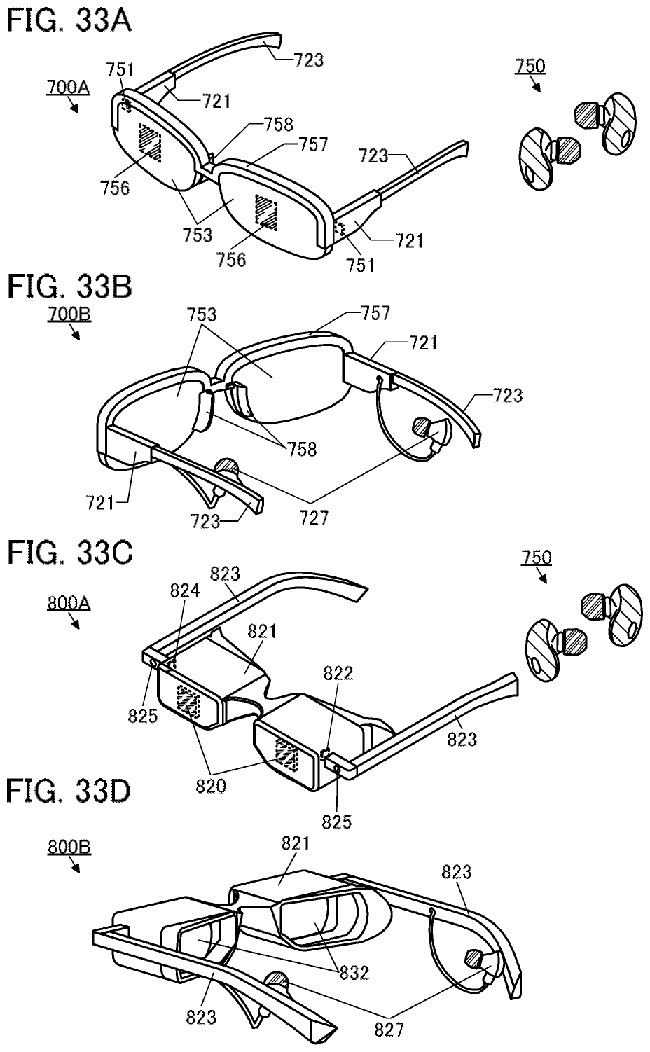

In this embodiment, electronic devices of embodiments of the present invention will be described with reference to FIGS. 33A to 33D, FIGS. 34A to 34F, and FIGS. 35A to 35G.

Electronic devices of this embodiment are each provided with the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus of one embodiment of the present invention can have a high definition, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display apparatus having one or both of such high definition and high resolution can further increase realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIGS. 33A to 33D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 33A and an electronic device 700B illustrated in FIG. 33B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 33C and an electronic device 800B illustrated in FIG. 33D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic devices are capable of performing ultrahigh-resolution display. Such electronic devices provide a high sense of immersion to the user.

The display portions 820 are provided at positions where the user can see through the lenses 832 inside the housing 821. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 33C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A in FIG. 33A has a function of transmitting information to the earphones 750 with the wireless communication function. As another example, the electronic device 800A in FIG. 33C has a function of transmitting information to the earphones 750 with the wireless communication function.

The electronic device may include an earphone portion. The electronic device 700B in FIG. 33B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B in FIG. 33D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferable because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

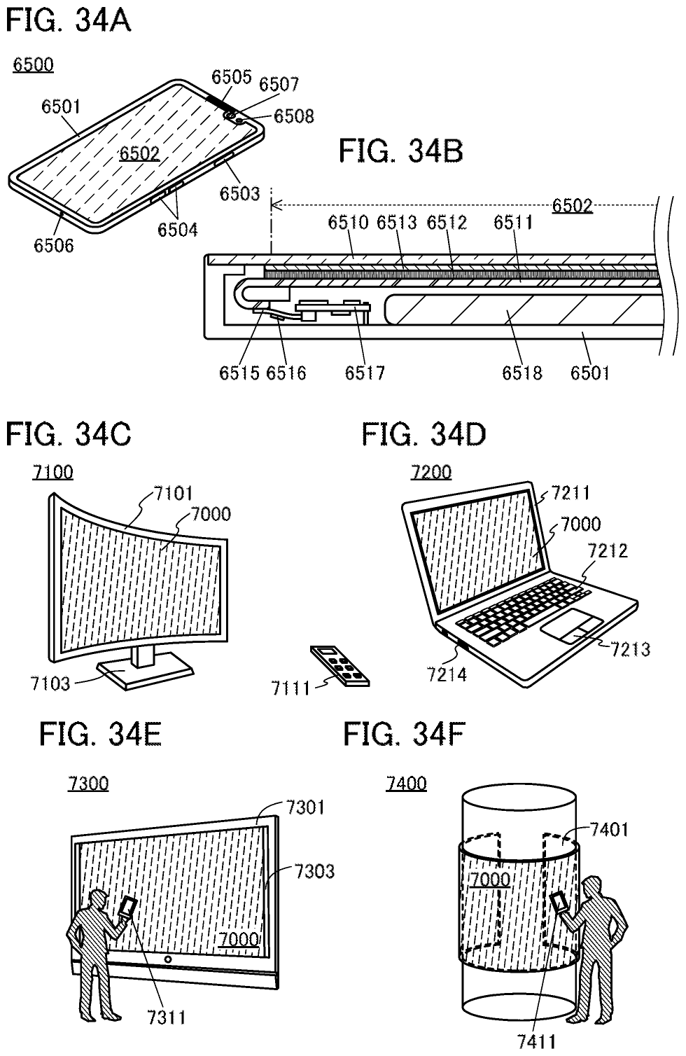

An electronic device 6500 illustrated in FIG. 34A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 34B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 34C illustrates an example of a television device. In a television device 7100, a display portion 7000 is incorporated in a housing 7101. Here, the housing 7101 is supported by a stand 7103.

The display apparatus of one embodiment of the present invention can be used in the display portion 7000.

Operation of the television device 7100 illustrated in FIG. 34C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 34D illustrates an example of a laptop personal computer. The laptop personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000.

FIGS. 34E and 34F illustrate examples of digital signage.

Digital signage 7300 illustrated in FIG. 34E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 34F illustrates digital signage 7400 attached to a cylindrical pillar 7401. The digital signage 7400 includes the display portion 7000 provided along a curved surface of the pillar 7401.

The display apparatus of one embodiment of the present invention can be used in the display portion 7000 illustrated in each of FIGS. 34E and 34F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIGS. 34E and 34F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

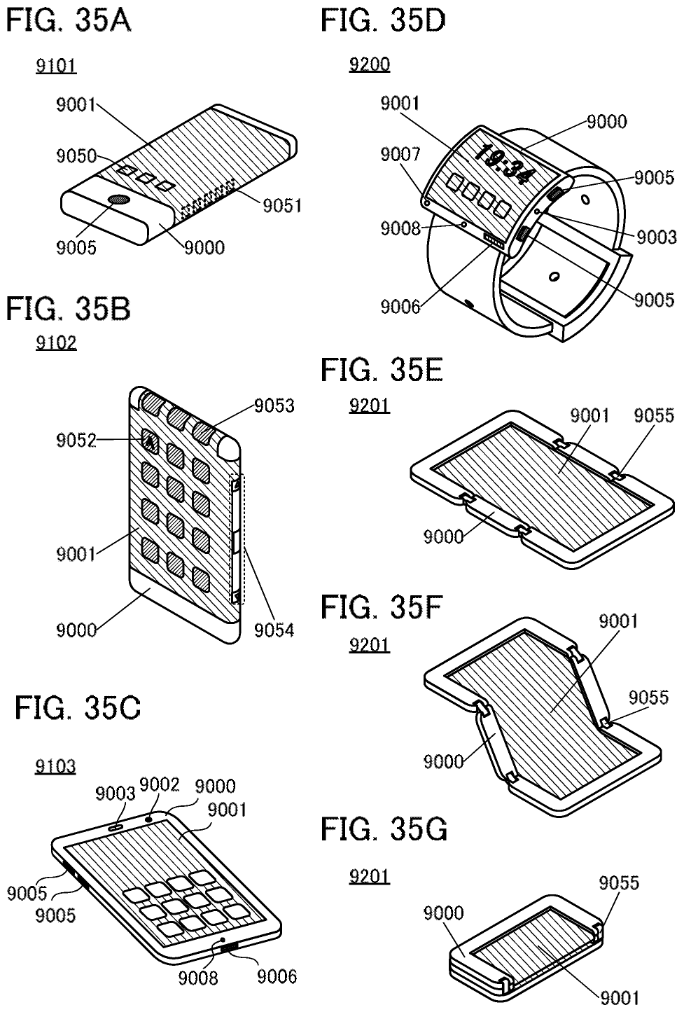

Electronic devices illustrated in FIGS. 35A to 35G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays), a microphone 9008, and the like.

In FIGS. 35A to 35G, the display apparatus of one embodiment of the present invention can be used in the display portion 9001.

The electronic devices illustrated in FIGS. 35A to 35G have a variety of functions. For example, the electronic devices can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 35A to 35G will be described in detail below.

FIG. 35A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 35A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 35B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 35C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 35D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 35E to 35G are perspective views of a foldable portable information terminal 9201. FIG. 35E is a perspective view illustrating the portable information terminal 9201 that is opened. FIG. 35G is a perspective view illustrating the portable information terminal 9201 that is folded. FIG. 35F is a perspective view illustrating the portable information terminal 9201 that is shifted from one of the states in FIGS. 35E and 35G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate.

This application is based on Japanese Patent Application Serial No. 2021-165508 filed with Japan Patent Office on Oct. 7, 2021, the entire contents of which are hereby incorporated by reference.

What is claimed is:

1. A display apparatus comprising:
a first light-emitting device;
a second light-emitting device;
a third light-emitting device;
a color conversion layer;
a first insulating layer; and
a second insulating layer,
wherein the first light-emitting device comprises a first pixel electrode, a first light-emitting layer over the first pixel electrode, and a common electrode over the first light-emitting layer,
wherein the second light-emitting device comprises a second pixel electrode, a second light-emitting layer over the second pixel electrode, and the common electrode over the second light-emitting layer,
wherein the third light-emitting device comprises a third pixel electrode, a third light-emitting layer over the third pixel electrode, and the common electrode over the third light-emitting layer,
wherein the first light-emitting layer and the second light-emitting layer comprise the same light-emitting material,
wherein the third light-emitting device emits shorter-wavelength light than the first light-emitting device and the second light-emitting device,
wherein the color conversion layer overlaps with the first light-emitting device,
wherein the color conversion layer converts a color of light emitted from the first light-emitting device into a different color,
wherein the first insulating layer covers a side surface and part of a top surface of the first light-emitting layer and a side surface and part of a top surface of the second light-emitting layer,
wherein the second insulating layer overlaps with the part of the top surface of the first light-emitting layer and the part of the top surface of the second light-emitting layer with the first insulating layer therebetween,
wherein the second insulating layer comprises a portion positioned between the side surface of the first light-emitting layer and the side surface of the second light-emitting layer, and
wherein the common electrode covers a top surface of the second insulating layer.

2. A display apparatus comprising:
a first light-emitting device;
a second light-emitting device;
a third light-emitting device;
a color conversion layer;
a first insulating layer; and
a second insulating layer,
wherein the first light-emitting device comprises a first pixel electrode, a first light-emitting layer over the first pixel electrode, a first functional layer over the first light-emitting layer, and a common electrode over the first functional layer,
wherein the second light-emitting device comprises a second pixel electrode, a second light-emitting layer over the second pixel electrode, a second functional layer over the second light-emitting layer, and the common electrode over the second functional layer,
wherein the third light-emitting device comprises a third pixel electrode, a third light-emitting layer over the third pixel electrode, a third functional layer over the third light-emitting layer, and the common electrode over the third functional layer,
wherein the first light-emitting layer and the second light-emitting layer comprise the same light-emitting material,
wherein the third light-emitting device emits the shortest-wavelength light among the first light-emitting device, the second light-emitting device, and the third light-emitting device,
wherein the color conversion layer overlaps with the first light-emitting device,
wherein the color conversion layer converts a color of light emitted from the first light-emitting device into a different color,
wherein the first insulating layer covers a side surface and part of a top surface of the first light-emitting layer, a side surface and part of a top surface of the second light-emitting layer, a side surface and part of a top surface of the first functional layer, and a side surface and part of a top surface of the second functional layer,
wherein the second insulating layer overlaps with the part of the top surface of the first light-emitting layer, the part of the top surface of the second light-emitting layer, the part of the top surface of the first functional layer, and the part of the top surface of the second functional layer with the first insulating layer therebetween,
wherein the second insulating layer comprises a portion positioned between the side surface of the first light-emitting layer and the side surface of the second light-emitting layer, and
wherein the common electrode covers a top surface of the second insulating layer.

3. The display apparatus according to claim 2,
wherein the first functional layer, the second functional layer, and the third functional layer each comprise at least one of a hole-injection layer, an electron-injection layer, a hole-transport layer, an electron-transport layer, a hole-blocking layer, and an electron-blocking layer.

4. The display apparatus according to claim 1,
wherein the first light-emitting device and the second light-emitting device emit green light,
wherein the third light-emitting device emits blue light, and
wherein the color conversion layer converts green light into red light.

5. The display apparatus according to claim 1, further comprising a first coloring layer at a position overlapping with the first light-emitting device with the color conversion layer therebetween,
wherein the first coloring layer transmits red light.

6. The display apparatus according to claim 1, further comprising:
a second coloring layer transmitting green light at a position overlapping with the second light-emitting device; and
a third coloring layer transmitting blue light at a position overlapping with the third light-emitting device.

7. The display apparatus according to claim 1,
wherein in a cross-sectional view, an end portion of the second insulating layer has a tapered shape with a taper angle less than 90°.

8. The display apparatus according to claim 1,
wherein the second insulating layer covers at least part of a side surface of the first insulating layer.

9. The display apparatus according to claim 1,
wherein an end portion of the second insulating layer is positioned on an outer side of an end portion of the first insulating layer.

10. The display apparatus according to claim 1,
wherein the top surface of the second insulating layer has a convex shape.

11. The display apparatus according to claim 1,
wherein in a cross-sectional view, an end portion of the first insulating layer has a tapered shape with a taper angle less than 90°.

12. The display apparatus according to claim 1,
wherein the first insulating layer and the second insulating layer each comprise a portion overlapping with a top surface of the first pixel electrode and a portion overlapping with a top surface of the second pixel electrode.

13. The display apparatus according to claim 1,
wherein the first light-emitting layer covers a side surface of the first pixel electrode,
wherein the second light-emitting layer covers a side surface of the second pixel electrode, and
wherein the third light-emitting layer covers a side surface of the third pixel electrode.

14. The display apparatus according to claim 1,
wherein in a cross-sectional view, an end portion of the first pixel electrode, an end portion of the second pixel electrode, and an end portion of the third pixel electrode each have a tapered shape with a taper angle less than 90°.

15. The display apparatus according to claim 1,
wherein the first insulating layer is an inorganic insulating layer, and
wherein the second insulating layer is an organic insulating layer.

16. The display apparatus according to claim 1,
wherein the first insulating layer comprises aluminum oxide.

17. The display apparatus according to claim 1,
wherein the first light-emitting device comprises a common layer between the first light-emitting layer and the common electrode,
wherein the second light-emitting device comprises the common layer between the second light-emitting layer and the common electrode,
wherein the third light-emitting device comprises the common layer between the third light-emitting layer and the common electrode, and
wherein the common layer is positioned between the second insulating layer and the common electrode.

18. A display module comprising:
the display apparatus according to claim 1; and
at least one of a connector and an integrated circuit.

19. An electronic device comprising:
the display module according to claim 18; and
at least one of a housing, a battery, a camera, a speaker, and a microphone.

20. The display apparatus according to claim 2,
wherein the first insulating layer and the second insulating layer each comprise a portion overlapping with a top surface of the first pixel electrode and a portion overlapping with a top surface of the second pixel electrode.
